(19) United States
(12) Patent Application Publication
(10) Pub. No.: US 2025/0151612 A1
(43) Pub. Date: May 8, 2025

(54) Light-Emitting Device

(71) Applicant: Semiconductor Energy Laboratory Co., Ltd., Kanagawa-ken (JP)

(72) Inventors: Toshiki SASAKI, Kawasaki (JP); Nobuharu OHSAWA, Zama (JP); Hiromi SEO, Sagamihara (JP); Shinya FUKUZAKI, Atsugi (JP)

(73) Assignee: Semiconductor Energy Laboratory Co., Ltd., Kanagawa-ken (JP)

(21) Appl. No.: 18/932,954

(22) Filed: Oct. 31, 2024

(30) Foreign Application Priority Data
Nov. 2, 2023 (JP) 2023-188880

(51) Int. Cl. H10K 85/60; H10K 50/11; H10K 50/17; H10K 101/40

(52) U.S. Cl. CPC H10K 85/654; H10K 50/11; H10K 50/171; H10K 85/653; H10K 85/656; H10K 85/6572; H10K 2101/40

(57) ABSTRACT

A light-emitting device with high reliability is provided. The light-emitting device includes a first electrode, a second electrode, and an EL layer. The EL layer is positioned between the first electrode and the second electrode. The EL layer includes a light-emitting layer and an electron-injection layer. The electron-injection layer contains a metal or an oxide of the metal, a first organic compound, and a second organic compound. The first organic compound includes a first π-electron deficient heteroaromatic ring with an electron-donating group. The second organic compound includes a second π-electron deficient heteroaromatic ring. The LUMO level of the second organic compound is lower than that of the first organic compound by 0.20 eV or more.

### BACKGROUND OF THE INVENTION

### 1. Field of the Invention

One embodiment of the present invention relates to a light-emitting device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

### 2. Description of the Related Art

Display devices are being developed into a variety of applications these days. For example, a television device for home use (also referred to as TV or television receiver), digital signage, and a public information display (PID) are being developed as large-sized display devices, and a smartphone and a tablet terminal each provided with a touch panel are being developed as small-sized display devices.

At the same time, an increase in the resolution of display device is also required. For example, devices for virtual reality (VR), augmented reality (AR), substitutional reality (SR), or mixed reality (MR) are given as devices requiring high-resolution display devices and are being developed actively.

Development is actively conducted on light-emitting devices (also referred to as light-emitting elements) as display elements used in display devices. Light-emitting devices utilizing electroluminescence (hereinafter referred to as EL; such devices are also referred to as EL devices or EL elements), particularly organic EL devices that mainly use organic compounds, are suitable for display devices because of having features such as ease of reduction in thickness and weight, high-speed response to input signals, and driving with a constant DC voltage power source.

In order to obtain a higher-resolution light-emitting apparatus using an organic EL device, patterning an organic layer by a photolithography technique using a photoresist or the like, instead of an evaporation method using a metal mask, has been studied. By using the photolithography technique, a high-resolution display device in which the distance between EL layers is several micrometers can be obtained (see Patent Document 1, for example).

### REFERENCES

### Patent Documents

[Patent Document 1] Japanese Translation of PCT International Application No. 2018-521459
[Patent Document 2] PCT International Publication No. 2021/045178

### SUMMARY OF THE INVENTION

It has been known that EL layers in an organic EL device (the organic EL device is also referred to as a light-emitting device in this specification) exposed to atmospheric components such as water and oxygen have affected initial characteristics or reliability, and thus it has been common knowledge that the EL layers are treated in a near-vacuum atmosphere. In particular, an electron-injection layer, which includes an alkali metal, an alkaline earth metal, or a compound thereof highly reactive with water or oxygen, rapidly deteriorates and loses the function as the electron-injection layer when the surface of the EL layer is exposed to the air.

However, processing steps with the aforementioned photolithography technique inevitably expose the surface of the EL layer to the air.

An object of one embodiment of the present invention is to provide a novel light-emitting device. An object of another embodiment of the present invention is to provide a highly efficient light-emitting device. An object of another embodiment of the present invention is to provide a highly reliable light-emitting device. An object of another embodiment of the present invention is to provide a highly efficient and highly reliable light-emitting device.

An object of another embodiment of the present invention is to provide a novel light-emitting device and manufactured through a photolithography process. An object of another embodiment of the present invention is to provide a highly efficient light-emitting device and manufactured through a photolithography process. An object of another embodiment of the present invention is to provide a highly reliable light-emitting device and manufactured through a photolithography process. An object of another embodiment of the present invention is to provide a high-emission-efficiency and highly reliable light-emitting device and manufactured through a photolithography process.

An object of another embodiment of the present invention is to provide a novel light-emitting device and can be used in a high-resolution display device. An object of another embodiment of the present invention is to provide a highly efficient light-emitting device and can be used in a high-resolution display device. An object of another embodiment of the present invention is to provide a highly reliable light-emitting device and can be used in a high-resolution display device. An object of another embodiment of the present invention is to provide a high-emission-efficiency and highly reliable light-emitting device and can be used in a high-resolution display device.

An object of another embodiment of the present invention is to provide a highly reliable display device. An object of another embodiment of the present invention is to provide a high-resolution display device. An object of another embodiment of the present invention is to provide a highly reliable and high-resolution display device.

Note that the description of these objects does not preclude the presence of other objects. One embodiment of the present invention does not necessarily achieve all of these objects. Other objects can be derived from the description of the specification, the drawings, and the claims.

One embodiment of the present invention is a light-emitting device including a first electrode, a second electrode, and an EL layer. The EL layer is positioned between the first electrode and the second electrode. The EL layer includes a light-emitting layer and an electron-injection layer. The electron-injection layer contains a metal or an oxide of the metal, a first organic compound, and a second organic compound. The first organic compound is an organic compound including a first π-electron deficient heteroaromatic ring with an electron-donating group. The second organic compound is an organic compound including a second π-electron deficient heteroaromatic ring. The LUMO level of the second organic compound is lower than the LUMO level of the first organic compound by 0.20 eV or more.

Another embodiment of the present invention is a light-emitting device that is one light-emitting device of a plurality of light-emitting devices included in a light-emitting device group. The light-emitting device group includes a first electrode group formed over one insulating surface, a second electrode group facing the first electrode group, and an EL layer group positioned between the first electrode group and the second electrode group. The light-emitting device includes a first electrode, a second electrode, and an EL layer. The first electrode is one included in the first electrode group. The first electrode is independent for each of the plurality of light-emitting devices. The EL layer is one included in the EL layer group. The EL layer is independent for each of the plurality of light-emitting devices. The second electrode is a continuous conductive layer shared by the plurality of light-emitting devices. The second electrode and the EL layer overlap with the first electrode. The EL layer includes a light-emitting layer and an electron-injection layer. The electron-injection layer contains a metal or an oxide of the metal, a first organic compound, and a second organic compound. The first organic compound is an organic compound including a first π-electron deficient heteroaromatic ring with an electron-donating group. The second organic compound is an organic compound including a second π-electron deficient heteroaromatic ring. The LUMO level of the second organic compound is lower than the LUMO level of the first organic compound by 0.20 eV or more. The distance between the EL layer included in the light-emitting device and the EL layer included in another light-emitting device adjacent to the light-emitting device is greater than or equal to 0.5 μm and less than or equal to 5 μm.

Another embodiment of the present invention is a light-emitting device including a first electrode, a second electrode, and an EL layer. The EL layer is positioned between the first electrode and the second electrode. The EL layer includes a light-emitting layer and an electron-injection layer. The electron-injection layer has a stacked-layer structure of a first layer containing a metal and a second layer containing a first organic compound and a second organic compound. The first layer is closer to a cathode side than the second layer is. The first organic compound is an organic compound including a first π-electron deficient heteroaromatic ring with an electron-donating group. The second organic compound is an organic compound including a second π-electron deficient heteroaromatic ring. The LUMO level of the second organic compound is lower than the LUMO level of the first organic compound by 0.20 eV or more.

Another embodiment of the present invention is a light-emitting device that is one light-emitting device of a plurality of light-emitting devices included in a light-emitting device group. The light-emitting device group includes a first electrode group formed over one insulating surface, a second electrode group facing the first electrode group, and an EL layer group positioned between the first electrode group and the second electrode group. The light-emitting device includes a first electrode, the second electrode, and an EL layer. The first electrode is one included in the first electrode group. The first electrode is independent for each of the plurality of light-emitting devices. The EL layer is one included in the EL layer group. The EL layer is independent for each of the plurality of light-emitting devices. The second electrode is a continuous conductive layer shared by the plurality of light-emitting devices. The second electrode and the EL layer overlap with the first electrode. The EL layer includes a light-emitting layer and an electron-injection layer. The electron-injection layer has a stacked-layer structure of the first layer containing a metal and a second layer containing a first organic compound and a second organic compound. The first layer is closer to a cathode side than the second layer is. The first organic compound is an organic compound including a first π-electron deficient heteroaromatic ring with an electron-donating group. The second organic compound is an organic compound including a second π-electron deficient heteroaromatic ring. The LUMO level of the second organic compound is lower than the LUMO level of the first organic compound by 0.20 eV or more. The distance between the EL layer included in the light-emitting device and the EL layer included in another light-emitting device adjacent to the light-emitting device is greater than or equal to 0.5 μm and less than or equal to 5 μm.

Another embodiment of the present invention is the light-emitting device with the above structure, in which a relation of the LUMO level of the first organic compound (LUMO1 (eV)) and the LUMO level of the second organic compound (LUMO2 (eV)) satisfies LUMO1−0.80≤LUMO2≤LUMO1−0.20.

Another embodiment of the present invention is the light-emitting device with the above structure, in which the LUMO level of the second organic compound (LUMO2 (eV)) satisfies LUMO1−0.80≤LUMO2≤LUMO1−0.30 in the case where the LUMO level of the first organic compound is LUMO1 (eV).

Another embodiment of the present invention is the light-emitting device with the above structure, in which the first π-electron deficient heteroaromatic ring is a heteroaromatic ring including two or more pyridine rings.

Another embodiment of the present invention is the light-emitting device with the above structure, in which the first organic compound is an organic compound having an acid dissociation constant pKₐ larger than or equal to 8.

Another embodiment of the present invention is the light-emitting device with the above structure, in which the first π-electron deficient heteroaromatic ring and the second π-electron deficient heteroaromatic ring are different from each other.

Another embodiment of the present invention is the light-emitting device with the above structure, in which the second organic compound includes an azole ring (an imidazole ring, a pyrazole ring, an oxazole ring, or a thiazole ring), a triazole ring, a diazine ring (a pyrazine ring, a pyrimidine ring, or a pyridazine ring), or a triazine ring.

Another embodiment of the present invention is the light-emitting device with the above structure, in which the second organic compound has an acid dissociation constant pKₐ less than 4.

Another embodiment of the present invention is the light-emitting device with the above structure, in which the light-emitting layer contains a third organic compound; the third organic compound includes a third π-electron deficient heteroaromatic ring; and the third π-electron deficient heteroaromatic ring is the same as the second π-electron deficient heteroaromatic ring.

Another embodiment of the present invention is the light-emitting device with the above structure, in which the light-emitting layer contains a third organic compound and the third organic compound is an organic compound identical to the second organic compound.

Another embodiment of the present invention is the light-emitting device with the above structure further including an electron-transport layer between the light-emitting layer and the electron-injection layer, in which the electron-transport layer contains a fourth organic compound, and the fourth organic compound is an organic compound different from the third organic compound.

Another embodiment of the present invention is the light-emitting device with the above structure, in which the metal is a metal belonging to any of Group 3, Group 11, and Group 13 of the periodic table.

Another embodiment of the present invention is the light-emitting device with the above structure, in which the first π-electron deficient heteroaromatic ring includes a phenanthroline ring.

Another embodiment of the present invention is the light-emitting device with the above structure, in which the first π-electron deficient heteroaromatic ring is a 1,10-phenanthroline ring and an electron-donating group is at at least one of a 4-position and a 7-position of the 1,10-phenanthroline ring.

Another embodiment of the present invention is the light-emitting device with the above structure, in which the electron-donating group is any one or more of an alkyl group, an alkoxy group, an aryloxy group, an alkylamino group, an arylamino group, and a heterocyclic amino group.

Another embodiment of the present invention is the light-emitting device with the above structure, in which the first organic compound has an acid dissociation constant pKₐ larger than or equal to 8.

Another embodiment of the present invention is the light-emitting device with the above structure, in which the minimum value of an electrostatic potential of the first organic compound is less than or equal to −0.085 Eₕ in the case where a threshold value of an electron density distribution in atomic units is 0.0004 e/a₀³.

Another embodiment of the present invention is the light-emitting device with the above structure, in which the spin density of the electron-injection layer measured by an electron spin resonance method is higher than or equal to 5×10¹⁶ spins/cm³.

Another embodiment of the present invention is the light-emitting device with the above structure, in which the electron-injection layer is positioned between the second electrode and the light-emitting layer. Another embodiment of the present invention is the light-emitting device with the above structure including a hole-injection layer, and in which the hole-injection layer is positioned between the first electrode and the light-emitting layer, and the hole-injection layer contains a fifth organic compound having a hole-transport property and a first substance having an acceptor property with respect to the fifth organic compound. Another embodiment of the present invention is the light-emitting device with the above structure, the hole-injection layer contains the fifth organic compound having a hole-transport property and an organic compound having four or more halogen groups, four or more cyano groups, or a combination of a halogen group and a cyano group the number of which is four or more. Another embodiment of the present invention is the light-emitting device with the above structure, the hole-injection layer contains the fifth organic compound having a hole-transport property and a metal or an oxide of the metal that is different from a metal or an oxide of the metal included in the electron-injection layer.

Another embodiment of the present invention is the light-emitting device with the above structure, in which the spin density of the hole-injection layer measured by an electron spin resonance method is higher than or equal to 1×10¹⁷ spins/cm³.

Another embodiment of the present invention is a light-emitting apparatus including a plurality of light-emitting devices, in which each of the plurality of light-emitting devices is a light-emitting device described in any of the above-described light-emitting devices. Each of the plurality of light-emitting devices includes an EL layer including a light-emitting layer and an electron-injection layer between the first electrode and the second electrode. The EL layer included in each of the plurality of light-emitting devices is independent between the plurality of light-emitting devices.

Another embodiment of the present invention is a display module including the above-described light-emitting device and at least one of a connector and an integrated circuit.

Another embodiment of the present invention is an electronic device including the above-described light-emitting device and at least one of a housing, a battery, a camera, a speaker, and a microphone.

With one embodiment of the present invention, a novel light-emitting device can be provided. With another embodiment of the present invention, a highly efficient light-emitting device can be provided. With another embodiment of the present invention, a highly reliable light-emitting device can be provided. With another embodiment of the present invention, a highly efficient and highly reliable light-emitting device can be provided.

With another embodiment of the present invention, a novel light-emitting device and manufactured through a photolithography process can be provided. With another embodiment of the present invention, a highly efficient light-emitting device and manufactured through a photolithography process can be provided. With another embodiment of the present invention, a highly reliable light-emitting device and manufactured through a photolithography process can be provided. With another embodiment of the present invention, a high-emission-efficiency and highly reliable light-emitting device and manufactured through a photolithography process can be provided.

With another embodiment of the present invention, a novel light-emitting device and can be used in a high-resolution display device can be provided. With another embodiment of the present invention, a highly efficient light-emitting device and can be used in a high-resolution display device can be provided. With another embodiment of the present invention, a highly reliable light-emitting device and can be used in a high-resolution display device can be provided. With another embodiment of the present invention, a high-emission-efficiency and highly reliable light-emitting device and can be used in a high-resolution display device can be provided.

With another embodiment of the present invention, a highly reliable display device can be provided. With another embodiment of the present invention, a high-resolution display device can be provided. With another embodiment of the present invention, a highly reliable and high-resolution display device can be provided.

With another embodiment of the present invention, a novel organic compound, a novel light-emitting device, a novel display device, a novel display module, and a novel electronic device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIGS. 1A and 1B each illustrate a light-emitting device;

FIGS. 2A and 2B each illustrate a light-emitting device;

FIGS. 3A and 3B are, respectively, a top view and a cross-sectional view of a light-emitting apparatus;

FIGS. 4A to 4E are cross-sectional views illustrating an example of a method for manufacturing a display device;

FIGS. 5A and 5B are cross-sectional views illustrating the example of a method for manufacturing the display device;

FIGS. 6A to 6D are cross-sectional views illustrating the example of a method for manufacturing the display device;

FIGS. 7A to 7C are cross-sectional views illustrating the example of a method for manufacturing the display device;

FIGS. 8A to 8C are cross-sectional views illustrating the example of a method for manufacturing the display device;

FIGS. 9A to 9C are cross-sectional views illustrating the example of a method for manufacturing the display device;

FIGS. 10A and 10B are perspective views illustrating a structure example of a display module;

FIGS. 11A and 11B are cross-sectional views illustrating structure examples of a display device;

FIG. 12 is a perspective view illustrating a structure example of a display device;

FIG. 13 is a cross-sectional view illustrating a structure example of a display device;

FIG. 14 is a cross-sectional view illustrating a structure example of a display device;

FIG. 15 is a cross-sectional view illustrating a structure example of a display device;

FIGS. 16A to 16D illustrate examples of electronic devices;

FIGS. 17A to 17F illustrate examples of electronic devices;

FIGS. 18A to 18G illustrate examples of electronic devices;

FIGS. 19A to 19C show results of analyzing spin density distribution in composite materials in a ground state;

FIGS. 20A and 20B show results of analyzing electrostatic potential maps of organic compounds in a ground state;

FIGS. 21A to 21C show results of analyzing electrostatic potential maps of composite materials in a ground state;

FIGS. 22A and 22B each illustrate a light-emitting device;

FIGS. 23A to 23C are cross-sectional views illustrating structure examples of a display device;

FIGS. 24A to 24C are cross-sectional views illustrating structure examples of a display device;

FIG. 25 shows luminance-current density characteristics of light-emitting devices 1-1 and 1-2 and a comparative light-emitting device 1;

FIG. 26 shows luminance-voltage characteristics of the light-emitting devices 1-1 and 1-2 and the comparative light-emitting device 1;

FIG. 27 shows current efficiency-current density characteristics of the light-emitting devices 1-1 and 1-2 and the comparative light-emitting device 1;

FIG. 28 shows current density-voltage characteristics of the light-emitting devices 1-1 and 1-2 and the comparative light-emitting device 1;

FIG. 29 shows electroluminescence spectra of the light-emitting devices 1-1 and 1-2 and the comparative light-emitting device 1;

FIG. 30 shows luminance-current density characteristics of light-emitting devices 2-1 and 2-2 and comparative light-emitting devices 2-1 and 2-2;

FIG. 31 shows luminance-voltage characteristics of the light-emitting devices 2-1 and 2-2 and the comparative light-emitting devices 2-1 and 2-2;

FIG. 32 shows current efficiency-current density characteristics of the light-emitting devices 2-1 and 2-2 and the comparative light-emitting devices 2-1 and 2-2;

FIG. 33 shows current density-voltage characteristics of the light-emitting devices 2-1 and 2-2 and the comparative light-emitting devices 2-1 and 2-2;

FIG. 34 shows electroluminescence spectra of the light-emitting devices 2-1 and 2-2 and the comparative light-emitting devices 2-1 and 2-2; and

FIG. 35 shows a relation between the LUMO level of the second organic compound and an increase in voltage due to processing by a photolithography technique.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

In this specification and the like, a device manufactured using a metal mask or a fine metal mask (FMM) is sometimes referred to as a device having a metal mask (MM) structure. In this specification and the like, a device manufactured without using a metal mask or an FMM is sometimes referred to as a device having a metal maskless (MML) structure.

### Embodiment 1

As a method for forming an organic semiconductor film in a predetermined shape, a vacuum evaporation method with a metal mask (mask vapor deposition) is widely used. However, in these days of higher density and higher resolution, mask vapor deposition has come close to the limit of increasing the resolution for various reasons such as the alignment accuracy and the distance between the mask and the substrate. An organic semiconductor device having a finer pattern is expected to be achieved by shape processing of an organic semiconductor film by a photolithography technique. Moreover, since a photolithography technique achieves large-area processing more easily than mask vapor deposition, processing of an organic semiconductor film by the photolithography technique is being researched.

It has been known that EL layers in an organic EL device exposed to atmospheric components such as water and oxygen have affected initial characteristics or reliability, and thus have been treated in a near-vacuum atmosphere in common-sense steps.

In particular, an electron-injection layer in a light-emitting device, which often includes an alkali metal, an alkaline earth metal, or a compound thereof (hereinafter also referred to as a Li compound or the like) highly reactive with water or oxygen, rapidly deteriorates and loses the function as the electron-injection layer when being exposed to the atmosphere.

However, processing steps with the aforementioned photolithography technique inevitably expose the surface of the EL layer to the air. The processing with the photolithography technique therefore causes a significant deterioration of the electron-injection properties of an electron-injection layer using an alkali metal compound or the like. Thus, an organic EL device that includes an electron-injection layer using an alkali metal compound or the like and is processed by a photolithography technique has increased driving voltage and is hard to obtain favorable characteristics.

Here, the present inventors have found that an organic EL device with favorable characteristics can be obtained even through a photolithography process involving exposure of an EL layer to the air, as the electron-injection layer, by using, a layer containing a metal or an oxide of the metal, an organic compound (a first organic compound) including a first π-electron deficient heteroaromatic ring with an electron-donating group, and an organic compound (a second organic compound) including a second π-electron deficient heteroaromatic ring.

That is, an organic EL device with favorable characteristics can be obtained even through a photolithography process involving exposure of an EL layer to the air, as the electron-injection layer, by using, a layer containing a metal or an oxide of the metal, an organic compound including a first π-electron deficient heteroaromatic ring with an electron-donating group, and an organic compound including a second π-electron deficient heteroaromatic ring.

In one embodiment of the present invention, the LUMO level of the second organic compound is preferably lower than that of the first organic compound by greater than or equal to 0.20 eV and less than or equal to 0.80 eV, further preferably by greater than or equal to 0.20 eV and less than or equal to 0.50 eV, still further preferably by greater than or equal to 0.25 eV and less than or equal to 0.50 eV, yet further preferably by greater than or equal to 0.30 eV and less than or equal to 0.50 eV, yet still further preferably by greater than or equal to 0.35 eV and less than or equal to 0.50 eV, yet still further preferably by greater than or equal to 0.40 eV and less than or equal to 0.50 eV.

That is, when the LUMO level of the first organic compound is “LUMO1 (eV)” and the LUMO level of the second organic compound is “LUMO2 (eV)”, the LUMO2 preferably satisfies the following Formula (1):

$$LUMO 1 - 0.8 \leq LUMO 2 \leq LUMO 1 - 0.2 \qquad Formula ( 1 )$$

Further preferably, the LUMO2 satisfies the following Formula (2):

$$LUMO 1 - 0.5 \leq LUMO 2 \leq LUMO 1 - 0.2 \qquad Formula ( 2 )$$

Further preferably, the LUMO2 satisfies the following Formula (3):

$$LUMO 1 - 0.5 \leq LUMO 2 \leq LUMO 1 - 0.25 \qquad Formula ( 3 )$$

Further preferably, the LUMO2 satisfies the following Formula (4):

$$LUMO 1 - 0.5 \leq LUMO 2 \leq LUMO 1 - 0.3 \qquad Formula ( 4 )$$

Further preferably, the LUMO2 satisfies the following Formula (5):

$$LUMO 1 - 0.5 \leq LUMO 2 \leq LUMO 1 - 0.35 \qquad Formula ( 5 )$$

Further preferably, the LUMO2 satisfies the following Formula (6):

$$LUMO 1 - 0.5 \leq LUMO 2 \leq LUMO 1 - 0.4 \qquad Formula ( 6 )$$

When the LUMO2 is within any of the above ranges, the light-emitting device of one embodiment of the present invention can be a light-emitting device having favorable characteristics with a low driving voltage regardless of whether a photolithography process involving exposure of an EL layer to the air is performed or not. Furthermore, the light-emitting device can have high reliability.

The metal or the metal oxide, the first organic compound, and the second organic compound form a donor level (SOMO level or HOMO level) when interacting with each other. This lowers the barrier against electron injection to an electron-transport layer, whereby electrons can be smoothly injected and transported to the electron-transport layer without using a conventional electron-injection layer, which significantly deteriorates when subjected to an unstable photolithography process involving exposure to the air. Furthermore, the LUMO2 within any of the above ranges allows the interaction to be more stable, so that an electron-injection layer that does not easily deteriorate even when subjected to a photolithography process involving exposure to the air can be formed. Thus, electrons can be smoothly injected and transported to the electron-transport layer even when a photolithography process involving exposure of an EL layer to the air is performed, so that a highly reliable light-emitting device with a suppressed increase in driving voltage can be manufactured through a photolithography process.

Note that the HOMO level and the LUMO level of an organic compound are generally estimated by cyclic voltammetry (CV), photoelectron spectroscopy, optical absorption spectroscopy, inverse photoemission spectroscopy, or the like. When values of different compounds are compared with each other, it is preferable that values estimated by the same measurement be used.

As described above, when an electron-injection layer is formed using the organic compound (the first organic compound) including the first π-electron deficient heteroaromatic ring with an electron-donating group, the organic compound (the second organic compound) including the second π-electron deficient heteroaromatic ring, and the metal or the metal oxide, the electron-injection layer can have resistance to oxygen and water in the air and water and a chemical solution used in the photolithography process. Thus, one embodiment of the present invention can provide a light-emitting device having high moisture resistance, high water resistance, high oxygen resistance, high chemical resistance, a low driving voltage, and high emission efficiency.

For the structure of the electron-injection layer containing the organic compound (the first organic compound) including the first π-electron deficient heteroaromatic ring with an electron-donating group, the organic compound (the second organic compound) including the second π-electron deficient heteroaromatic ring, and the metal or the metal oxide, a mixed layer of the first organic compound, the second organic compound, and the metal or the metal oxide is preferable. A stacked-layer structure of a layer containing a metal and a layer containing the first organic compound and the second organic compound is also suitable.

In the case where the stacked-layer structure of the layer containing a metal and the layer containing the first organic compound and the second organic compound is employed, it is preferable that the layer containing a metal and the layer containing the first organic compound and the second organic compound be stacked on the cathode side and the anode side, respectively, to be in contact with each other and the layer containing the first organic compound and the second organic compound be in contact with the electron-transport layer.

When being the mixed layer of the first organic compound, the second organic compound, and the metal or the metal oxide, the electron-injection layer can have a smaller number of layers than the stacked-layer structure, and thus is highly productive and easy to mass produce.

An organic EL device that includes a conventional electron-injection layer formed using an alkali metal, an alkaline earth metal, or an oxide thereof such as lithium oxide (Li₂O) exhibits favorable characteristics when manufactured through a continuous vacuum process. Meanwhile, when manufactured through a photolithography process involving exposure of an EL layer to the air, the light-emitting device that includes the electron-injection layer containing an alkali metal, an alkaline earth metal, or an oxide thereof has a much higher driving voltage than a light-emitting device manufactured through a continuous vacuum process, as described above. This is probably because, as described above, an oxide of an alkali metal or an alkaline earth metal deteriorates due to the exposure to the air and the donor property decreases.

That is, in another embodiment of the present invention, an oxide of an alkali metal or an alkaline earth metal such as lithium oxide (Li₂O), an organic compound (the first organic compound) including a first π-electron deficient heteroaromatic ring with an electron-donating group, and an organic compound (the second organic compound) including a second π-electron deficient heteroaromatic ring are used for an electron-injection layer; thus, even when manufactured through a photolithography process involving exposure to the air, an organic EL device can exhibit favorable characteristics comparable to those of a light-emitting device manufactured by a continuous vacuum process.

This is because, when the alkaline metal, the alkaline earth metal, or the oxide thereof, the first organic compound including the first π-electron deficient heteroaromatic ring with an electron-donating property, and the second organic compound including the second π-electron deficient heteroaromatic ring are used for the electron-injection layer, a donor level (SOMO level or HOMO level) is formed by their interaction, but the absolute value of the stabilization energy by the interaction is large and stable and the donor level is high, which can lower the barrier against electron injection from the electron-injection layer to the electron-transport layer even after exposure to the air and enables smooth injection and transport of electrons to the electron-transport layer. It is thus possible to obtain an organic EL device having favorable characteristics and a suppressed increase in driving voltage even when exposure to the air is performed.

As described above, by using the light-emitting device of one embodiment of the present invention, which includes the layer containing the metal or the metal oxide, the organic compound (the first organic compound) including the first π-electron deficient heteroaromatic ring with an electron-donating group, and the organic compound (the second organic compound) including the second π-electron deficient heteroaromatic ring as the electron-injection layer, the organic EL device having favorable characteristics even when manufactured through a process involving exposure of an EL layer to the air can be obtained. That is, the use of the structure of one embodiment of the present invention offers an organic EL device with favorable characteristics, which is manufactured through a photolithography process involving exposure of an EL layer to the air. As a result, a display device with extremely high resolution and favorable characteristics can be provided.

### <<Electron-Injection Layer>>

As described above, the electron-injection layer is provided between the cathode and the light-emitting layer and contains the metal or the metal oxide, the organic compound (the first organic compound) including the first π-electron deficient heteroaromatic ring with an electron-donating group, and the organic compound (the second organic compound) including the second π-electron deficient heteroaromatic ring.

### <Metal or Metal Oxide>

As the metal or the metal oxide included in the electron-injection layer, a metal or an oxide thereof containing an alkali metal (Group 1 element) such as Li, an alkaline earth metal (Group 2 element) such as Mg or Ca, a Group 3 element including Y and lanthanoids such as Eu and Yb, a Group 11 element such as Cu, Ag, or Au, an earth metal (Group 13 element) such as Al or In, or a Group 14 element such as Sn can be used.

An alkali metal, an alkaline earth metal, or an oxide thereof is preferably used as the metal or the metal oxide, in which case the donor level formed by interaction with the first organic compound and the second organic compound can be a high energy level. Accordingly, electrons can be smoothly injected and transported from the cathode to the electron-injection layer, enabling the light-emitting device to have a low driving voltage and emit light with high emission efficiency. A transition metal and an oxide of the transition metal is preferable because it has low reactivity with components of the air such as water and oxygen. Among the above materials, a metal and a metal oxide containing an element belonging to an odd-numbered group (Group 1, 3, 11, or 13) in the periodic table is preferably used, in which case the interaction with the first organic compound and the second organic compound is likely to occur so that the donor level is easily formed.

A metal or an oxide of the metal that has a low melting point and can be deposited by a vacuum evaporation method is preferably used because it can be easily mixed or stacked with an organic compound. Specifically, for example, the metals belonging to Groups 11 and 13 and oxides thereof have low melting points, and thus can be suitably used for vacuum evaporation. The metals belonging to Groups 11 and 13 and oxides thereof are preferable because they are stable with respect to oxygen and water in the air. The metal or the metal oxide that can be deposited by a vacuum evaporation method preferably has a normal-pressure melting point lower than or equal to 2000° C., further preferably lower than or equal to 1500° C., still further preferably lower than or equal to 1000° C., or a reduced-pressure (vacuum with 1 Pa or less) sublimation temperature lower than or equal to 1500° C., further preferably lower than or equal to 1000° C., still further preferably lower than or equal to 500° C.

Specifically, lithium, magnesium, calcium, silver, indium, an oxide thereof, or the like can be used as the metal or the metal oxide, for example. Note that even when used alone, a metal might be oxidized in a deposition step or an air exposure step to become an oxide of the metal.

Specifically, as such a metal material, lithium, magnesium, calcium, ytterbium, silver, aluminum, or indium is particularly preferable.

### <First Organic Compound>

As the first organic compound contained in the electron-injection layer, an organic compound including a π-electron deficient heteroaromatic ring can be used. As the first organic compound, an organic compound including a π-electron deficient heteroaromatic ring with an electron-donating group is preferably used, in which case the electron density of the π-electron deficient heteroaromatic ring can be increased.

An organic compound including a heteroaromatic ring containing nitrogen is preferable as the organic compound including a π-electron deficient heteroaromatic ring, a pyridine ring is preferable as the heteroaromatic ring containing nitrogen, and an organic compound including a heteroaromatic ring having two or more pyridine rings is particularly preferable as the organic compound including a π-electron deficient heteroaromatic ring. This is because two nitrogen atoms contained in the organic compound including the heteroaromatic ring having two or more pyridine rings are coordinated to a metal or an oxide of the metal to facilitate interaction with the metal or the metal oxide.

Among organic compounds including a heteroaromatic ring having two or more pyridine rings, an organic compound having a bipyridine skeleton, the nitrogen atoms of which are coordinated to a metal or an oxide of the metal more easily, is particularly preferably used to facilitate interaction with the metal or the metal oxide. A phenanthroline ring, which is rigid and stable, is further preferably used. In particular, an organic compound including a 1,10-phenanthroline ring, the two nitrogen atoms of which are positioned to be easily coordinated to a metal or an oxide of the metal, is preferably used to facilitate interaction with the metal or the metal oxide.

In the case where an electron-donating group is introduced to a 1,10-phenanthroline ring, the electron-donating group is preferably substituted at the 4- and 7-positions of the 1,10-phenanthroline ring. Introducing an electron-donating group to the 4- and 7-positions of the 1,10-phenanthroline ring can increase the electron density of the nitrogen atoms at the 1- and 10-positions, thereby facilitating the interaction with the metal and the metal oxide.

Examples of the electron-donating group included in the π-electron deficient heteroaromatic ring include an alkyl group, an alkoxy group, an aryloxy group, an alkylamino group, an arylamino group, and a heterocyclic amino group. Note that examples of the electron-donating group that is preferably introduced to the π-electron deficient heteroaromatic ring are not limited to the above examples. Any group that can increase the electron density of the π-electron deficient heteroaromatic ring when introduced thereto can be used as the electron-donating group. The electron-donating group may be introduced to the π-electron deficient heteroaromatic ring via an arylene group such as a phenylene group, and the arylene group is preferably a p-phenylene group.

Specific examples of the alkyl group that can be used as the electron-donating group include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, and a 2,3-dimethylbutyl group.

Specific examples of the alkoxyl group that can be used as the electron-donating group include a methoxy group, an ethoxy group, an n-propoxy group, an isopropoxy group, an n-butoxy group, a sec-butoxy group, an isobutoxy group, a tert-butoxy group, an n-pentyloxy group, an isopentyloxy group, a sec-pentyloxy group, a tert-pentyloxy group, a neopentyloxy group, an n-hexyloxy group, an isohexyloxy group, a sec-hexyloxy group, a tert-hexyloxy group, and a neohexyloxy group.

Specific examples of the aryloxy group that can be used as the electron-donating group include a phenoxy group, an o-tolyloxy group, a m-tolyloxy group, a p-tolyloxy group, a mesityloxy group, an o-biphenyloxy group, a m-biphenyloxy group, a p-biphenyoxyl group, a 1-naphthyloxy group, a 2-naphthyloxy group, and a 2-fluorenyloxy group. Note that the aryloxy group may further have a substituent, and specific examples of the substituent include an alkyl group, an alkoxy group, and a phenyl group.

Specific examples of the alkylamino group that can be used as the electron-donating group include a dimethylamino group and a diethylamino group.

Specific examples of the arylamino group that can be used as the electron-donating group include a diphenylamino group, a bis(α-naphthyl)amino group, and a bis(m-tolyl)amino group. Note that the arylamino group may further have a substituent, and specific examples of the substituent include an alkyl group, an alkoxy group, and a phenyl group.

Specific examples of the heterocyclic amino group that can be used as the electron-donating group include groups represented by Structural Formulae (R-1) to (R-26) below. Note that the heterocyclic amino group may further have a substituent, and specific examples of the substituent include an alkyl group, an alkoxy group, and a phenyl group.

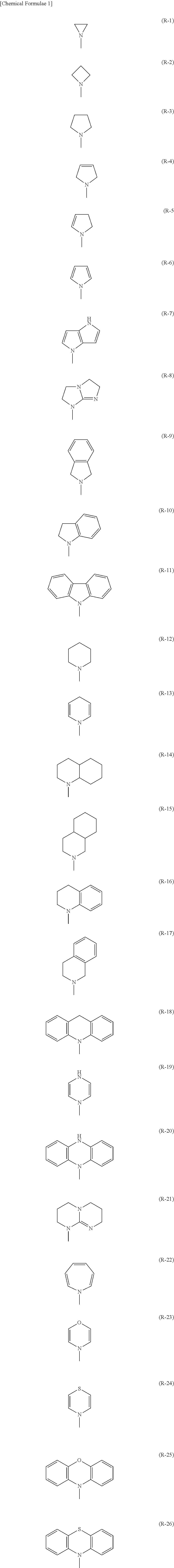

Note that the group represented by Structural Formula (R-1), (R-2), (R-3), (R-4), (R-5), (R-8), (R-9), (R-10), (R-12), (R-14), (R-15), (R-16), (R-17), or (R-21) is further preferably used as the electron-donating group. Among these groups, the group represented by Structural Formula (R-3), (R-4), (R-8), or (R-21) is preferably used because the group has a high electron-donating property and can further increase the electron density of the phenanthroline ring.

Specific examples of the electron-donating group include groups represented by Structural Formulae (R-27) and (R-28) below.

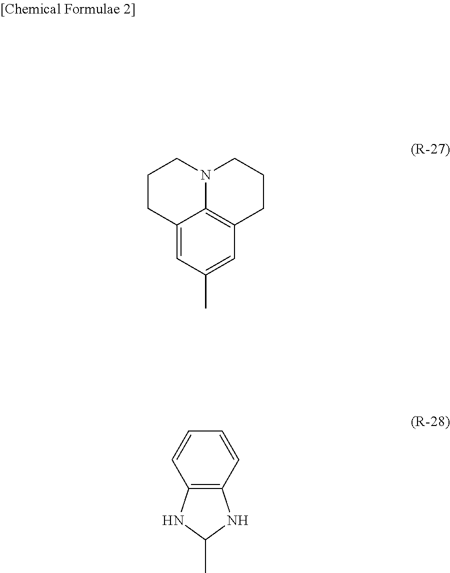

Note that an organic compound including a π-electron deficient heteroaromatic ring that can be used as the first organic compound may have both the above-described electron-donating group and another substituent. Specific examples of the substituent that can be introduced to the π-electron deficient heteroaromatic ring together with the above electron-donating group include an aryl group. Specific examples of the aryl group include a phenyl group, an o-tolyl group, a m-tolyl group, a p-tolyl group, a mesityl group, an o-biphenyl group, a m-biphenyl group, a p-biphenyl group, a 1-naphthyl group, a 2-naphthyl group, and a 2-fluorenyl group. Note that the aryl group may further have a substituent, and specific examples of the substituent include an alkyl group, an alkoxy group, and a phenyl group.

Specific examples of an organic compound including a π-electron deficient heteroaromatic ring that can be used as the first organic compound are represented by Structural Formulae (100) to (111). Note that the organic compound that can be used as the first organic compound is not limited to those examples.

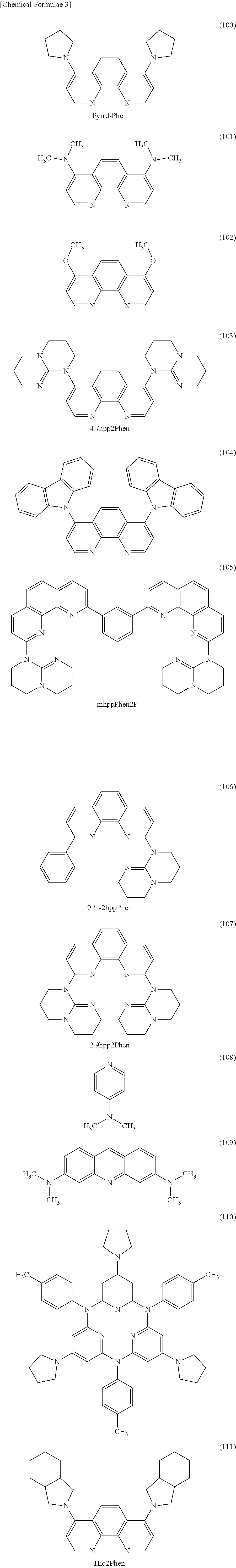

The negative minimum value of the electrostatic potential (ESP) of the first organic compound is preferably small (i.e., the minimum value is preferably a negative value the absolute value of which is large), in which case the absolute value of the stabilization energy by the interaction with the metal or the metal oxide is high.

In an organic compound including a π-electron deficient heteroaromatic ring, the electrostatic potential around the hetero atoms of the π-electron deficient heteroaromatic ring, which is likely to be negative, can be further lowered (i.e., the absolute value of the negative value can be increased) by introduction of an electron-donating group to the π-electron deficient heteroaromatic ring.

Note that an electrostatic potential is the energy of interaction between positive point charge with unit quantity of electricity and electron distribution of a molecule. An electrostatic potential value also depends on the threshold value of electron density.

To increase the efficiency of the interaction with the metal or the metal oxide, the minimum value of the electrostatic potential of the first organic compound is preferably smaller (negatively larger) than the minimum value of the electrostatic potential of a π-electron deficient heteroaromatic ring having no substituent.

Specifically, when the threshold value of electron density distribution in atomic units is 0.0004 e/a₀³ (e represents elementary charge (1 e=1.60218×10⁻¹⁹ C) and a₀ represents a Bohr radius (1 a₀=5.29177×10⁻¹¹ m)), the minimum value of the electrostatic potential of the first organic compound is preferably smaller than or equal to −0.085 Eₕ (Eₕ represents the Hartree energy (1 Eₕ=27.211 eV)), further preferably smaller than or equal to −0.090 Eₕ. When the threshold value of electron density distribution is 0.003 e/a₀³, the minimum value of the electrostatic potential of the first organic compound is preferably smaller than or equal to −0.12 Eₕ, further preferably smaller than or equal to −0.13 Eₕ. When the threshold value of electron density distribution is 0.0004 e/a₀³, the minimum value of the ESP of the first organic compound is preferably smaller than or equal to −0.085 Eₕ, further preferably smaller than or equal to −0.12 Eₕ when the threshold value of electron density distribution is 0.003 e/a₀³.

The minimum values of the electrostatic potentials (ESP) of the above organic compounds represented by Structural Formulae (100) to (107) above and Structural Formula (111), which can be used as the first organic compound, BPhen, mPPhen2P, NBPhen, and Phen were estimated by quantum chemical calculation. The organic compounds represented by Structural Formulae (100) to (107), the organic compound represented by Structural Formula (111), and Structural Formulae of BPhen, mPPhen2P, NBPhen, and Phen are shown below.

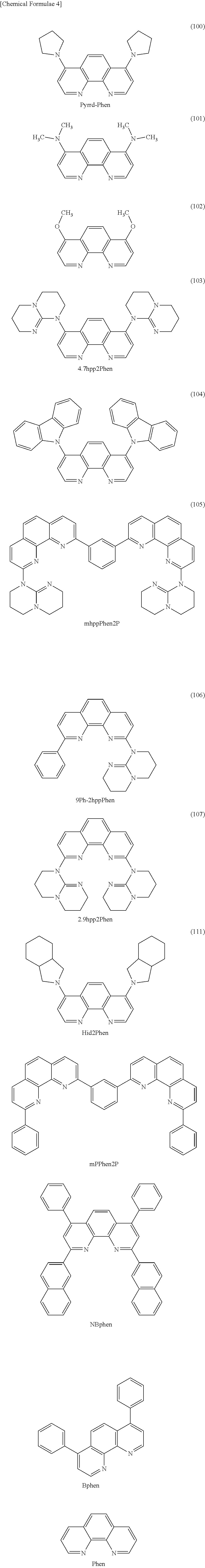

As the quantum chemistry computational program, Gaussian 09 was used. The calculation was performed using SGI 8600 manufactured by Hewlett Packard Enterprise. The most stable structures of the organic compounds in a ground state were calculated by the density functional theory (DFT). As a basis function, 6-311G(d,p) was used, and as a functional, B3LYP was used.

Table 1 shows the analysis results of the electrostatic potentials of the organic compounds in a ground state. Note that an electrostatic potential is the energy of interaction between positive point charge with unit quantity of electricity and electron distribution of a molecule. An electrostatic potential value also depends on the threshold value of electron density. Table 1 shows the electrostatic potentials in electron density distribution at the time when the density threshold value in atomic units is 0.0004 e/a₀³ or 0.003 e/a₀³.

TABLE 1

| | The minimum value | The minimum value |
|---|---|---|
| | of ESP (Eₕ) | of ESP (Eₕ) |
| | (the density | (the density |
| | threshold = 0.0004 e/a₀³) | threshold = 0.003 e/a₀³) |
| Pyrrd-Phen (100) | −0.091 | −0.12 |
| DMeAPhen (101) | −0.089 | −0.12 |
| p-MeO-Phen (102) | −0.089 | −0.12 |
| 4,7hpp2Phen (103) | −0.096 | −0.13 |
| CzPhen (104) | −0.072 | −0.10 |
| mhppPhen2P (105) | −0.057 | −0.096 |
| 9Ph2hppPhen (106) | −0.057 | −0.096 |
| 2,9hpp2Phen (107) | −0.061 | −0.097 |
| Bphen | −0.083 | −0.11 |
| mPPhen2P | −0.057 | −0.094 |
| NBphen | −0.053 | −0.093 |
| Phen | −0.081 | −0.110 |
| Hid2Phen (111) | −0.094 | −0.13 |

From the above table, it is found that the minimum values of ESP of the organic compounds represented by Structural Formulae (100) to (103) and Structural Formula (111) are each smaller than or equal to −0.085 Eₕ when the threshold value of electron density distribution in atomic units is 0.0004 e/a₀³ and that these organic compounds are further preferably used as the first organic compound. It is also found that the minimum values of ESP of the organic compounds represented by Structural Formulae (100) to (103) and Structural Formula (111) are each smaller than or equal to −0.12 Eₕ when the threshold value of electron density distribution in atomic units is 0.003 e/a₀³ and that these organic compounds are further preferably used as the first organic compound.

This is because the organic compounds represented by Structural Formulae (100) to (103) and Structural Formula (111) have an electron-donating group at each of the 4- and 7-positions of the 1,10-phenantholine ring and thus has a high property of donating electrons to the nitrogen atoms at the 1- and 10-positions of the phenanthroline ring.

It is found that the minimum values of ESP of the organic compounds represented by Structural Formulae (100), (103) and (111) are each smaller than or equal to −0.090 Eₕ when the threshold value of electron density distribution in atomic units is 0.0004 e/a₀³ and that these organic compounds are particularly preferably used as the first organic compound. It is also found that the minimum values of ESP of the organic compounds represented by Structural Formula (103) and Structural Formula (111) are each smaller than or equal to −0.13 Eₕ when the threshold value of electron density distribution in atomic units is 0.003 e/a₀³ and that these organic compounds are particularly preferably used as the first organic compound.

It is found that the organic compounds represented by Structural Formula (103) and Structural Formula (111) are further preferably used as the first organic compound because their minimum values of the ESP are each smaller than or equal to −0.090 Eₕ when the threshold value of electron density distribution in atomic units is 0.0004 e/a₀³, and smaller than or equal to −0.13 Eₕ when the threshold value of electron density distribution in atomic units is 0.003 e/a₀³.

The first organic compound is preferably strongly basic, in which case the first organic compound interacts with holes to significantly reduce the hole-transport property in the electron-injection layer, enabling the light-emitting device to have high efficiency and a low driving voltage. Specifically, the acid dissociation constant pKₐ of the first organic compound is preferably higher than or equal to 8, further preferably higher than or equal to 10, still further preferably higher than or equal to 12.

In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound.

The acid dissociation constant may be obtained by calculation. For example, the acid dissociation constant pKₐ can be obtained by the following calculation method.

The initial structure of a molecule serving as a calculation model is the most stable structure (the singlet ground state) obtained from first-principles calculation.

For the first-principles calculation, Jaguar, which is the quantum chemical computational software manufactured by SchrÖdinger, Inc., is used, and the most stable structure in the singlet ground state is calculated by the density functional theory (DFT). As a basis function, 6-31G** is used, and as a functional, B3LYP-D3 is used. The structure subjected to quantum chemical calculation is sampled by conformational analysis in mixed torsional/low-mode sampling with Maestro GUI produced by SchrÖdinger, Inc.

In the calculation of pKₐ, one or more atoms in each molecule are designated as basic sites, MacroModel is used to search for the stable structure of the protonated molecule in water, conformational search is performed with OPLS2005 force field, and a conformational isomer having the lowest energy is used. Jaguar's pKₐ calculation module is used. After structure optimization is performed by B3LYP/6-31G*, single point calculation is performed by cc-pVTZ(+) and the pKₐ value is calculated using empirical correction for functional group(s). In the case where one or more atoms are designated as basic sites in a molecule, the largest of obtained values is used as a pKₐ value. The obtained pKₐ values are shown below.

The acid dissociation constant pKₐ of 2,9hpp2Phen is 13.35, that of 4,7hpp2Phen is 13.42, that of Pyrrd-Phen is 11.23, that of mPPhen2P is 5.16, that of NBPhen is 5.59, and that of BPhen is 5.62.

### <Estimation of Interaction Between Metal and Organic Compound by Quantum Chemical Calculation>

The spin density and the electrostatic potential (ESP) at the time of interaction between a metal, the first organic compound having an electron-donating group and a π-electron deficient heteroaromatic ring, and the second organic compound including a π-electron deficient heteroaromatic ring were analyzed by quantum chemical calculation. The calculation was performed using 4,7-di-1-pyrrolidinyl-1,10-phenanthroline (abbreviation: Pyrrd-Phen) as the first organic compound, 11-[3′-(dibenzothiophen-4-yl)biphenyl-3-yl]phenanthro[9′,10′:4,5]furo[2,3-b]pyrazine (abbreviation: 11mDBtBPPnfpr) as the second organic compound, and silver (Ag) as the metal.

As the quantum chemistry computational program, Gaussian 09 was used. The calculation was performed using SGI 8600 manufactured by Hewlett Packard Enterprise. The most stable structures of the first organic compound alone in a ground state, the second organic compound alone in a ground state, a composite material of the first organic compound and the metal in a ground state, a composite material of the second organic compound and the metal in a ground state, and a composite material of the first organic compound, the second organic compound, and the metal in a ground state were calculated by the density functional theory (DFT). As basis functions, 6-311G(d,p) and LanL2DZ were used, and as a functional, B3LYP was used. In the DFT, the total energy is represented as the sum of potential energy, electrostatic energy between electrons, electronic kinetic energy, and exchange-correlation energy including all the complicated interactions between electrons. Also in the DFT, exchange-correlation interaction is approximated by a functional (a function of another function) of one electron potential represented in terms of electron density to enable highly accurate calculations.

FIGS. 19A and 19B respectively show the analysis results of spin density distribution in the composite material of the first organic compound (Pyrrd-Phen) and the metal (Ag) in a ground state, the composite material of the second organic compound (11mDBtBPPnfpr) and the metal (Ag) in a ground state, and the composite material of the first organic compound (Pyrrd-Phen), the second organic compound (11mDBtBPPnfpr), and the metal (Ag) in a ground state. In the diagrams, spheres represent atoms included in the compounds, and clouds around some of the atoms represent the spin density distribution when the threshold value of the electron density distribution in atomic units is 0.003 e/a₀³. The clouds represent localization of the doublet ground state of the compounds. Note that no spin density distribution is observed in the first organic compound (Pyrrd-Phen) in a ground state and the second organic compound (11mDBtBPPnfpr) in a ground state because the ground states of the first organic compound and the second organic compound are singlet ground states.

In the composite material of the first organic compound (Pyrrd-Phen) and the metal (Ag) in the doublet ground state, the first organic compound (Pyrrd-Phen) interacts with the metal (Ag), and the metal (Ag) is coordinated to the nitrogen atoms having unshared electron pairs (the nitrogen atoms (N) at the 1- and 10-positions) in the 1,10-phenanthroline ring of the first organic compound (Pyrrd-Phen), which leads to stabilization and the formation of the composite material. As illustrated in FIG. 19A, some spins attributed to an unpaired electron of the metal (Ag) are accordingly distributed over part of the 1,10-phenanthroline ring of the first organic compound (Pyrrd-Phen), particularly the nitrogen atoms having unshared electron pairs (the nitrogen atoms (N) at the 1- and 10-positions). However, the interaction is weak, and thus, most spins are distributed over the metal (Ag).

In the composite material of the second organic compound (11mDBtBPPnfpr) and the metal (Ag) in the doublet ground state, the second organic compound (11mDBtBPPnfpr) interacts with the metal (Ag), and the metal (Ag) is coordinated to the nitrogen atoms (N) having unshared electron pairs in the phenanthro[9′,10′:4,5]furo[2,3-b]pyrazine ring of the second organic compound (11mDBtBPPnfpr), which leads to stabilization and formation of the composite material. As illustrated in FIG. 19B, some spins attributed to an unpaired electron of the metal (Ag) are accordingly distributed over part of the phenanthro[9′,10′:4,5]furo[2,3-b]pyrazine ring of the second organic compound (11mDBtBPPnfpr), specifically the nitrogen atoms (N) having unshared electron pairs. However, the interaction is weak, and thus, most spins are distributed over the metal (Ag).

Meanwhile, in the composite material of the first organic compound (Pyrrd-Phen), the second organic compound (11mDBtBPPnfpr), and the metal (Ag), which is one embodiment of the present invention, in the doublet ground state, the first organic compound (Pyrrd-Phen), the second organic compound (11mDBtBPPnfpr), and the metal (Ag) interact with one another, and the metal (Ag) is coordinated to the nitrogen atoms having unshared electron pairs (the nitrogen atoms (N) at the 1- and 10-positions) in the 1,10-phenanthroline ring of the first organic compound (Pyrrd-Phen) and the nitrogen atoms (N) having unshared electron pairs in the phenanthro[9′,10′:4,5]furo[2,3-b]pyrazine ring of the second organic compound (11mDBtBPPnfpr), which leads to stabilization and formation of the composite material. As illustrated in FIG. 19C, spins attributed to an unpaired electron of the metal (Ag) are accordingly localized in the second organic compound (11mDBtBPPnfpr). Furthermore, no spin density distribution is observed in the metal (Ag). It is thus found that the second organic compound (11mDBtBPPnfpr) is in a radical anion state owing to the interaction between the first organic compound (Pyrrd-Phen), the second organic compound (11mDBtBPPnfpr), and the metal (Ag).

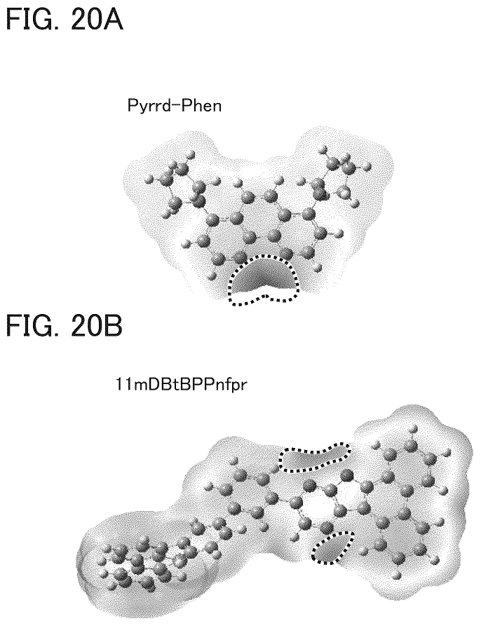

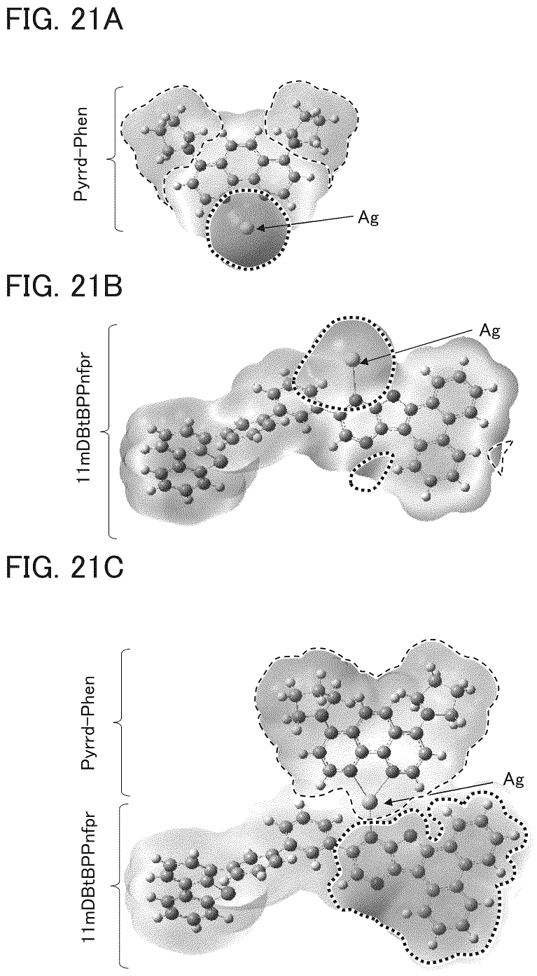

Next, FIGS. 20A and 20B and FIGS. 21A to 21C respectively show the analysis results of the electrostatic potential maps of the first organic compound (Pyrrd-Phen) in a ground state, the second organic compound (11mDBtBPPnfpr) in a ground state, the composite material of the first organic compound (Pyrrd-Phen) and the metal (Ag) in a ground state, the composite material of the second organic compound (11mDBtBPPnfpr) and the metal (Ag) in a ground state, and the composite material of the first organic compound (Pyrrd-Phen), the second organic compound (11mDBtBPPnfpr), and the metal (Ag) in a ground state. In the diagrams, spheres represent atoms included in the compounds, and clouds around some of the atoms represent electrostatic potentials in electron density distribution at the time when the threshold value of the electron density distribution in atomic units is 0.0004 e/a₀³. An electrostatic potential is the energy of interaction between positive point charge with unit quantity of electricity and electron distribution of a molecule. An electrostatic potential map denotes an electrostatic potential on an electron density isosurface in colors; in the map, a region with a negative electrostatic potential is denoted in red, a region with a positive electrostatic potential is denoted in blue, an atom in the region with a negative electrostatic potential has negative charge, and an atom in the region with a positive electrostatic potential has positive charge. To show a region with a negative electrostatic potential and a region with a positive electrostatic potential in FIGS. 20A and 20B and FIGS. 21A to 21C, which are grayscale images, a deep red portion (i.e., the region with a negative electrostatic potential) is surrounded by a thick dotted line, and a deep blue portion (i.e., the region with a positive electrostatic potential) is surrounded by a thin dashed-dotted line.

As shown in FIG. 20A, the electrostatic potential around the nitrogen atoms having unshared electron pairs (the nitrogen atoms (N) at the 1- and 10-positions) in the 1,10-phenanthroline ring of the first organic compound (Pyrrd-Phen) in the singlet ground state is negative. The N atoms each had a negative Mulliken partial charge of −0.29 e in atomic units. Accordingly, it is found that the N atoms have negative partial charge.

As shown in FIG. 20B, the electrostatic potential around the nitrogen atoms (N) having unshared electron pairs in the phenanthro[9′,10′:4,5]furo[2,3-b]pyrazine ring of the second organic compound (11mDBtBPPnfpr) in the singlet ground state is negative. The N atoms each had a negative Mulliken partial charge of −0.31 e in atomic units. Accordingly, it is found that the N atoms have negative partial charge.

In the composite material of the first organic compound (Pyrrd-Phen) and the metal (Ag) in the doublet ground state, the first organic compound (Pyrrd-Phen) interacts with the metal (Ag), and the metal (Ag) is coordinated to the nitrogen atoms having unshared electron pairs (the nitrogen atoms (N) at the 1- and 10-positions) in the 1,10-phenanthroline ring of the first organic compound (Pyrrd-Phen), which leads to stabilization and the formation of the composite material. As shown in FIG. 21A, the electrostatic potential around the nitrogen atoms having unshared electron pairs (the nitrogen atoms (N) at the 1- and 10-positions) in the 1,10-phenanthroline ring of the first organic compound (Pyrrd-Phen) and the metal (Ag) is accordingly negative. The N atoms each had a negative Mulliken partial charge of −0.37 e in atomic units and the metal (Ag) had a negative Mulliken partial charge of −0.18 e in atomic units. Accordingly, it is found that the N atoms and the Ag atom have negative partial charge.

In the composite material of the second organic compound (11mDBtBPPnfpr) and the metal (Ag) in the doublet ground state, the second organic compound (11mDBtBPPnfpr) interacts with the metal (Ag), and the metal (Ag) is coordinated to the nitrogen atoms (N) having unshared electron pairs in the phenanthro[9′,10′:4,5]furo[2,3-b]pyrazine ring of the second organic compound (11mDBtBPPnfpr), which leads to stabilization and formation of the composite material. As shown in FIG. 21B, the electrostatic potential around the nitrogen atoms (N) having unshared electron pairs in the phenanthro[9′,10′:4,5]furo[2,3-b]pyrazine ring of the second organic compound (11mDBtBPPnfpr) and the metal (Ag) is accordingly negative. The N atoms each had a negative Mulliken partial charge of −0.38 e in atomic units and the metal (Ag) had a negative Mulliken partial charge of −0.09 e in atomic units. Accordingly, it is found that the N atoms and the Ag atom have negative partial charge.

Meanwhile, in the composite material of the first organic compound (Pyrrd-Phen), the second organic compound (11mDBtBPPnfpr), and the metal (Ag), which is one embodiment of the present invention, in the doublet ground state, the first organic compound (Pyrrd-Phen), the second organic compound (11mDBtBPPnfpr), and the metal (Ag) interact with one another, and the metal (Ag) is coordinated to the nitrogen atoms having unshared electron pairs (the nitrogen atoms (N) at the 1- and 10-positions) in the 1,10-phenanthroline ring of the first organic compound (Pyrrd-Phen) and the nitrogen atoms (N) having unshared electron pairs in the phenanthro[9′,10′:4,5]furo[2,3-b]pyrazine ring of the second organic compound (11mDBtBPPnfpr), which leads to stabilization and formation of the composite material. Accordingly, as shown in FIG. 21C, a positive electrostatic potential is mainly distributed over the metal (Ag) and the first organic compound (Pyrrd-Phen), and a negative electrostatic potential is mainly distributed over the second organic compound (11mDBtBPPnfpr). It is also found that the electrostatic potential around the nitrogen atoms (N) having unshared electron pairs in the phenanthro[9′,10′:4,5]furo[2,3-b]pyrazine ring of the second organic compound (11mDBtBPPnfpr) is negative, whereas the electrostatic potential around the metal (Ag) is positive. The N atoms each had a negative Mulliken partial charge of −0.62 e in atomic units, whereas the metal (Ag) had a positive Mulliken partial charge of 0.37 e in atomic units. These results show that charge of the Ag atom is distributed over the N atoms.

From the above, it is found that the combination of the metal, the first organic compound including a π-electron deficient heteroaromatic ring with an electron-donating group, and the second organic compound including a π-electron deficient heteroaromatic ring is such that the first organic compound and the metal interact with each other to form a donor level and function as an electron donor with respect to the second organic compound. In one embodiment of the present invention, the electron-injection layer formed using the material including this combination can have a favorable electron-injection property and resistance to oxygen and water in the air and water and a chemical solution used during the process by a lithography method; thus, the light-emitting device can have a reduced driving voltage and high emission efficiency.

### <Estimation of SOMO or HOMO Level in Interaction Between Metal and Organic Compound by Quantum Chemical Calculation>

Next, stabilization energy at the time of interaction between a metal, the first organic compound including a π-electron deficient heteroaromatic ring with an electron-donating group, and the second organic compound including a π-electron deficient heteroaromatic ring and the SOMO or HOMO level formed at the time of the interaction were estimated by quantum chemical calculation.

As the quantum chemistry computational program, Gaussian 09 was used. The calculation was performed using SGI 8600 manufactured by Hewlett Packard Enterprise. First, the most stable structures of the first organic compound in a ground state, the second organic compound in a ground state, the metal in a ground state, the composite material of the first organic compound and the metal in a ground state, the composite material of the second organic compound and the metal in a ground state, and the composite material of the first organic compound, the second organic compound, and the metal in a ground state were calculated by the density functional theory (DFT). As basis functions, 6-311G(d,p) and LanL2DZ were used, and as a functional, B3LYP was used. Next, the stabilization energy was calculated by subtracting the sum of the total energy of the organic compound(s) alone and the total energy of the metal alone from the total energy of the composite material of the organic compound(s) and the metal. That is, (stabilization energy)=(the total energy of the composite material of the organic compound(s) and the metal)−(the total energy of the organic compound(s) alone)−(the total energy of the metal alone).

The following tables show the results of the calculation performed using 4,7-di-1-pyrrolidinyl-1,10-phenanthroline (abbreviation: Pyrrd-Phen) as the first organic compound, 2,9-di(naphthalen-2-yl)-4,7-diphenyl-1,10-phenanthroline (abbreviation: NBPhen), 9-[3′-(dibenzothiophen-4-yl)biphenyl-3-yl]naphtho[1′,2′:4,5]furo[2,3-b]pyrazine (abbreviation: 9mDBtBPNfpr), 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), 2-[3-(2,6-dimethyl-3-pyridinyl)-5-(9-phenanthrenyl)phenyl]-4,6-diphenyl-1,3,5-triazine (abbreviation: mPn-mDMePyPTzn), and 2-[4-(2-naphthalenyl)phenyl]-4-phenyl-6-spiro[9H-fluorene-9,9′-[9H]xanthen]-4-yl-1,3,5-triazine (abbreviation: PNP-SFx(4)Tzn) as the second organic compounds, and indium (In) as the metal. Note that the HOMO and SOMO energy levels in the tables are calculated values and might be different from measured values.

TABLE 2

| | HOMO level (eV) |
|---|---|
| Pyrrd-Phen | −5.65 |
| NBPhen | −5.74 |
| 9mDBtBPNfpr | −5.96 |
| 8mpTP4mDBtPBfpm | −5.94 |
| mPn-mDMePyPTzn | −5.96 |
| βNP-SFx(4)Tzn | −5.93 |

TABLE 3

| | Stabilization energy (eV) | SOMO level (eV) |
|---|---|---|
| NBphen + In | −1.5 | −3.28 |
| 9mDBtBPNfpr + In | −0.8 | −3.64 |
| 8mpTP4mDBtPBfpm + In | −0.8 | −3.69 |
| mPn-mDMePyPTzn + In | −0.6 | −3.08 |
| βNP-SFx(4)Tzn + In | −0.7 | −3.51 |

TABLE 4

| | Stabilization | SOMO |
|---|---|---|
| | energy (eV) | level (eV) |
| Pyrrd-Phen + NBPhen + In | −1.3 | −3.02 |
| Pyrrd-Phen + 9mDBtBPNfpr + In | −1.9 | −2.78 |
| Pyrrd-Phen + 8mpTP4mDBtPBfpm + In | −1.9 | −2.86 |
| Pyrrd-Phen + mPn-mDMePyPTzn + In | −1.9 | −2.99 |
| Pyrrd-Phen + βNP-SFx(4)Tzn + In | −1.8 | −2.86 |

The tables show that the stabilization energy of the composite material of two materials, the metal (In) and the second organic compound (NBPhen, 9mDBtBPNfpr, 8mpTP-4mDBtPBfpm, mPn-mDMePyPTzn, or βNP-SFx(4)Tzn), has a negative value; thus, when the organic compound and the metal are mixed, the state where the organic compound and the metal interact with each other is more energetically stable than the state where the organic compound and the metal do not interact with each other. In addition, the SOMO levels formed at the time of the interaction are higher than the HOMO level of the first organic compound (Pyrrd-Phen) and the HOMO level of the second organic compound (NBPhen, 9mDBtBPNfpr, 8mpTP-4mDBtPBfpm, mPn-mDMePyPTzn, or βNP-SFx(4)Tzn).

Note that the composite material of the metal (In) and the second organic compound (NBPhen) including a π-electron deficient heteroaromatic ring that is the same as the 1,10-phenanthroline ring of the first organic compound (Pyrrd-Phen) has a larger absolute value of the stabilization energy and thus is more stabilized than the composite material of the metal (In) and the second organic compound (9mDBtBPNfpr, 8mpTP-4mDBtPBfpm, mPn-mDMePyPTzn, or PNP-SFx(4)Tzn) including a π-electron deficient heteroaromatic ring that is different from the 1,10-phenanthroline ring. Thus, the SOMO level formed here is also high.

Meanwhile, the composite material of three materials, the metal (In), the first organic compound (Pyrrd-Phen), and the second organic compound (9mDBtBPNfpr, 8mpTP-4mDBtPBfpm, mPn-mDMePyPTzn, or PNP-SFx(4)Tzn), which is one embodiment of the present invention, has a larger absolute value of the stabilization energy and thus is more stabilized than the composite material of the two materials, the metal (In) and the second organic compound (9mDBtBPNfpr, 8mpTP-4mDBtPBfpm, mPn-mDMePyPTzn, or PNP-SFx(4)Tzn). The SOMO level formed here is higher than the HOMO level of the first organic compound (Pyrrd-Phen) and the HOMO level of the second organic compound (9mDBtBPNfpr, 8mpTP-4mDBtPBfpm, mPn-mDMePyPTzn, or PNP-SFx(4)Tzn). The SOMO level is preferably high to achieve a high electron-injection property.

Furthermore, the composite material of the metal (In), the first organic compound (Pyrrd-Phen), and the second organic compound (9mDBtBPNfpr, 8mpTP-4mDBtPBfpm, mPn-mDMePyPTzn, or PNP-SFx(4)Tzn) including a π-electron deficient heteroaromatic ring that is different from the 1,10-phenanthroline ring of the first organic compound (Pyrrd-Phen) has a larger absolute value of the stabilization energy and thus is more stabilized than the composite material of the metal (In), the first organic compound (Pyrrd-Phen), and the second organic compound (NBPhen) including a π-electron deficient heteroaromatic ring that is the same as the 1,10-phenanthrorine ring of the first organic compound (Pyrrd-Phen). Thus, the SOMO level formed here is further higher.

As described above, when the organic compound (the first organic compound) including the first π-electron deficient heteroaromatic ring with an electron-donating group, the organic compound (the second organic compound) including the second π-electron deficient heteroaromatic ring, and the metal interact with one another to form a composite material, the first π-electron deficient heteroaromatic ring is preferably different from the second π-electron deficient heteroaromatic ring for higher stability and a higher electron-injection property.

As shown in the above tables, the composite material of the metal, the first organic compound, and the second compound is preferable because it has a large absolute value of the stabilization energy and thus is stabilized. The SOMO level formed here is higher than the HOMO level of the first organic compound and the HOMO level of the second organic compound. The SOMO level is preferably high to achieve a high electron-injection property. A high SOMO level is formed even when a metal that is stable in the air, such as silver or indium, is used instead of an alkaline metal compound or the like, and thus an electron-injection layer with high stability and a high electron-injection property can be formed.

### <Second Organic Compound>

The electron-injection layer includes the second organic compound including a π-electron deficient heteroaromatic ring, in addition to the metal or the metal oxide and the first organic compound. The second organic compound can improve heat resistance, electron-transport properties, and the like. In one embodiment of the present invention, when the π-electron deficient heteroaromatic ring included in the first organic compound is referred to as the first π-electron deficient heteroaromatic ring and the π-electron deficient heteroaromatic ring included in the second organic compound is referred to as the second π-electron deficient heteroaromatic ring, the first π-electron deficient heteroaromatic ring and the second π-electron deficient heteroaromatic ring are preferably different rings.

As the second π-electron deficient heteroaromatic ring, a heteroaromatic ring having an azole skeleton (an imidazole ring, a pyrazole ring, an oxazole ring, a thiazole ring, a triazole ring, an oxadiazole ring, or a thiadiazole ring), a heteroaromatic ring having a pyridine skeleton, a heteroaromatic ring having a diazine skeleton, a heteroaromatic ring having a triazine skeleton, or the like is preferable, and a diazine ring (a pyrazine ring, a pyrimidine ring, or a pyridazine ring) or a triazine ring is particularly preferable because it is electrochemically stable and has a high electron-transport property.

Note that the second π-electron deficient heteroaromatic ring may have a fused ring structure.

In one embodiment of the present invention, the LUMO level of the second organic compound is preferably lower than that of the first organic compound by greater than or equal to 0.20 eV and less than or equal to 0.80 eV, further preferably by greater than or equal to 0.20 eV and less than or equal to 0.50 eV, still further preferably by greater than or equal to 0.25 eV and less than or equal to 0.50 eV, yet further preferably by greater than or equal to 0.30 eV and less than or equal to 0.50 eV, yet further preferably by greater than or equal to 0.35 eV and less than or equal to 0.50 eV, yet still further preferably by greater than or equal to 0.40 eV and less than or equal to 0.50 eV.

That is, when the LUMO level of the first organic compound is “LUMO1 (eV)” and the LUMO level of the second organic compound is “LUMO2 (eV)”, the LUMO2 preferably satisfies the following Formula (1):

$$LUMO 1 - 0.8 \leq LUMO 2 \leq LUMO 1 - 0.2 \qquad Formula ( 1 )$$

Further preferably, the LUMO2 satisfies the following Formula (2):

$$LUMO 1 - 0.5 \leq LUMO 2 \leq LUMO 1 - 0.2 \qquad Formula ( 2 )$$

Further preferably, the LUMO2 satisfies the following Formula (3):

$$LUMO 1 - 0.5 \leq LUMO 2 \leq LUMO 1 - 0.25 \qquad Formula ( 3 )$$

Further preferably, the LUMO2 satisfies the following Formula (4):

$$LUMO 1 - 0.5 \leq LUMO 2 \leq LUMO 1 - 0.3 \qquad Formula ( 4 )$$

Further preferably, the LUMO2 satisfies the following Formula (5):

$$LUMO 1 - 0.5 \leq LUMO 2 \leq LUMO 1 - 0.35 \qquad Formula ( 5 )$$

Further preferably, the LUMO2 satisfies the following Formula (6):

$$LUMO 1 - 0.5 \leq LUMO 2 \leq LUMO 1 - 0.4 \qquad Formula ( 6 )$$

When the LUMO2 is within any of the above ranges, the light-emitting device of one embodiment of the present invention can be a light-emitting device having favorable characteristics with a low driving voltage regardless of whether a photolithography process involving exposure of an EL layer to the air is performed or not. Furthermore, the light-emitting device can have high reliability.

As the second organic compound, an organic compound having an electron-transport property can be used. The organic compound having an electron-transport property is preferably a substance having an electron mobility higher than or equal to 1×10⁻⁷ cm²/Vs, further preferably higher than or equal to 1×10⁻⁶ cm²/Vs, when the square root of electric field strength [V/cm] is 600. Note that any other substance can also be used as long as the substance has an electron-transport property higher than a hole-transport property.

Specific examples of the organic compound having an electron-transport property include the following compounds: organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), 4,4′-bis(5-methylbenzoxazol-2-yl)stilbene (abbreviation: BzOs), 2-{4-[9,10-di(2-naphthyl)-2-anthryl]phenyl}-1-phenyl-1H-benzimidazole (abbreviation: ZADN), and 4,7-diphenyl-2,9-bis[4-(1-phenyl-1H-benzo[d]imidazol-2-yl)phenyl]-1,10-phenanthroline (abbreviation: DBimiBphen); organic compounds having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-{3-[3-(N-phenyl-9H-carbazol-3-yl)-9H-carbazol-9-yl]phenyl}dibenzo[f,h]quinoxaline (abbreviation: 2mPCCzPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(PN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP—PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 7-[4-(9-phenyl-9H-carbazol-2-yl)quinazolin-2-yl]-7H-dibenzo[c,g]carbazole (abbreviation: PC-cgDBCzQz), 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), and 11-[3′-(dibenzothiophen-4-yl)biphenyl-3-yl]phenanthro[9′,10′:4,5]furo[2,3-b]pyrazine (abbreviation: 11mDBtBPPnfpr); and organic compounds having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthalenyl)phenyl]-4-phenyl-6-spiro[9H-fluorene-9,9′-[9H]xanthen]-4-yl-1,3,5-triazine (abbreviation: PNP-SFx(4)Tzn), and 2-phenyl-4,6-bis[3-(triphenylsilyl)phenyl]-1,3,5-triazine (abbreviation: mSiTrz).

Among the above, ZADN, mSiTrz, mPn-mDMePyPTzn, 8mpTP-4mDBtPBfpm, 11mDBtBPPnfpr, and PNP-SFx(4)Tzn are preferable as the second organic compound because of their appropriate LUMO levels; thus, the use of the organic compounds makes it easy to obtain a light-emitting device that has favorable characteristics and a suppressed increase in driving voltage even when manufactured through a process involving exposure of an EL layer to the air.

The second organic compound preferably has 25 to 100 carbon atoms. When having 25 to 100 carbon atoms, the second organic compound can have excellent sublimability, and thus, thermal decomposition of the organic compound during vacuum evaporation can be inhibited and the material use efficiency can be high.

An organic compound having a glass transition temperature Tg higher than or equal to 100° C. is preferably used as the second organic compound. Accordingly, the electron-injection layer has high heat resistance and is not easily crystallized. Thus, the electron-injection layer is not easily crystallized even when part of the EL layer is processed by a lithography technique.

As the second organic compound, an organic compound with an acid dissociation constant pKₐ smaller than 4 can be used. In this case, the second organic compound can have low water solubility, and thus can be highly resistant to water and a chemical solution used during the process with a lithography technique.

An organic compound with an acid dissociation constant pKₐ smaller than 4 has lower water solubility than an organic compound with an acid dissociation constant pKₐ larger than or equal to 4. The water resistance of an electron-injection layer including an organic compound with an acid dissociation constant pKₐ smaller than 4 as the second organic compound can be higher than that of an electron-injection layer including an organic compound with an acid dissociation constant pKₐ larger than or equal to 4 as the second organic compound. Moreover, occurrence of a problem such as peeling of the electron-injection layer from another layer in the manufacturing process can be inhibited. Accordingly, occurrence of a problem that causes a defect in a light-emitting device can be inhibited.

For example, 8BP-4mDBtPBfpm, 4,8mDBtP2Bfpm, 6BP-4Cz2PPm, 2mDBTBPDBq-II, 9mDBtBPNfpr, 11mDBtBPPnfpr, mPCCzPTzn-02, or BP-BPIcz(II)Tzn can be suitably used as the second organic compound.

Note that the acid dissociation constant pKₐ of 4,8mDBtP2Bfpm is 0.60. The acid dissociation constant pKₐ of 11mDBtBPPnfpr is −1.85. In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound.

An organic compound having a polarization term δₚ less than or equal to 4.0 MPa^{0.5} of a solubility parameter δ can be used as the second organic compound, for example. An organic compound having a polarization term δₚ less than or equal to 4.0 MPa^{0.5} of a solubility parameter δ has lower water solubility than an organic compound having a polarization term δₚ greater than 4.0 MPa^{0.5} of a solubility parameter δ, for example. The water resistance of the electron-injection layer including an organic compound having a polarization term δₚ less than or equal to 4.0 MPa^{0.5} as the second organic compound can be higher than that of the electron-injection layer including an organic compound having a polarization term δₚ greater than 4.0 MPa^{0.5} as the second organic compound. Moreover, occurrence of a problem such as peeling of the electron-injection layer from another layer in the photolithography process can be inhibited. Accordingly, occurrence of a problem that causes a defect in a light-emitting device can be inhibited.

Japanese Published Patent Application No. 2017-173056 describes that the polarization term δₚ of the solubility parameter δ of water is 16.0 MPa^{0.5}.

An organic compound having a larger difference in the polarization term δₚ of the solubility parameter δ from water serving as a solvent is preferable because it has lower water solubility. Thus, an organic compound having a polarization term δₚ less than or equal to 4.0 MPa^{0.5} of the solubility parameter δ is preferably used as the second organic compound.

For example, 8BP-4mDBtPBfpm, 4,8mDBtP2Bfpm, 6BP-4Cz2PPm, 2mDBTBPDBq-II, 9mDBtBPNfpr, 11mDBtBPPnfpr, mPCCzPTzn-02, or BP-BPIcz(II)Tzn can be suitably used as the second organic compound.

Note that the polarization term δₚ of the solubility parameter δ is 3.5 MPa^{0.5} in 8BP-4mDBtPBfpm, 3.4 MPa^{0.5} in 4,8mDBtP2Bfpm, 3.4 MPa^{0.5} in 6BP-4Cz2PPm, 3.2 MPa^{0.5} in 2mDBTBPDBq-II, 3.8 MPa^{0.5} in 9mDBtBPNfpr, 3.1 MPa^{0.5} in 11mDBtBPPnfpr, 3.5 MPa^{0.5} in mPCCzPTzn-02, and 3.2 MPa^{0.5} in BP-BPIcz(II)Tzn.

The polarization term δₚ of the solubility parameter δ is calculated by the following calculation method.

As the classical molecular dynamics calculation software, Desmond produced by SchrÖdinger, Inc. is used. Furthermore, the OPLS2005 force field is used. The calculation is performed with Apollo 6500 produced by Hewlett Packard Enterprise Development.

As a calculation model, a standard cell containing approximately 32 molecules is used. As the initial molecular structure of each of the compounds, the most stable structures (singlet ground states) obtained from the first-principles calculation and structures having energy close to that of the most stable structures are mixed in equal proportions and randomly arranged such that molecules do not collide. Then, by Monte Carlo simulated annealing using the OPLS2005 force field, the structures are randomly moved and rotated to move the molecules. Furthermore, the molecules are moved toward the center of the standard cell to maximize the density, so that the initial arrangement is obtained.

For the first-principles calculation, Jaguar, which is the quantum chemical computational software, is used, and the most stable structure in the singlet ground state is calculated by the density functional theory (DFT). As a basis function, 6-31G** is used, and as a functional, B3LYP-D3 is used. The structure subjected to quantum chemical calculation is sampled by conformational analysis in mixed torsional/low-mode sampling with Maestro GUI produced by SchrÖdinger, Inc. The calculation is performed with Apollo 6500 produced by Hewlett Packard Enterprise Development.

The aforementioned initial arrangement is subjected to Brownian motion simulation and then defined in an NVT ensemble; subsequently, calculation in an NPT ensemble is performed for an enough relaxation time (30 ns) under the conditions of 1 atm and 300 K with respect to time steps that reproduce molecular vibration (2 fs), so that an amorphous solid is calculated. The solubility parameter δ of the obtained amorphous solid is defined by the following formula.

$$δ = {( \frac{Δ Hv - RT}{Vm} )}^{1 / 2} \qquad [ Formula 1 ]$$

Here, ΔHv represents heat of evaporation obtained by subtracting total energy of individual molecules averaged in the whole molecular dynamics calculation from energy of the standard cell, Vm represents the molar volume, R represents the gas constant, and T represents the temperature. There is a tendency for the solubility to decrease as the difference in the solubility parameter increases between a substance serving as a solvent and a substance serving as a solute.

The solubility parameter δ can be separated into a diffusion term δ_{d} and a polarization term δₚ. The Van der Waals interaction contributes to the diffusion term δ_{d}, and the electrostatic interaction contributes to the polarization term δₚ. In particular, the electrostatic interaction between a solute and the dipoles of a water molecule greatly contributes to the water solubility of the solute. The water solubility of an organic compound that can be used as the second organic compound actually correlates well with the calculated polarization term δₚ of the solubility parameter δ.

Note that the LUMO level of the second organic compound is further preferably lower than that of the first organic compound. In that case, electrons can be easily donated from the donor level formed by the first organic compound and the metal or the metal oxide to the second organic compound. The LUMO level of the second organic compound is preferably lower than that of the first organic compound also because the second organic compound preferably has an electron-transport property.

The LUMO level of the second organic compound is preferably higher than or equal to −3.0 eV and lower than or equal to −2.0 eV, further preferably higher than or equal to −3.0 eV and lower than or equal to −2.5 eV. The LUMO level of the first organic compound is preferably higher than or equal to −3.0 eV and lower than or equal to −2.0 eV, further preferably higher than or equal to −2.7 eV and lower than or equal to −2.0 eV.

In the above case, electrons can be easily donated from the donor level formed by the first organic compound and the metal or the metal oxide to the second organic compound. In addition, electrons in the second organic compound can be easily transported.

The electron-injection layer includes the second organic compound in addition to the metal or the metal oxide and the first organic compound, in which case interaction between materials occurs efficiently. This can be confirmed by measurement of spin density by electron spin resonance (ESR).

For example, the spin density measured by ESR of a film that includes the metal or the metal oxide and the first organic compound is preferably higher than that of a film that includes the metal or the metal oxide and the second organic compound. The spin density measured by ESR of a film that includes the metal or the metal oxide, the first organic compound, and the second organic compound is preferably higher than that of a film that includes any two of the metal or the metal oxide, the first organic compound, and the second organic compound. In that case, interaction between the materials is found to occur efficiently.

More specifically, in the film that includes the metal or the metal oxide and the first organic compound, the density of spins attributed to a signal observed at a g-factor of approximately 2.00 is measured by an electron spin resonance method to be, for example, higher than or equal to 5×10¹⁶ spins/cm³, preferably higher than or equal to 1×10¹⁷ spins/cm³. In such a case, it can be confirmed that the interaction between the materials occurs efficiently in the layer that includes the metal or the metal oxide and the first organic compound. Alternatively, in the film that includes the metal or the metal oxide, the first organic compound, and the second organic compound, the density of spins attributed to a signal observed at a g-factor of approximately 2.00 is measured by an electron spin resonance method to be, for example, higher than or equal to 5×10¹⁶ spins/cm³, preferably higher than or equal to 1×10¹⁷ spins/cm³. In such a case, it can be confirmed that the interaction between the materials occurs more efficiently in the layer that includes the metal or the metal oxide, the first organic compound, and the second organic compound than in the layer that includes only two of the metal or the metal oxide, the first organic compound, and the second organic compound. The density of spins attributed to a signal observed at a g-factor of approximately 2.00 is measured by an electron spin resonance method to be, for example, lower than or equal to 2×10¹⁶ spins/cm³ in a mixed film that includes the metal or the metal oxide and the second organic compound. The density of spins attributed to a signal observed at a g-factor of approximately 2.00 is measured by an electron spin resonance method to be, for example, lower than or equal to 2×10¹⁶ spins/cm³ in a mixed film that includes the first organic compound and the second organic compound.

In the electron-injection layer, the molar ratio of the metal or the metal oxide to the first organic compound (or the sum of the first organic compound and the second organic compound) is preferably greater than or equal to 0.1 and less than or equal to 10, further preferably greater than or equal to 0.2 and less than or equal to 5, still further preferably greater than or equal to 0.5 and less than or equal to 2. Alternatively, the volume ratio of the metal or the metal oxide to the first organic compound (the sum of the first organic compound and the second organic compound) is preferably greater than or equal to 0.01 and less than or equal to 0.3, further preferably greater than or equal to 0.02 and less than or equal to 0.2, still further preferably greater than or equal to 0.05 and less than or equal to 0.1. Mixing the metal or the metal oxide and the first organic compound (or the first organic compound and the second organic compound) in such a ratio enables providing the electron-injection layer having a favorable electron-injection property. Although the second organic compound is not necessarily used, the volume ratio of the first organic compound to the second organic compound is preferably greater than or equal to 0.1 and less than or equal to 10, further preferably greater than or equal to 0.2 and less than or equal to 5, still further preferably greater than or equal to 0.5 and less than or equal to 2. Mixing the first organic compound and the second organic compound in such a ratio enables providing the electron-injection layer having a favorable electron-transport property. When an organic compound with favorable thermophysical properties with high Tg is used as the second organic compound, highly reliable organic EL device can be provided.

The thickness of the electron-injection layer is preferably greater than or equal to 2 nm and less than or equal to 20 nm, further preferably greater than or equal to 5 nm and less than or equal to 10 nm. In the case where the electron-injection layer has a stacked-layer structure of a metal layer and a layer containing the first organic compound, the thickness of the metal layer is preferably greater than or equal to 0.1 nm and less than or equal to 5 nm, further preferably greater than or equal to 0.2 nm and less than or equal to 2 nm. In the case where the electron-injection layer has a stacked-layer structure of a metal layer and a layer containing the first organic compound, the thickness of the layer containing the first organic compound is preferably greater than or equal to 2 nm and less than or equal to 20 nm, further preferably greater than or equal to 5 nm and less than or equal to 10 nm.

The light-emitting device of one embodiment of the present invention having the aforementioned structure can exhibit favorable characteristics even when exposure to the air or a photolithography process involving exposure to the air is performed before the second electrode is formed.

The light-emitting device of one embodiment of the present invention having the above-described structure can be a highly reliable light-emitting device with high current efficiency and a suppressed increase in driving voltage.

One embodiment of the present invention is particularly suitably used in a light-emitting device formed through a photolithography process and also contributes to cost reduction in manufacturing of light-emitting devices not formed through a photolithography process because high stability in the atmosphere of one embodiment of the present invention increases yield and eliminates the need for too strictly managing the atmosphere in the manufacturing process.

### Embodiment 2

In this embodiment, light-emitting devices of one embodiment of the present invention will be described in detail.

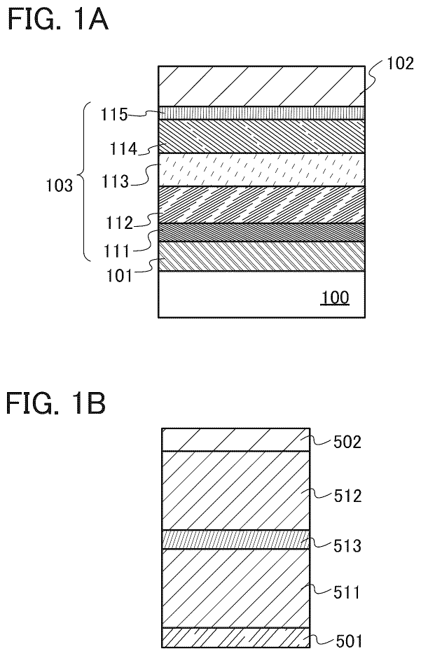

FIG. 1 is a schematic diagram of the light-emitting device of one embodiment of the present invention. The light-emitting device includes a first electrode 101 over an insulator 100, and an EL layer 103 between the first electrode 101 and a second electrode 102. The EL layer 103 includes at least a light-emitting layer 113 and an electron-injection layer 115. The light-emitting layer 113 contains a light-emitting substance and emits light when voltage is applied between the first electrode 101 and the second electrode 102.

The EL layer 103 preferably includes, besides the light-emitting layer 113 and the electron-injection layer 115, functional layers such as a hole-injection layer 111, a hole-transport layer 112, and an electron-transport layer 114, as illustrated in FIG. 1A. The EL layer 103 may include functional layers other than the above functional layers, such as a hole-blocking layer, an exciton-blocking layer, and an intermediate layer. Alternatively, any of the above-described layers may be omitted.

The electron-injection layer 115 contains the metal or the metal oxide, the organic compound (the first organic compound) including the first π-electron deficient heteroaromatic ring with an electron-donating group, and the organic compound (the second organic compound) including the second π-electron deficient heteroaromatic ring, which are described in Embodiment 1. The electron-injection layer 115 may further contain another organic compound (a third organic compound).

The specific structure of the electron-injection layer 115 is described in detail in Embodiment 1; thus, repeated description thereof is omitted.

This embodiment shows an example in which the first electrode 101 includes an anode, the second electrode 102 includes a cathode, and the first electrode 101 is formed on the insulator 100 side; however, a structure in which the second electrode 102 is formed on the insulator 100 side, what is called an inversely stacked structure, may be employed. In this case, the light-emitting device has a stacked-layer structure in which the second electrode 102, the electron-injection layer 115, (the electron-transport layer 114), the light-emitting layer 113, (the hole-transport layer 112, the hole-injection layer 111), and the first electrode 101 are stacked in this order from the insulator 100 side. In the case of such a light-emitting device having an inversely stacked structure, the relatively stable hole-injection layer 111 serves as a surface; thus, the light-emitting device can have higher reliability.

The first electrode 101 and the second electrode 102 may each have a single-layer structure or a stacked-layer structure. In the case of the stacked-layer structure, a layer in contact with the EL layer 103 serves as an anode or a cathode. In the case where the electrodes each have the stacked-layer structure, there is no limitation on work functions of materials for layers other than the layer in contact with the EL layer 103, and the materials can be selected in accordance with required properties such as a resistance value, processing easiness, reflectivity, light-transmitting property, and stability.

The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Such conductive metals and their oxide films are usually formed by a sputtering method, but may be formed by application of a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium, (Ti), aluminum (Al), nitride of a metal material (e.g., titanium nitride), or the like can be used for the anode. The anode may be a stack of layers formed of any of these materials. For example, a film in which Al, Ti, and ITSO are stacked in this order over Ti is preferable because the film has high efficiency owing to high reflectivity and enables high resolution of several thousand ppi. Graphene can also be used for the anode. When a composite material that can be included in the hole-injection layer 111, which is described later, is used for a layer (typically, the hole-injection layer) in contact with the anode, an electrode material can be selected regardless of its work function.

The hole-injection layer 111 is provided in contact with the anode and has a function of facilitating injection of holes to the EL layer 103. The hole-injection layer 111 can be formed using a phthalocyanine-based compound or complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS).

The hole-injection layer 111 may be formed using a substance having an electron-acceptor property. Examples of the substance having an electron-acceptor property include organic compounds having an electron-withdrawing group (a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-acceptor property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an electron-acceptor property, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing any of the aforementioned materials having an electron-acceptor property and an organic compound having a hole-transport property.

As the organic compound having a hole-transport property used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property used in the composite material preferably has a hole mobility higher than or equal to 1×10⁻⁶ cm²/Vs. The organic compound having a hole-transport property used in the composite material preferably has a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

In addition, the above-described composite material containing a material having an electron-acceptor property and an organic compound having a hole-transport property efficiently causes interaction between materials. Thus, in a film containing the composite material, the spin density attributed to a signal observed at a g-factor of approximately 2.00 is measured by ESR to be, preferably higher than or equal to 1×10¹⁷ spins/cm³.

Such an organic compound having a hole-transport property further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable manufacturing a light-emitting device with a long lifetime.

Specific examples of the organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAβPNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Examples of the aromatic amine compounds that can be used as the material having a hole-transport property include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an electron-acceptor property, the organic compound having an acceptor property is easy to use because it is easily deposited by vapor deposition.

The hole-transport layer 112 is formed using an organic compound having a hole-transport property. The organic compound having a hole-transport property preferably has a hole mobility of 1×10⁻⁶ cm²/Vs or higher.

Examples of the material having a hole-transport property include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′:3′,1″-terphenyl]-4-yl-3,3′-9H,9′H-bicarbazole; compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the material having a hole-transport property used for the composite material for the hole-injection layer 111 can also be suitably used as the material contained in the hole-transport layer 112.

The light-emitting layer 113 is a layer including a light-emitting substance and preferably includes a light-emitting substance and a host material. The light-emitting layer 113 may additionally include other materials. Alternatively, the light-emitting layer 113 may be a stack of two layers with different compositions.

As the light-emitting substance, fluorescent substances, phosphorescent substances, substances exhibiting thermally activated delayed fluorescence (TADF), or other light-emitting substances may be used.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

A condensed heteroaromatic compound containing nitrogen and boron, especially a compound having a diaza-boranaphtho-anthracene skeleton, exhibits a narrow emission spectrum, emits blue light with favorable color purity, and can thus be used suitably. Examples of the compound include 5,9-diphenyl-5,9-diaza-13b-boranaphtho[3,2,1-de]anthracene (abbreviation: DABNA1), 9-(biphenyl-3-yl)-N,N,5,11-tetraphenyl-5H,9H-[1,4]benzazaborino[2,3,4-kl]phenazaborin-3-amine (abbreviation: DABNA2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-ki][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-Y), or the like can be suitably used.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN²]phenyl-KC}iridium(III) (abbreviation: [Ir(mpptz-dmp)₃]), and tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptzl-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC) (abbreviation: CNImIr); an organometallic complex having a benzimizazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); and an organometallic iridium complex in which a phenylpyridine derivative including an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac). These compounds emit blue phosphorescent light and have an emission peak in the wavelength range of 450 nm to 520 nm.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C²)iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²)iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), [2-d₃-methyl-(2-pyridinyl-κN)benzofuro[2,3-b]pyridine-KC]bis[2-(2-pyridinyl-κN)phenyl-κC]iridium(III) (abbreviation: [Ir(ppy)₂(mbfpypy-d₃)]), [2-(4-d₃-methyl-5-phenyl-2-pyridinyl-κN2)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), and [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]); and a rare earth metal complex such as tris(acetylacetonato) (monophenanthroline)terbium(III) (abbreviation: [Tb(acac)₃(Phen)]). These compounds mainly emit green phosphorescent light and have an emission peak in the wavelength range of 500 nm to 600 nm. Note that organometallic iridium complexes including a pyrimidine skeleton have distinctively high reliability or emission efficiency and thus are particularly preferable.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-N]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range of 600 nm to 700 nm. Furthermore, the organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro 111-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

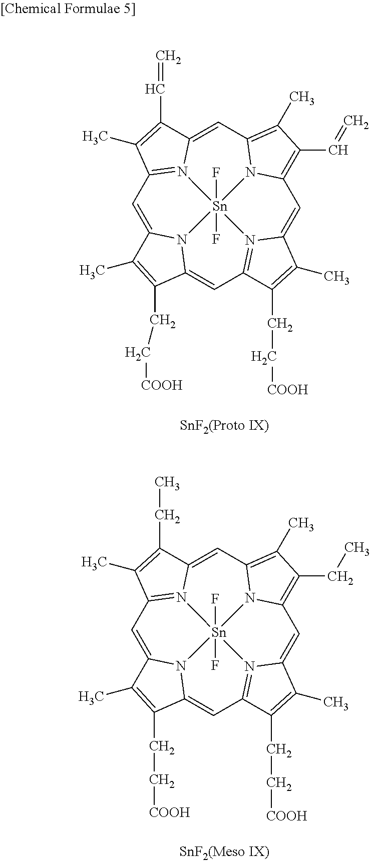

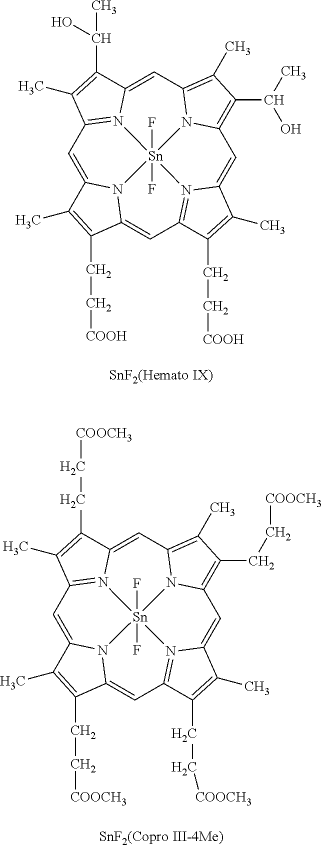

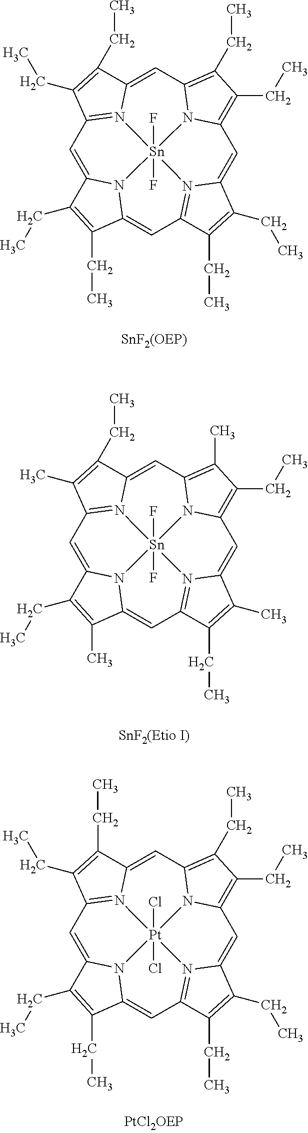

Alternatively, it is possible to use a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high electron-acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-acceptor property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

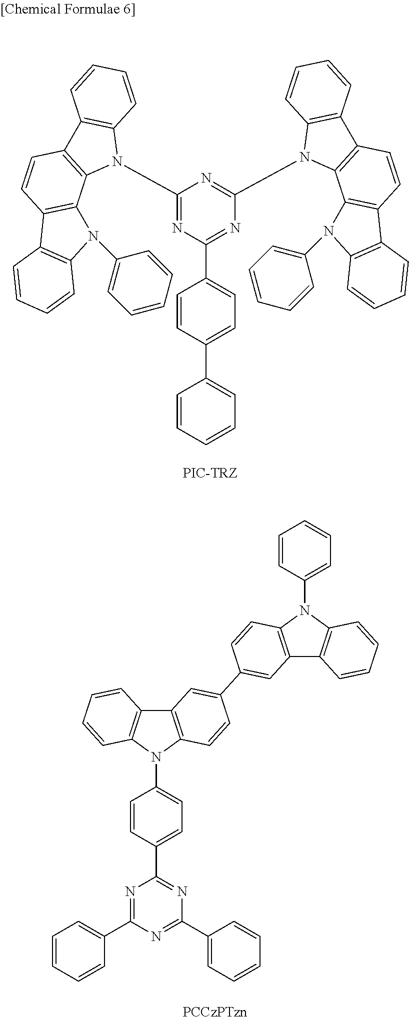 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

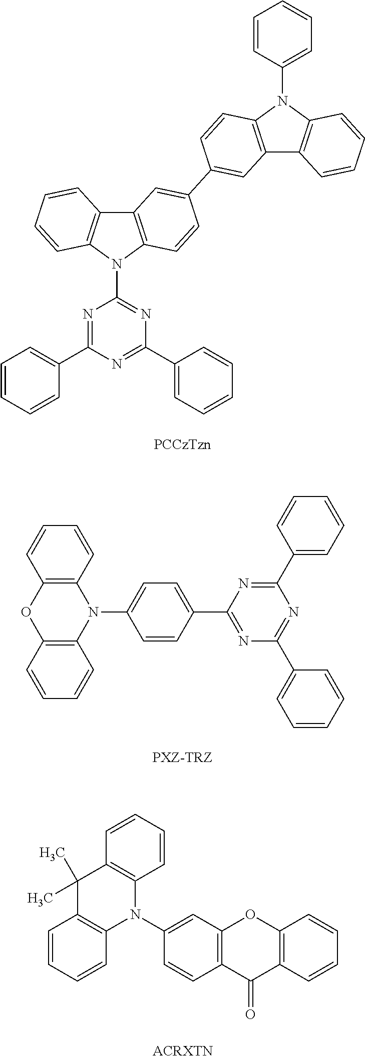 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21]

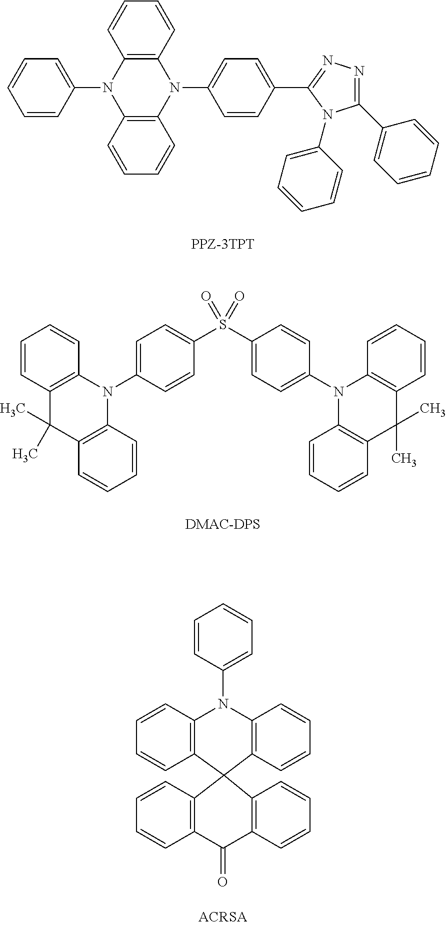 [SMILES: c1ccc(-c2nnc(-c3ccc(N4c5ccccc5N(c5ccccc5)c5ccccc54)cc3)n2-c2ccccc2)cc1 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

When a TADF material is used as the light-emitting substance, the S₁ level of the host material is preferably higher than that of the TADF material. In addition, the T₁ level of the host material is preferably higher than that of the TADF material.

As the host material in the light-emitting layer, various carrier-transport materials such as materials having an electron-transport property and/or materials having a hole-transport property, and the TADF materials can be used.

The material having a hole-transport property is preferably an organic compound having an amine skeleton or a π-electron rich heteroaromatic ring skeleton, for example. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable manufacturing a light-emitting device with a long lifetime.

Examples of such an organic compound include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), and 9,9′-diphenyl-9H,9′H-3,3′-bicarbazole (abbreviation: PCCP); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used.

As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferably used. Examples of the organic compound having a π-electron deficient heteroaromatic ring skeleton include an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above materials, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton have high reliability and thus are preferable. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high electron-acceptor property and high reliability.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOS); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-{3-[3-(N-phenyl-9H-carbazol-3-yl)-9H-carbazol-9-yl]phenyl}dibenzo[f,h]quinoxaline (abbreviation: 2mPCCzPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)₂Py), 2,2′-(pyridine-2,6-diyl)bis{4-[4-(2-naphthyl)phenyl]-6-phenylpyrimidine}(abbreviation: 2,6(NP—PPm)₂Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthalenyl)phenyl]-4-phenyl-6-spiro[9H-fluorene-9,9′-[9H]xanthen]-4-yl-1,3,5-triazine (abbreviation: PNP-SFx(4)Tzn), or 2-phenyl-4,6-bis[3-(triphenylsilyl)phenyl]-1,3,5-triazine (abbreviation: mSiTrz). The organic compound that has a heteroaromatic ring having a diazine skeleton, the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength on a lowest-energy-side absorption band of the fluorescent substance, in which case excitation energy is transferred smoothly from the TADF material to the fluorescent substance and light emission can be obtained efficiently.

In order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that brings about light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination. Here, the luminophore refers to an atomic group (skeleton) that brings about light emission in a fluorescent substance. The luminophore is preferably a skeleton having a π bond, further preferably includes an aromatic ring, and still further preferably includes a condensed aromatic ring or a condensed heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. Among the substances having an anthracene skeleton that is used as the host material, a substance having a diphenylanthracene skeleton, in particular, a substance having a 9,10-diphenylanthracene skeleton, is chemically stable and thus is preferably used as the host material. The host material preferably has a carbazole skeleton because the hole-injection and hole-transport properties are improved; further preferably, the host material has a benzocarbazole skeleton in which a benzene ring is further condensed to a carbazole skeleton because the HOMO level thereof is shallower than that of the host material having a carbazole skeleton by approximately 0.1 eV and thus holes enter the host material easily. In particular, the host material preferably has a dibenzocarbazole skeleton because the HOMO level thereof is shallower than that of the host material having a carbazole skeleton by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-QNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property can be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission whose wavelength overlaps with the wavelength on a lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side) observed by comparison of the emission spectra of the material having a hole-transport property, the material having an electron-transport property, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the material having a hole-transport property, the material having an electron-transport property, and the mixed film of these materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

The electron-transport layer 114 contains a material having an electron-transport property. The material having an electron-transport property preferably has an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound including a π-electron deficient heteroaromatic ring is preferably one or more of an organic compound including a heteroaromatic ring having an azole skeleton, an organic compound including a heteroaromatic ring having a pyridine skeleton, an organic compound including a heteroaromatic ring having a diazine skeleton, and an organic compound including a heteroaromatic ring having a triazine skeleton.

As the organic compounds having an electron-transport property that can be used in the electron-transport layer 114, the organic compound having an electron-transport property in the light-emitting layer 113 and the organic compound mentioned in Embodiment 1 as the organic compound that can be used as the second organic compound in the electron-injection layer 115 can be similarly used. Among the above-described materials, the organic compound that has a heteroaromatic ring having a diazine skeleton, the organic compound that has a heteroaromatic ring having a pyridine skeleton, and the organic compound that has a heteroaromatic ring having a triazine skeleton are especially preferable because of having high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. An organic compound having a phenanthroline skeleton such as mTpPPhen, PnNPhen, or mPPhen2P is preferable, and an organic compound having a phenanthroline dimer structure such as mPPhen2P is further preferable because of its excellent stability. The organic compound having an electron-transport property and high HOMO level, such as 2mPCCzPDBq and DACT-II, is preferable because a light-emitting device with a low driving voltage can be obtained.

The electron-transport layer preferably contains an organic compound having an electron-transport property with an acid dissociation constant pKₐ of less than 4.

The electron-transport layer 114 may have a stacked-layer structure. In the case where the electron-transport layer 114 has a stacked-layer structure, the layer in contact with the light-emitting layer 113 may function as a hole-blocking layer. In the case where the electron-transport layer in contact with the light-emitting layer functions as a hole-blocking layer, the electron-transport layer is preferably formed using a material having a deeper HOMO level than a material included in the light-emitting layer by more than or equal to 0.5 eV.

The electron-injection layer 115 is formed between the electron-transport layer 114 and the second electrode 102. Since the structure of the electron-injection layer 115 has been described in detail in Embodiment 1, the repetitive description thereof is omitted.

The second electrode 102 is an electrode including a cathode. The second electrode 102 may have a stacked-layer structure, in which case a layer in contact with the EL layer 103 functions as a cathode. For the cathode, a metal, an alloy, an electrically conductive compound, or a mixture thereof each having a low work function (specifically, lower than or equal to 3.8 eV) or the like can be used. Specific examples of such a cathode material include elements belonging to Group 1 or 2 of the periodic table, such as alkali metals (e.g., lithium (Li) or cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film formed using any of the above materials having a low work function is provided between the second electrode 102 and the electron-transport layer, a variety of conductive materials such as Al, Ag, ITO, or indium oxide-tin oxide containing silicon or silicon oxide can be used for the cathode regardless of the work function.

When the second electrode 102 is formed using a material that transmits visible light, the light-emitting device can emit light from the second electrode 102 side. When the first electrode 101 is formed using a material that transmits visible light, the light-emitting device can emit light from the first electrode 101 side.

Films of these conductive materials can be deposited by a dry process such as a vacuum evaporation method or a sputtering method, an ink-jet method, a spin coating method, or the like. Alternatively, a wet process using a sol-gel method or a wet process using a paste of a metal material may be employed.

Note that in the case of a top-emission light-emitting device, forming a cap layer by evaporation of an organic compound over the second electrode can improve light extraction efficiency. The cap layer may have a single-layer structure or a stacked-layer structure. In the case of a stacked-layer structure, the use of organic compounds with different refractive indexes can further increase the light extraction efficiency.

The EL layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different deposition methods may be used to form the electrodes or the layers described above.

Next, an embodiment of a light-emitting device with a structure in which a plurality of light-emitting units are stacked (this type of light-emitting device is also referred to as a stacked or tandem device) is described with reference to FIG. 1B. This light-emitting device includes a plurality of light-emitting units between an anode and a cathode. One light-emitting unit has substantially the same structure as the EL layer 103 illustrated in FIG. 1A. In other words, the light-emitting device illustrated in FIG. 1B includes a plurality of light-emitting units, and the light-emitting device illustrated in FIG. 1A includes a single light-emitting unit.

In FIG. 1B, a first light-emitting unit 511 and a second light-emitting unit 512 are stacked between a first electrode 501 and a second electrode 502, and an intermediate layer 513 is provided between the first light-emitting unit 511 and the second light-emitting unit 512. The first electrode 501 and the second electrode 502 correspond, respectively, to the first electrode 101 and the second electrode 102 illustrated in FIG. 1A, and the materials given in the description for FIG. 1A can be used. Furthermore, the first light-emitting unit 511 and the second light-emitting unit 512 may have the same structure or different structures.

The intermediate layer 513 has a function of injecting electrons into one of the light-emitting units and injecting holes into the other of the light-emitting units when voltage is applied between the first electrode 501 and the second electrode 502. That is, in FIG. 1B, the intermediate layer 513 injects electrons into the first light-emitting unit 511 and holes into the second light-emitting unit 512 when voltage is applied such that the potential of the anode becomes higher than the potential of the cathode.

The intermediate layer 513 includes a charge-generation layer. The charge-generation layer includes at least a p-type layer 117. The p-type layer 117 is preferably formed using any of the composite materials given above as examples of materials that can be used for the hole-injection layer 111. The p-type layer 117 may be formed by stacking a film containing the above-described acceptor material as a material included in the composite material and a film containing a hole-transport material. When a potential is applied to the p-type layer 117, electrons are injected into the electron-transport layer 114 and holes are injected into the cathode; thus, the light-emitting device operates.

Note that the intermediate layer 513 preferably includes one or both of an electron-relay layer 118 and an n-type layer 119 in addition to the p-type layer 117.

The electron-relay layer 118 contains at least the substance having an electron-transport property and has a function of preventing an interaction between the n-type layer 119 and the p-type layer 117 and smoothly transferring electrons. The LUMO level of the substance having an electron-transport property included in the electron-relay layer 118 is preferably between the LUMO level of an acceptor substance in the p-type layer 117 and the LUMO level of a substance included in a layer of the electron-transport layer 114 that is in contact with the intermediate layer 513. As a specific value of the energy level, the LUMO level of the substance having an electron-transport property in the electron-relay layer 118 is preferably higher than or equal to −5.0 eV, further preferably higher than or equal to −5.0 eV and lower than or equal to −3.0 eV. Note that as the substance having an electron-transport property in the electron-relay layer 118, a phthalocyanine-based material or a metal complex having a metal-oxygen bond and an aromatic ligand is preferably used.

The n-type layer 119 can be formed using a substance having a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the n-type layer 119 contains a substance having an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). As the substance having an electron-transport property, a material similar to the above-described material for the electron-transport layer 114 can be used.

Instead of the n-type layer 119, a layer containing the metal or the metal oxide, the organic compound (the first organic compound) including the first π-electron deficient heteroaromatic ring with an electron-donating group, and the organic compound (the second organic compound) including the second π-electron deficient heteroaromatic ring described as being used for the electron-injection layer in Embodiment 1 may be formed in the same position as the n-type layer 119. In the case of such a structure, a tandem light-emitting device with favorable characteristics can be manufactured.

In the case where the anode-side surface of a light-emitting unit is in contact with the intermediate layer 513, the charge-generation layer of the intermediate layer 513 can also function as a hole-injection layer of the light-emitting unit; therefore, a hole-injection layer is not necessarily provided in the light-emitting unit. In the case where the cathode-side surface of a light-emitting unit is in contact with the intermediate layer 513, the intermediate layer 513 can also function as an electron-injection layer of the light-emitting unit; therefore, an electron-injection layer is not necessarily provided in the light-emitting unit.

The light-emitting device having two light-emitting units is described with reference to FIG. 1B; however, one embodiment of the present invention can also be applied to a light-emitting device in which three or more light-emitting units are stacked. With a plurality of light-emitting units partitioned by the intermediate layer 513 between a pair of electrodes as in the light-emitting device of this embodiment, it is possible to provide a long-life element that can emit light with high luminance at a low current density. A light-emitting apparatus that can be driven at a low voltage and has low power consumption can also be provided.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The EL layer 103, the first light-emitting unit 511, the second light-emitting unit 512, the layers such as the intermediate layer 513, and the electrodes that are described above can be formed by a method such as an evaporation method (including a vacuum evaporation method), a droplet discharge method (also referred to as an ink-jet method), a coating method, or a gravure printing method. A low molecular material, a middle molecular material (including an oligomer and a dendrimer), or a high molecular material may be included in the above components.

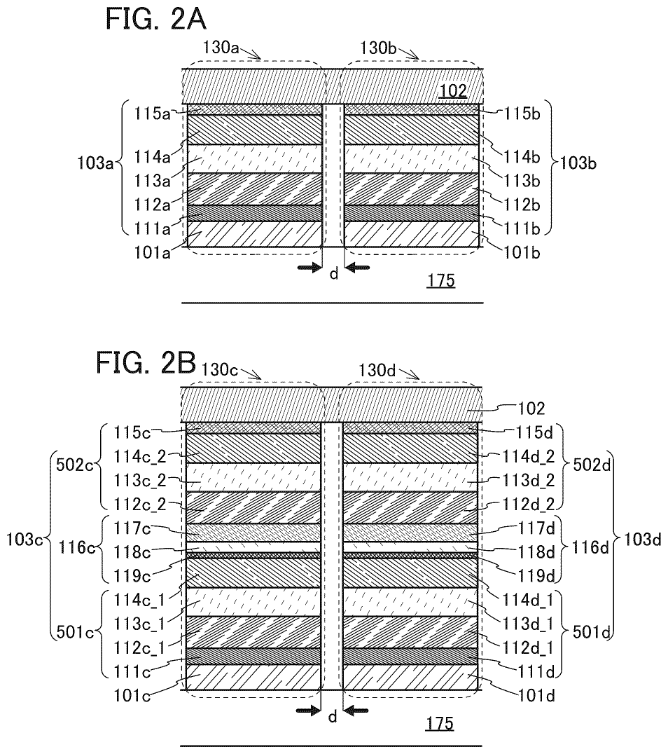

FIG. 2A illustrates two adjacent light-emitting devices (light-emitting devices 130a and 130b) included in a display device of one embodiment of the present invention.

The light-emitting device 130a includes an EL layer 103a between a first electrode 101a over an insulating layer 175 and the second electrode 102 facing the first electrode 101a. The EL layer 103a includes a hole-injection layer 111a, a hole-transport layer 112a, a light-emitting layer 113a, an electron-transport layer 114a, and an electron-injection layer 115a, but may have a different stacked-layer structure.

The light-emitting device 130b includes an EL layer 103b between a first electrode 101b over the insulating layer 175 and the second electrode 102 facing the first electrode 101b. The EL layer 103b includes a hole-injection layer 111b, a hole-transport layer 112b, a light-emitting layer 113b, an electron-transport layer 114b, and an electron-injection layer 115b, but may have a different stacked-layer structure.

The structures of the electron-transport layer 114a and the electron-injection layer 115a in the light-emitting device 130a and the structures of the electron-transport layer 114b and the electron-injection layer 115b in the light-emitting device 130b preferably have the structure as described in Embodiment 1.

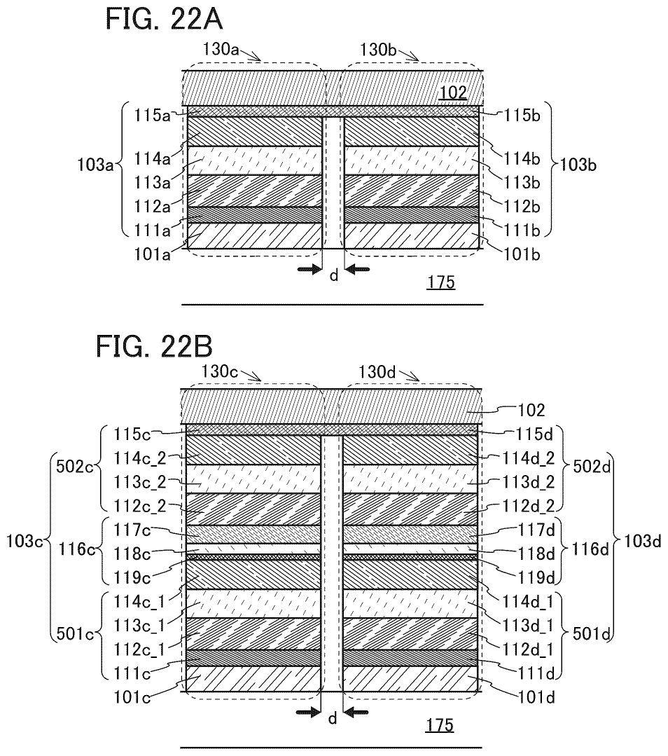

The second electrode 102 is preferably one layer shared by the light-emitting device 130a and the light-emitting device 130b. The EL layer 103a and the EL layer 103b are independent layers because these layers are processed by a photolithography technique after the electron-injection layer 115a is formed and after the electron-injection layer 115b is formed. In the light-emitting device of one embodiment of the present invention, even though processing by a photolithography technique is performed after the electron-injection layer 115a is formed and after the electron-injection layer 115b is formed, the light-emitting device can have favorable characteristics. Note that as illustrated in FIG. 22A, the electron-injection layers 115a and 115b may be one layer shared by the light-emitting devices 130a and 130b.

End portions (contours) of the EL layer 103a are processed by a photolithography technique and thus are substantially aligned with each other in the direction perpendicular to the substrate. Furthermore, end portions (contours) of the EL layer 103b are processed by a photolithography technique and thus are substantially aligned with each other in the direction perpendicular to the substrate.

The space d is present between the EL layer 103a and the EL layer 103b because of processing with a photolithography technique. Since the EL layers are processed by a photolithography technique, the distance between the first electrode 101a and the first electrode 101b can be made small, greater than or equal to 0.5 μm and less than or equal to 5 μm, compared with the case where mask vapor deposition is performed.

FIG. 2B illustrates two adjacent tandem light-emitting devices (light-emitting devices 130c and 130d) manufactured by a photolithography technique.

The light-emitting device 130c includes an EL 103c between a first electrode 101c over the insulating layer 175 and the second electrode 102. The EL layer 103c has a structure in which a first light-emitting unit 501c and a second light-emitting unit 502c are stacked with an intermediate layer 116c therebetween. Although FIG. 2 illustrates an example in which the two light-emitting units are stacked, three or more light-emitting units may be stacked. The first light-emitting unit 501c includes a hole-injection layer 111c, a first hole-transport layer 112c_1, a first light-emitting layer 113c_1, and a first electron-transport layer 114c_1. The intermediate layer 116c includes a p-type layer 117c, an electron-relay layer 118c, and an n-type layer 119c. The electron-relay layer 118c is not necessarily provided. The second light-emitting unit 502c includes a second hole-transport layer 112c_2, a second light-emitting layer 113c_2, a second electron-transport layer 114c_2, and an electron-injection layer 115c.

The light-emitting device 130d includes an EL layer 103d between a first electrode 101d over the insulating layer 175 and the second electrode 102. The EL layer 103d has a structure in which a first light-emitting unit 501d and a second light-emitting unit 502d are stacked with an intermediate layer 116d therebetween. Although FIG. 2 illustrates an example in which the two light-emitting units are stacked, three or more light-emitting units may be stacked. The first light-emitting unit 501d includes a hole-injection layer 111d, a first hole-transport layer 112d_1, a first light-emitting layer 113d_1, and a first electron-transport layer 114d_1. The intermediate layer 116d includes a p-type layer 117d, an electron-relay layer 118d, and an n-type layer 119d. The electron-relay layer 118d is not necessarily provided. The second light-emitting unit 502d includes a second hole-transport layer 112d_2, a second light-emitting layer 113d_2, a second electron-transport layer 114d_2, and an electron-injection layer 115d.

In the light-emitting devices 130c and 130d, the electron-injection layers 115c and 115d preferably have the structure as described in Embodiment 1.

Note that the second electrode 102 is preferably one layer shared by the light-emitting devices 130c and 130d. The EL layers 103c and 103d are independent of each other because processing by a photolithography technique is performed after the electron-injection layer 115c is formed and after the electron-injection layer 115d is formed. In the light-emitting device of one embodiment of the present invention, even though processing by a photolithography technique is performed after the electron-injection layer 115c is formed and after the electron-injection layer 115d is formed, the light-emitting device can have favorable characteristics. Note that as illustrated in FIG. 22B, the electron-injection layers 115c and 115d may be one layer shared by the light-emitting devices 130c and 130d.

End portions (contours) of the EL layer 103c are processed by a photolithography technique and thus are substantially aligned with each other in the direction perpendicular to the substrate. Furthermore, end portions (contours) of the EL layer 103d are processed by a photolithography technique and thus are substantially aligned with each other in the direction perpendicular to the substrate.

The space d is present between the EL layer 103c and the EL layer 103d because of processing with a photolithography technique. Since the EL layers are processed by a photolithography technique, the distance between the first electrode 101c and the first electrode 101d can be made small, greater than or equal to 0.5 μm and less than or equal to 5 μm, compared with the case where mask vapor deposition is performed.

In the light-emitting device of one embodiment of the present invention, since the EL layer is processed by a photolithography technique, the EL layer can be processed with a sufficient accuracy to manufacture a high-resolution display device. Furthermore, since a photolithography process can be performed on the electron-injection layer far from the light-emitting layer without contamination by an alkali metal, the light-emitting device can have favorable characteristics. As described above, the light-emitting device of one embodiment of the present invention having the above-described structure enables a high-resolution display device and can have favorable characteristics.

Since the EL layer in the light-emitting device of one embodiment of the present invention is processed at once with a photolithography technique, all the layers included in the EL layer have substantially the same contour. Here, “substantially the same” in this specification means, supposing that the EL layer includes a layer A and a layer B, a difference between a contour A of the layer A and a contour B of the layer B is within 5% of the width of the EL layer along a line perpendicular to the compared portions of the contours. In the case where an end surface of the EL layer has a tapered shape, a continuous change of the contour is allowed.

The structure of this embodiment can be used in combination with any of the other structures as appropriate.

### Embodiment 3

Described in this embodiment is a mode in which the light-emitting device of one embodiment of the present invention is used as a display element of a display device.

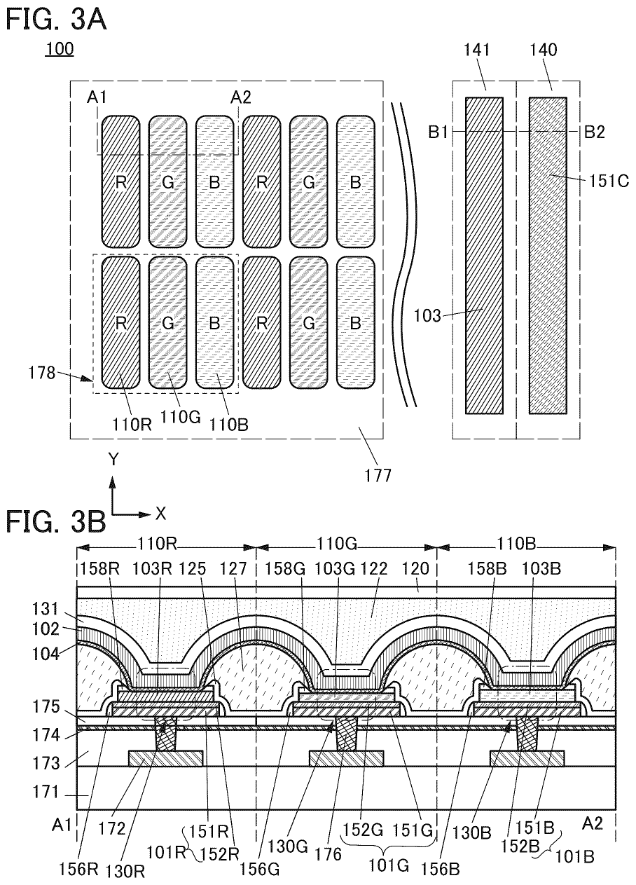

As illustrated in FIGS. 3A and 3B, a plurality of light-emitting devices 130 are formed over the insulating layer 175 to constitute a display device.

A display device includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, a full-color image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 3A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The EL layer 103 is provided in the region 141. A conductive layer 151C is provided in the connection portion 140.

Although FIG. 3A illustrates an example where the region 141 and the connection portion 140 are positioned on the right side of the pixel portion 177, the positions of the region 141 and the connection portion 140 are not particularly limited. The number of regions 141 and the number of connection portions 140 can each be one or more.

FIG. 3B is an example of a cross-sectional view along the dashed-dotted line A1-A2 in FIG. 3A. As illustrated in FIG. 3B, the display device includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 3B shows cross sections of a plurality of the inorganic insulating layers 125 and a plurality of the insulating layers 127, the inorganic insulating layers 125 are preferably connected to each other and the insulating layers 127 are preferably connected to each other when the display device is seen from above. In other words, the insulating layer 127 preferably has an opening portion over the first electrode.

In FIG. 3B, a light-emitting device 130R, a light-emitting device 130G, and a light-emitting device 130B are shown as the light-emitting devices 130. The light-emitting devices 130R, 130G, and 130B emit light of the respective colors. For example, the light-emitting device 130R can emit red light, the light-emitting device 130G can emit green light, and the light-emitting device 130B can emit blue light. Alternatively, the light-emitting device 130R, 130G, or 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be of a bottom-emission type.

The light-emitting device 130R has a structure as described in Embodiments 1 and 2. The light-emitting device 130R includes a first electrode 101R (pixel electrode) including a conductive layer 151R and a conductive layer 152R, an EL layer 103R over the first electrode 101R, and the second electrode 102 (common electrode) over the EL layer 103R. The electron-injection layer, which is the outermost surface layer of the EL layer 103R, has a structure as described in Embodiment 1. Such a structure can reduce damage to the light-emitting layer or an active layer during a photolithography process, which promises favorable film quality and electrical characteristics. When the electron-transport layer is a mixed layer of an organic compound having an electron-transport property and an organic compound having a hole-transport property, a display device in which an increase in driving voltage is inhibited can be provided.

The light-emitting device 130G has a structure as described in Embodiments 1 and 2. The light-emitting device 130G includes a first electrode 101G (pixel electrode) including a conductive layer 151G and a conductive layer 152G, an EL layer 103G over the first electrode 101G, and the second electrode 102 (common electrode) over the EL layer 103G. The electron-injection layer, which is the outermost surface layer of the EL layer 103G, has a structure as described in Embodiment 1. Such a structure can reduce damage to the light-emitting layer or an active layer during a photolithography process, which promises favorable film quality and electrical characteristics. When the electron-transport layer is a mixed layer of an organic compound having an electron-transport property and an organic compound having a hole-transport property, a display device in which an increase in driving voltage is inhibited can be provided.

The light-emitting device 130B has a structure as described in Embodiments 1 and 2. The light-emitting device 130B includes a first electrode 101B (pixel electrode) including a conductive layer 151B and a conductive layer 152B, an EL layer 103B over the first electrode 101B, and the second electrode 102 (common electrode) over the EL layer 103B. The electron-injection layer, which is the outermost surface layer of the EL layer 103B, has a structure as described in Embodiment 1. Such a structure can reduce damage to the light-emitting layer or an active layer during a photolithography process, which promises favorable film quality and electrical characteristics. When the electron-transport layer is a mixed layer of an organic compound having an electron-transport property and an organic compound having a hole-transport property, a display device in which an increase in driving voltage is inhibited can be provided.

In the light-emitting device, one of the pixel electrode (first electrode) and the common electrode (second electrode) functions as an anode and the other functions as a cathode. In this embodiment, description is made on the assumption that the pixel electrode functions as the anode and the common electrode functions as the cathode unless otherwise specified.

The EL layers 103R, 103G, and 103B are island-shaped layers that are independent of each other on a light-emitting device basis or on an emission color basis. It is preferable that the EL layers 103R, 103G, and 103B not overlap with one another. Providing the island-shaped EL layer 103 in each of the light-emitting devices 130 can suppress leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped EL layer 103 is formed by forming an EL film and processing the EL film by a photolithography technique.

The EL layer 103 is preferably provided to cover the top surface and the side surface of the first electrode 101 (pixel electrode) of the light-emitting device 130. In this case, the aperture ratio of the display device can be easily increased as compared to the structure where the end portion of the EL layer 103 is positioned inward from the end portion of the pixel electrode. Covering the side surface of the pixel electrode of the light-emitting device 130 with the EL layer 103 can inhibit the pixel electrode from being in contact with the second electrode 102; hence, a short circuit of the light-emitting device 130 can be inhibited.

In the display device of one embodiment of the present invention, the first electrode 101 (pixel electrode) of the light-emitting device preferably has a stacked-layer structure. For example, in the example illustrated in FIG. 3B, the first electrode 101 of the light-emitting device 130 is a stack of the conductive layer 151 on the insulating layer 171 side and the conductive layer 152 on the EL layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 and the conductive layer 152 may each be a stack of a plurality of layers containing different materials. In that case, the conductive layer 151 may include a layer formed using a material that can be used for the conductive layer 152, such as a conductive oxide, and the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

In FIG. 3B, the conductive layer 151 has a tapered end portion. Specifically, the conductive layer 151 preferably has a tapered end portion with a taper angle less than 90°. In that case, the conductive layer 152 provided along the side surface of the conductive layer 151 also has a tapered shape. When the side surface of the conductive layer 152 has a tapered shape, coverage with the EL layer 103 provided along the side surface of the conductive layer 152 can be improved.

The end portions of the conductive layers 151 and 152 may have no tapered shape, that is, have substantially a vertical shape. The end portion of the EL layer 103 is preferably positioned inward from the first electrode 101. In this case, leakage current through the EL layer 103 can be reduced, so that a display device with a low driving voltage and favorable display performance can be obtained.

Since the light-emitting device 130 has the structure as described in Embodiments 1 and 2, the display device of one embodiment of the present invention can be a light-emitting device with high reliability.

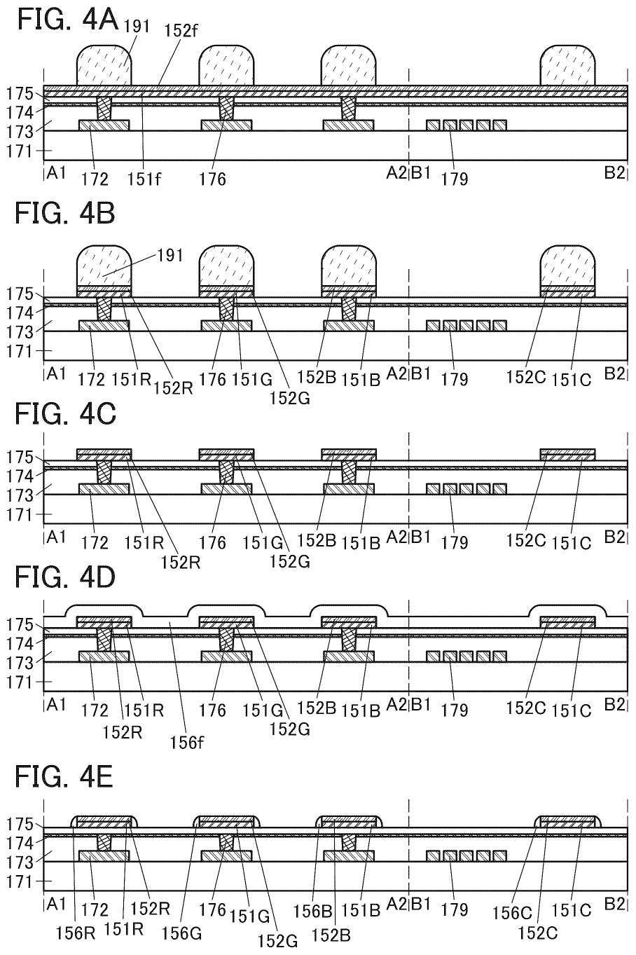

Next, a manufacturing method example of the display device having the structure illustrated in FIG. 3A is described with reference to FIGS. 4A to 4E, FIGS. 5A and 5B, FIGS. 6A to 6D, FIGS. 7A to 7C, FIGS. 8A to 8C, and FIGS. 9A to 9C.

### [Manufacturing Method Example]

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an atomic layer deposition (ALD) method, or the like.

Thin films included in the display device (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

Thin films included in the display device can be processed by a photolithography technique, for example.

As light used for exposure in the photolithography technique, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used.

For etching of thin films, a dry etching method, a wet etching method, a sandblast method, or the like can be used.

First, as illustrated in FIG. 4A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 4A, openings reaching the conductive layer 172 are formed in the insulating layers 175, 174, and 173. Then, the plugs 176 are formed to fill the openings.

Next, as illustrated in FIG. 4A, a conductive film 151f to be the conductive layers 151R, 151G, 151B, and 151C and a conductive film 152f to be the conductive layers 152R, 152G, and 152B, and a conductive layer 152C are formed over the plugs 176 and the insulating layer 175. A metal material can be used for the conductive film 151f, for example. For the conductive film 152f, an oxide containing one or more selected from indium, tin, zinc, gallium, titanium, aluminum, and silicon can be used.

Then, a resist mask 191 is formed over the conductive film 152f as illustrated in FIG. 4A. The resist mask 191 can be formed by application of a photosensitive material (photoresist), light exposure, and development.

Subsequently, as illustrated in FIG. 4B, the conductive films 151f and 152f in a region not overlapping with the resist mask 191 are removed, for example. In this manner, the conductive layers 151 and 152 are formed.

Next, the resist mask 191 is removed as illustrated in FIG. 4C. The resist mask 191 can be removed by ashing using oxygen plasma, for example.

Then, as illustrated in FIG. 4D, an insulating film 156f to be an insulating layer 156R, an insulating layer 156G, an insulating layer 156B, and an insulating layer 156C is formed over the conductive layer 152R, the conductive layer 152G, the conductive layer 152B, the conductive layer 152C, and the insulating layer 175.

As the insulating film 156f, an inorganic insulating film such as an oxide insulating film, a nitride insulating film, an oxynitride insulating film, or a nitride oxide insulating film, e.g., silicon oxynitride, can be used.

Subsequently, as illustrated in FIG. 4E, the insulating film 156f is processed to form the insulating layers 156R, 156G, 156B, and 156C.

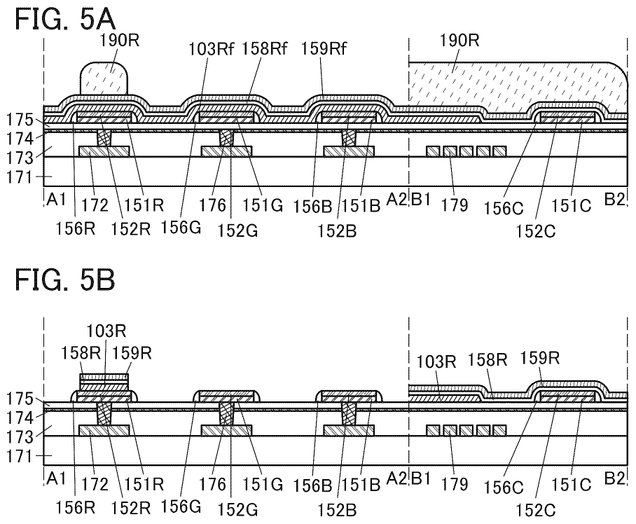

Next, as illustrated in FIG. 5A, an organic compound film 103Rf is formed over the conductive layers 152R, 152G, and 152B and the insulating layer 175. As illustrated in FIG. 5A, the organic compound film 103Rf is not formed over the conductive layer 152C.

Then, as illustrated in FIG. 5A, a sacrificial film 158Rf and a mask film 159Rf are formed.

Providing the sacrificial film 158Rf over the organic compound film 103Rf can reduce damage to the organic compound film 103Rf in the manufacturing process of the display device, resulting in an increase in the reliability of the light-emitting device.

As the sacrificial film 158Rf, a film that is highly resistant to the process conditions for the organic compound film 103Rf, specifically, a film having high etching selectivity with respect to the organic compound film 103Rf is used. As the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each higher than or equal to 100° C. and lower than or equal to 200° C., preferably higher than or equal to 100° C. and lower than or equal to 150° C., further preferably higher than or equal to 100° C. and lower than or equal to 120° C.

The sacrificial film 158Rf and the mask film 159Rf are preferably films that can be removed by a wet etching method or a dry etching method.

Note that the sacrificial film 158Rf that is formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials can be used, for example. It is particularly preferable to use a low-melting-point material such as aluminum or silver. It is preferable to use a metal material that can block ultraviolet rays for one or both of the sacrificial film 158Rf and the mask film 159Rf, in which case the organic compound film 103Rf can be inhibited from being irradiated with ultraviolet rays in patterning light exposure, and deterioration of the organic compound film 103Rf can be suppressed.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the above metal oxide, in place of gallium, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Rf and the mask film 159Rf are preferably formed using a semiconductor material such as silicon or germanium for excellent compatibility with a semiconductor manufacturing process. Alternatively, a compound containing the above semiconductor material can be used.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film.

Subsequently, a resist mask 190R is formed as illustrated in FIG. 5A. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display device.

Next, as illustrated in FIG. 5B, part of the mask film 159Rf is removed using the resist mask 190R, so that a mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), so that a sacrificial layer 158R is formed.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use a developer, an alkaline aqueous solution such as a tetramethylammonium hydroxide (TMAH) aqueous solution, or an acid aqueous solution such as dilute hydrofluoric acid, oxalic acid, phosphoric acid, acetic acid, nitric acid, or a chemical solution containing a mixed solution of any of these acids, for example.

In the case of using a dry etching method to process the sacrificial film 158Rf, deterioration of the organic compound film 103Rf can be suppressed by not using a gas containing oxygen as the etching gas.

The resist mask 190R can be removed by a method similar to that for the resist mask 191.

Next, as illustrated in FIG. 5B, the organic compound film 103Rf is processed to form the EL layer 103R. For example, part of the organic compound film 103Rf is removed using the mask layer 159R and the sacrificial layer 158R as a hard mask, whereby the EL layer 103R is formed.

Accordingly, as illustrated in FIG. 5B, the stacked-layer structure of the EL layer 103R, the sacrificial layer 158R, and the mask layer 159R remains over the conductive layer 152R. The conductive layers 152G and 152B are exposed.

The organic compound film 103Rf is preferably processed by anisotropic etching.

Anisotropic dry etching is particularly preferable. Alternatively, wet etching may be used.

In the case of using a dry etching method, deterioration of the organic compound film 103Rf can be suppressed by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas.

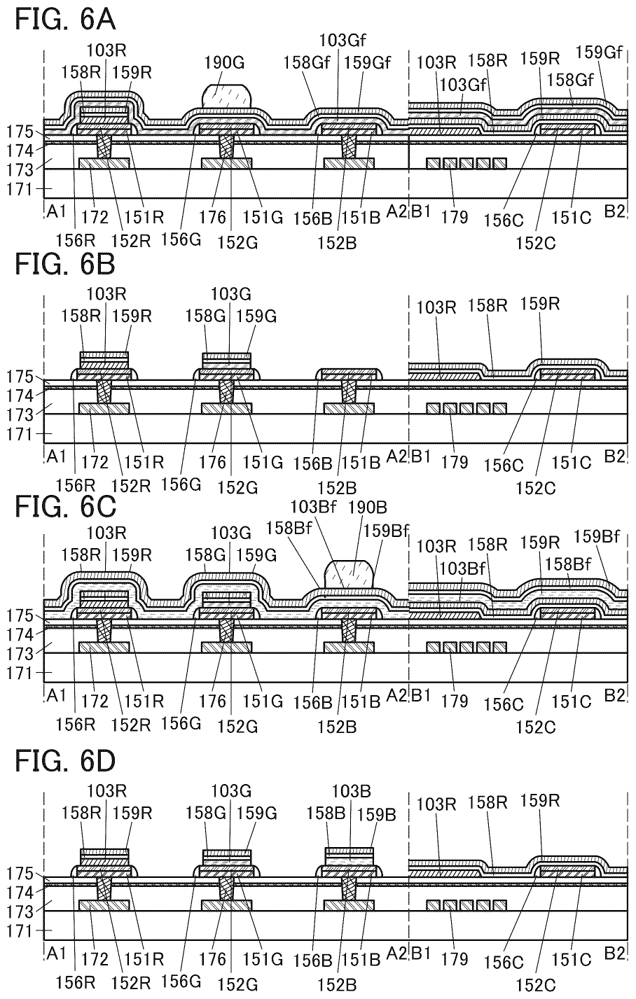

Then, as illustrated in FIG. 6A, an organic compound film 103Gf to be the EL layer 103G is formed.

The organic compound film 103Gf can be formed by a method similar to that for forming the organic compound film 103Rf. The organic compound film 103Gf can have a structure similar to that of the organic compound film 103Rf.

Subsequently, as illustrated in FIG. 6A, a sacrificial film 158Gf and a mask film 159Gf are formed in this order. After that, a resist mask 190G is formed. The materials and the formation methods of the sacrificial film 158Gf and the mask film 159Gf are similar to those for the sacrificial film 158Rf and the mask film 159Rf. The material and the formation method of the resist mask 190G are similar to those for the resist mask 190R.

The resist mask 190G is provided at a position overlapping with the conductive layer 152G.

Subsequently, as illustrated in FIG. 6B, part of the mask film 159Gf is removed using the resist mask 190G, so that a mask layer 159G is formed. The mask layer 159G remains over the conductive layer 152G. After that, the resist mask 190G is removed. Then, part of the sacrificial film 158Gf is removed using the mask layer 159G as a mask, so that a sacrificial layer 158G is formed. Next, the organic compound film 103Gf is processed to form the EL layer 103G.

Then, an organic compound film 103Bf is formed as illustrated in FIG. 6C.

The organic compound film 103Bf can be formed by a method similar to that for forming the organic compound film 103Rf. The organic compound film 103Bf can have a structure similar to that of the organic compound film 103Rf.

Subsequently, a sacrificial film 158Bf and a mask film 159Bf are formed in this order as illustrated in FIG. 6C. After that, a resist mask 190B is formed. The materials and the formation methods of the sacrificial film 158Bf and the mask film 159Bf are similar to those for the sacrificial film 158Rf and the mask film 159Rf. The material and the formation method of the resist mask 190B are similar to those for the resist mask 190R.

The resist mask 190B is provided at a position overlapping with the conductive layer 152B.

Subsequently, as illustrated in FIG. 6D, part of the mask film 159Bf is removed using the resist mask 190B, so that a mask layer 159B is formed. The mask layer 159B remains over the conductive layer 152B. After that, the resist mask 190B is removed. Then, part of the sacrificial film 158Bf is removed using the mask layer 159B as a mask, so that a sacrificial layer 158B is formed. Next, the organic compound film 103Bf is processed to form the EL layer 103B. For example, part of the organic compound film 103Bf is removed using the mask layer 159B and the sacrificial layer 158B as a hard mask, whereby the EL layer 103B is formed.

Accordingly, the stacked-layer structure of the EL layer 103B, the sacrificial layer 158B, and the mask layer 159B remains over the conductive layer 152B as illustrated in FIG. 6D. The mask layers 159R and 159G are exposed.

Note that the side surfaces of the EL layers 103R, 103G, and 103B are preferably perpendicular or substantially perpendicular to their formation surfaces. For example, the angle between the formation surfaces and these side surfaces is preferably greater than or equal to 60° and less than or equal to 90°.

The distance between two adjacent layers among the EL layers 103R, 103G, and 103B, which are formed by a photolithography technique as described above, can be reduced to less than or equal to 8 μm, less than or equal to 5 μm, less than or equal to 3 μm, less than or equal to 2 μm, or less than or equal to 1 μm. Here, the distance can be specified, for example, by the distance between opposite end portions of two adjacent layers among the EL layers 103R, 103G, and 103B. Reducing the distance between the island-shaped EL layers makes it possible to provide a display device having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

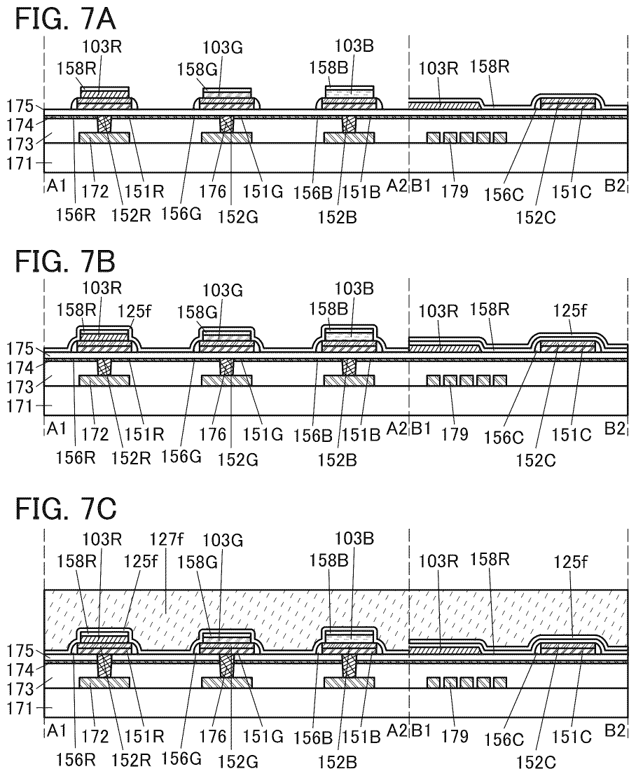

Next, the mask layers 159R, 159G, and 159B are preferably removed as illustrated in FIG. 7A.

The step of removing the mask layers can be performed by a method similar to that for the step of processing the mask films. Specifically, by using a wet etching method, damage caused to the EL layer 103 at the time of removing the mask layers can be reduced as compared to the case of using a dry etching method.

The mask layers may be removed by being dissolved in a polar solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, an inorganic insulating film 125f is formed as illustrated in FIG. 7B.

Then, as illustrated in FIG. 7C, an insulating film 127f to be the insulating layer 127 is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness of 3 nm or more, 5 nm or more, or 10 nm or more and 200 nm or less, 150 nm or less, 100 nm or less, or 50 nm or less is preferably formed at a substrate temperature in the above-described range.

The inorganic insulating film 125f is preferably formed by an ALD method, for example. An ALD method is preferably used, in which case deposition damage is reduced and a film with good coverage can be formed. As the inorganic insulating film 125f, an aluminum oxide film is preferably formed by an ALD method, for example.

The insulating film 127f is preferably formed by the aforementioned wet process. For example, the insulating film 127f is preferably formed by spin coating using a photosensitive material, and specifically preferably formed using a photosensitive resin composition containing an acrylic resin.

Then, part of the insulating film 127f is exposed to visible light or ultraviolet rays. The insulating layer 127 is formed in regions that are sandwiched between any two of the conductive layers 152R, 152G, and 152B and around the conductive layer 152C.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

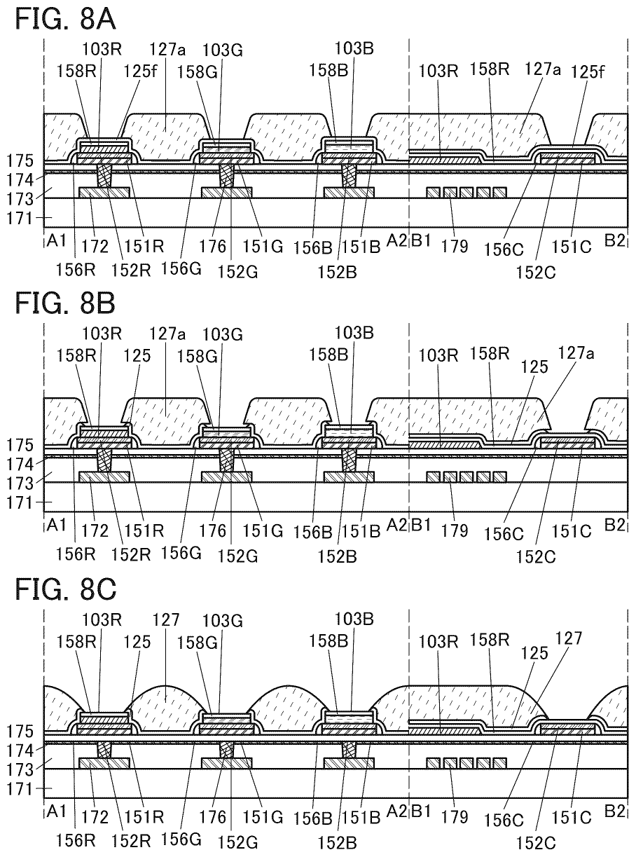

Next, the region of the insulating film 127f exposed to light is removed by development as illustrated in FIG. 8A, so that an insulating layer 127a is formed.

Next, as illustrated in FIG. 8B, etching treatment is performed using the insulating layer 127a as a mask to remove part of the inorganic insulating film 125f and reduce the thickness of part of the sacrificial layers 158R, 158G, and 158B. Thus, the inorganic insulating layer 125 is formed under the insulating layer 127a. Moreover, the surfaces of the thin portions in the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed concurrently.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of a wet etching method can reduce damage to the EL layers 103R, 103G, and 103B, as compared to the case of using a dry etching method. Wet etching can be performed using an alkaline solution, for example. For instance, TMAH aqueous solution, which is an alkaline solution, can be used for the wet etching of an aluminum oxide film. Alternatively, an acid solution containing fluoride can also be used. In this case, puddle wet etching can be performed. Note that the inorganic insulating film 125f is preferably formed using a material similar to that of the sacrificial layers 158R, 158G, and 158B, in which case the above etching treatment can be performed concurrently.

The sacrificial layers 158R, 158G, and 158B are not completely removed by the first etching treatment, and the etching treatment is stopped when the thicknesses of the sacrificial layers 158R, 158G, and 158B are reduced. The corresponding sacrificial layers 158R, 158G, and 158B remain over the EL layers 103R, 103G, and 103B in this manner, whereby the EL layers 103R, 103G, and 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) exists as each of the sacrificial layers 158R, 158G, and 158B, diffusion of oxygen into the EL layers 103R, 103G, and 103B can be suppressed.

Then, heat treatment (also referred to as post-baking) is performed. The heat treatment can change the insulating layer 127a into the insulating layer 127 having a tapered side surface (FIG. 8C). The heat treatment is conducted at a temperature lower than the upper temperature limit of the EL layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the EL layers 103R, 103G, and 103B can be prevented from being damaged and deteriorating in the heat treatment. This increases the reliability of the light-emitting device.

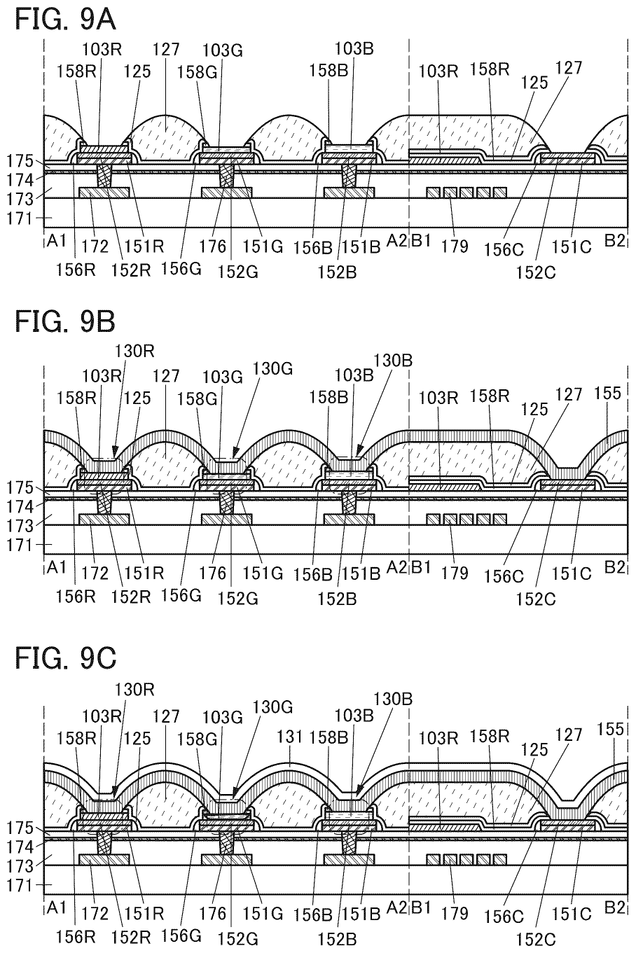

Next, as illustrated in FIG. 9A, etching treatment is performed using the insulating layer 127 as a mask to remove part of the sacrificial layers 158R, 158G, and 158B. Thus, openings are formed in the sacrificial layers 158R, 158G, and 158B, and the top surfaces of the EL layers 103R, 103G, and 103B and the conductive layer 152C are exposed. Note that this etching treatment may be hereinafter referred to as second etching treatment.

The end portion of the inorganic insulating layer 125 is covered with the insulating layer 127. FIG. 9A illustrates an example in which part of the end portion of the sacrificial layer 158G (specifically, a tapered portion formed by the first etching treatment) is covered with the insulating layer 127 and a tapered portion formed by the second etching treatment is exposed.

The second etching treatment is performed by wet etching. The use of a wet etching method can reduce damage to the EL layers 103R, 103G, and 103B, as compared to the case of using a dry etching method. Wet etching can be performed using an alkaline solution or an acidic solution, for example. An aqueous solution is preferably used in order that the EL layer 103 is not dissolved.

Next, as illustrated in FIG. 9B, a common electrode 155 is formed over the EL layers 103R, 103G, and 103B, the conductive layer 152C, and the insulating layer 127. The common electrode 155 can be formed by a sputtering method, a vacuum evaporation method, or the like.

Next, as illustrated in FIG. 9C, the protective layer 131 is formed over the common electrode 155. The protective layer 131 can be formed by a vacuum evaporation method, a sputtering method, a CVD method, an ALD method, or the like.

Then, the substrate 120 is bonded to the protective layer 131 using the resin layer 122, so that the display device can be manufactured. In the method for manufacturing the display device of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display device and inhibit generation of defects.

As described above, in the method for manufacturing the display device in one embodiment of the present invention, the island-shaped EL layers 103R, 103G, and 103B are formed not by using a fine metal mask but by processing a film formed on the entire surface; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the EL layers 103R, 103G, and 103B can be inhibited from being in contact with each other in the adjacent subpixels. As a result, generation of leakage current between the subpixels can be inhibited. This can prevent crosstalk, so that a display device with extremely high contrast can be obtained. Moreover, even a display device that includes tandem light-emitting devices manufactured by a photolithography technique can have favorable characteristics.

### Embodiment 4

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, desktop and notebook personal computers, a monitor of a computer and the like, digital signage, and a large game machine such as a pachinko machine.

### [Display Module]

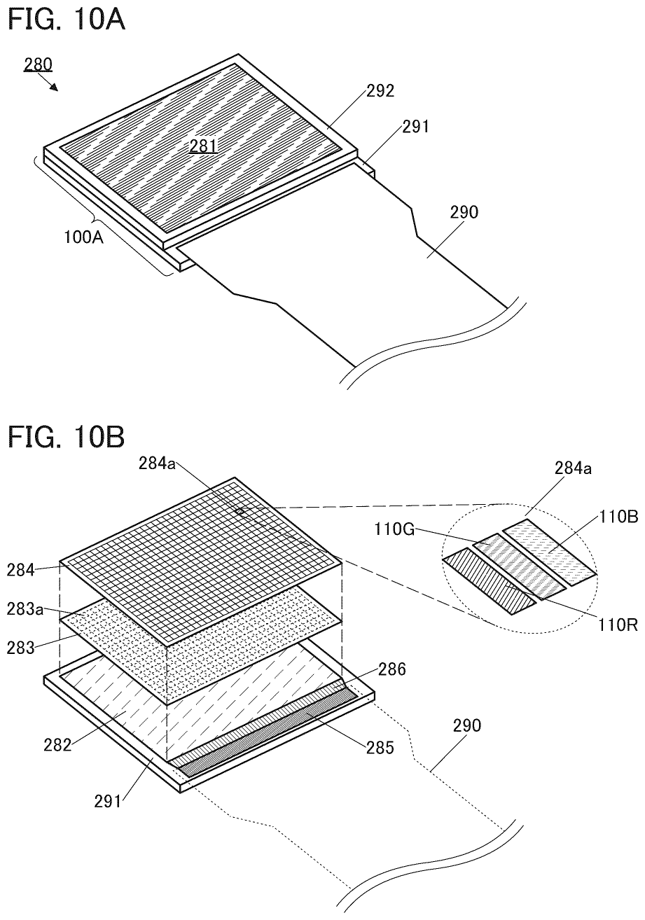

FIG. 10A is a perspective view of a display module 280. The display module 280 includes a display device 100A and an FPC 290. Note that the display device included in the display module 280 is not limited to the display device 100A and may be any of display devices 100B to 100E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 10B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 10B. The pixels 284a can employ any of the structures described in the above embodiments. FIG. 10B illustrates an example where the pixel 284a has a structure similar to that of the pixel 178 illustrated in FIG. 3A.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion.

### [Display Device 100A]

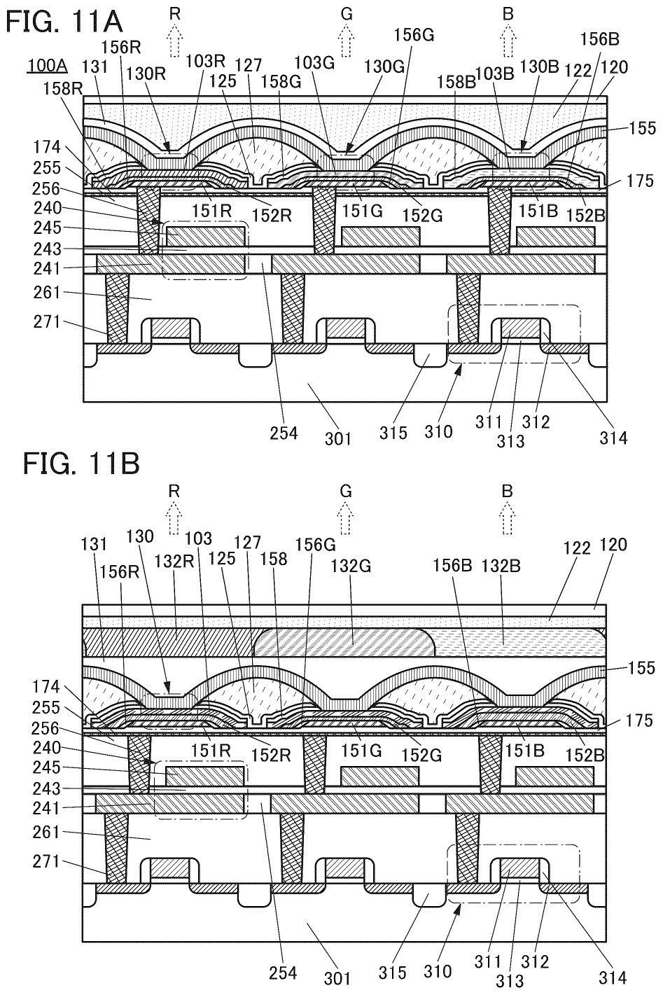

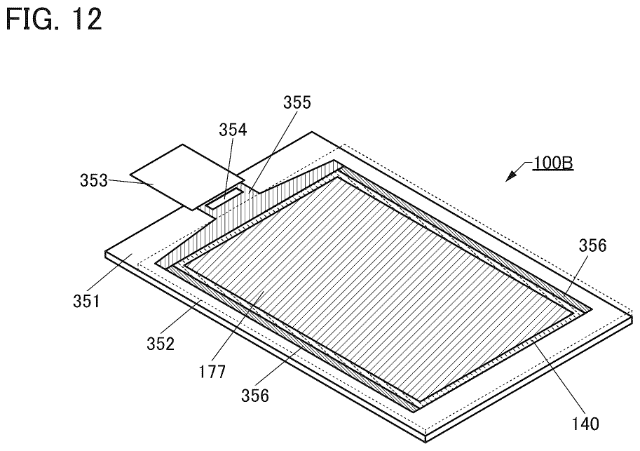

The display device 100A illustrated in FIG. 11A includes a substrate 301, the light-emitting devices 130R, 130G, and 130B, a capacitor 240, and a transistor 310.

The substrate 301 corresponds to the substrate 291 in FIGS. 10A and 10B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the EL layer 103R. The sacrificial layer 158G is positioned over the EL layer 103G. The sacrificial layer 158B is positioned over the EL layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is bonded to the protective layer 131 with the resin layer 122. Embodiment 3 can be referred to for the details of the light-emitting device 130 and the components thereover up to the substrate 120. The substrate 120 corresponds to the substrate 292 in FIG. 10A.

FIG. 11B illustrates a variation example of the display device 100A illustrated in FIG. 11A. The display device illustrated in FIG. 11B includes a coloring layer 132R, a coloring layer 132G, and a coloring layer 132B, and each of the light-emitting devices 130 includes a region overlapping with one of the coloring layers 132R, 132G, and 132B. In the display device illustrated in FIG. 11B, the light-emitting device 130 can emit white light, for example. The coloring layer 132R, the coloring layer 132G, and the coloring layer 132B can transmit red light, green light, and blue light, respectively, for example.

### [Display Device 100B]

FIG. 12 is a perspective view of the display device 100B.

In the display device 100B, a substrate 352 and a substrate 351 are bonded to each other. In FIG. 12, the substrate 352 is denoted by a dashed line.

The display device 100B includes the pixel portion 177, the connection portion 140, a circuit 356, a wiring 355, and the like. FIG. 12 illustrates an example in which an IC 354 and an FPC 353 are mounted on the display device 100B. Thus, the structure illustrated in FIG. 12 can be regarded as a display module including the display device 100B, the integrated circuit (IC), and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 12 illustrates an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

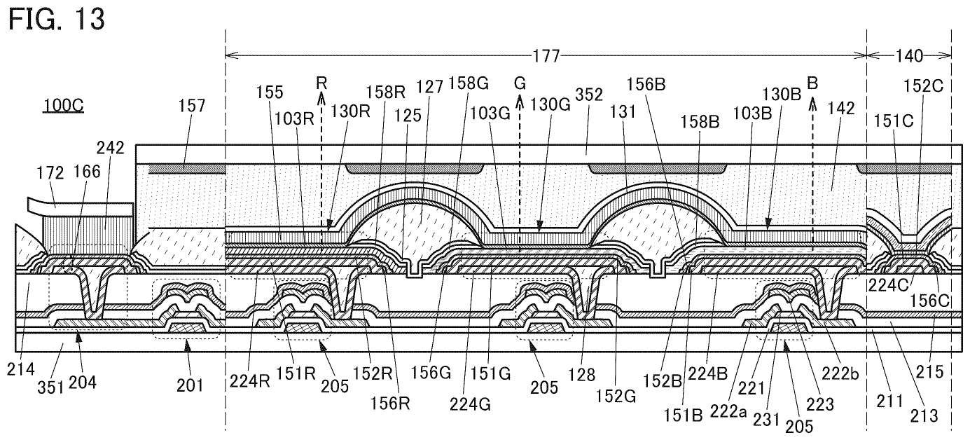

FIG. 13 illustrates an example of cross sections of part of a region including the FPC 353, part of the circuit 356, part of the pixel portion 177, part of the connection portion 140, and part of a region including an end portion of the display device 100B.

### [Display Device 100C]

The display device 100C illustrated in FIG. 13 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiments 1 and 2 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G, and the insulating layer 156G in the light-emitting device 130G are not described in detail because they are respectively similar to the conductive layers 224B, 151B, and 152B, and the insulating layer 156B in the light-emitting device 130B; the same applies to the conductive layers 224R, 151R, and 152R, and the insulating layer 156R in the light-emitting device 130R.

The conductive layers 224R, 224G, and 224B each have a depression portion covering the opening provided in the insulating layer 214. A layer 128 is embedded in the depression portion.

The layer 128 has a function of filling the depression portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depression portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-block layer 157. A solid sealing structure, a hollow sealing structure, or the like can be employed to seal the light-emitting device 130. In FIG. 13, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Alternatively, the space may be filled with a resin other than the frame-like adhesive layer 142.

FIG. 13 illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 13, the insulating layer 156C is provided to include a region overlapping with the side surface of the conductive layer 151C.

The display device 100B has a top-emission structure. Light from the light-emitting device is emitted toward the substrate 352. For the substrate 352, a material having a high visible-light-transmitting property is preferably used. In the case where the light-emitting device emits infrared or near-infrared light, a material having a high transmitting property with respect to infrared or near-infrared light is preferably used. The pixel electrode contains a material that reflects visible light, and the counter electrode (the common electrode 155) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, one of the source electrode and the drain electrode of the transistor 202 is electrically connected to an FPC 372 through a conductive layer 166 and a connection layer 242. As an example, the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-block layer 157 is preferably provided on the surface of the substrate 352 on the substrate 351 side. The light-block layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

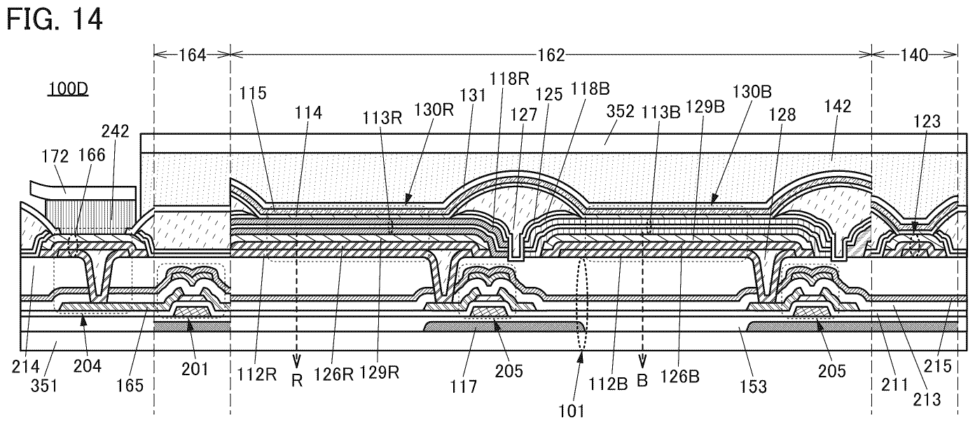

The display device 100D illustrated in FIG. 14 differs from the display device 100C in FIG. 13 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

The light-block layer is preferably formed between the substrate 351 and the transistor 201 and between the substrate 351 and the transistor 205. FIG. 14 illustrates an example where the light-block layer is provided over the substrate 351, an insulating layer 153 is provided over the light-block layer, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the common electrode 155.

Although not illustrated in FIG. 14, the light-emitting device 130G is also provided.

Although FIG. 14 and the like illustrate an example in which the top surface of the layer 128 includes a flat portion, the shape of the layer 128 is not particularly limited.

### [Display Device 100D2]

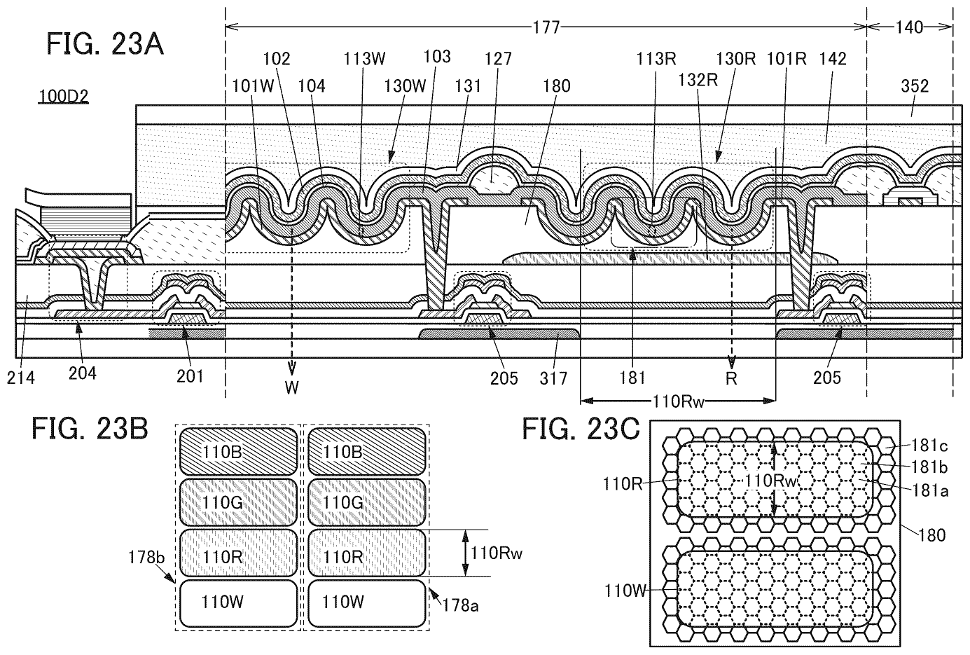

A display device 100D2 illustrated in FIG. 23 is an example of a bottom-emission display device different from the display device 100D illustrated in FIG. 14. The display device 100D2 is different from the display device 100D in that an organic resin layer 180 is included. Note that the reference numerals of the components that are the same as those in FIG. 14 are sometimes omitted and the description for FIG. 14 is preferably referred to for the details of such components.

FIG. 23B is a top-view layout of the pixel 178 (pixels 178a and 178b) including the subpixel 110 (the subpixels 110R, 110G, and 110B and a subpixel 110W), and FIG. 23C is a top view of the organic resin layer 180 in a region where the subpixels 110R and 110W included in the pixel 178 are formed. A region of the subpixel 110R between the light-blocking layers 317 can be represented as a width 110Rw in a light-emitting region.

As illustrated in FIG. 23A, the organic resin layer 180 is provided over the insulating layer 214. As shown in FIG. 23C and the region surrounded by the dashed-dotted line in FIG. 23A, the organic resin layer 180 includes a depressed portion 181 (depressed portions 181a and 181b) having a curved surface at least in a region where the subpixel is formed. Note that the depressed portion 181 may be provided outside the light-emitting region, like a depressed portion 181c. With the depressed portion 181c, light emission generated in a region overlapping with the light-blocking layer 317 or light travelled into the region overlapping with the light-blocking layer 317 can be refracted and extracted from the light-emitting region, whereby emission efficiency can be improved.

A plurality of depressed portions 181 may be formed in a matrix. The depressed portions 181a and 181b may be provided in contact with each other or may be provided to have a flat surface therebetween.

In FIG. 23, although the top surface shape and the cross-sectional shape of the depressed portion are hexagonal (FIG. 23C) and semicircular (FIG. 23A), respectively, other shapes may be employed as needed. Examples of a top surface shape of the depressed portion include polygons such as a triangle, a tetragon (including a rectangle and a square), and a pentagon; polygons with rounded corners; an ellipse; and a circle.

An insulating layer containing an organic material can be used as the organic resin layer 180. Examples of materials used for the organic resin layer 180 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The organic resin layer 180 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the organic resin layer 180. A photoresist may be used for the photosensitive resin. As the photosensitive resin, a positive photosensitive material or a negative photosensitive material can be used.

The organic resin layer 180 may contain a material absorbing visible light. For example, the organic resin layer 180 itself may be made of a material absorbing visible light, or the organic resin layer 180 may contain a pigment absorbing visible light. For example, the organic resin layer 180 can be formed using a resin that can be used as a color filter transmitting red, blue, or green light and absorbing light of the other colors; or a resin that contains carbon black as a pigment and functions as a black matrix.

The first electrode 101 (the first electrode 101R and a first electrode 101W) is over the organic resin layer 180 and the EL layer 103 is over the first electrode 101. End portions of the first electrode 101 and the EL layer 103 may be covered with the insulating layer 127.

The first electrode 101 formed over the organic resin layer 180 also has a depressed portion along the depressed portion of the organic resin layer 180. The EL layer 103 formed over the first electrode 101 also has a depressed portion along the depressed portion of the first electrode 101. A common layer 104 formed over the EL layer 103 also has a depressed portion along the depressed portion of the EL layer 103. The second electrode 102 formed over the common layer 104 also has a depressed portion along the depressed portion of the common layer 104. That is, the depressed portions of the organic resin layer 180, the first electrode 101, the EL layer 103, the common layer 104, and the second electrode 102 overlap with each other.

The common layer 104 is provided over the EL layer 103 and the insulating layer 127, and the second electrode 102 is provided over the common layer 104. The protective layer 131 is provided over the second electrode 102 and bonded to the substrate 352 with the adhesive layer 142 therebetween.

Although the light-emitting devices 130G and 130B are not illustrated in FIG. 23, the light-emitting devices 130G and 130B are also provided.

The above-described light-emitting apparatus of one embodiment of the present invention including the organic resin layer 180 includes the electron-injection layer as described in Embodiment 1, whereby an organic semiconductor device with high reliability, low driving voltage, and low power consumption can be provided.

### [Display Device 100E]

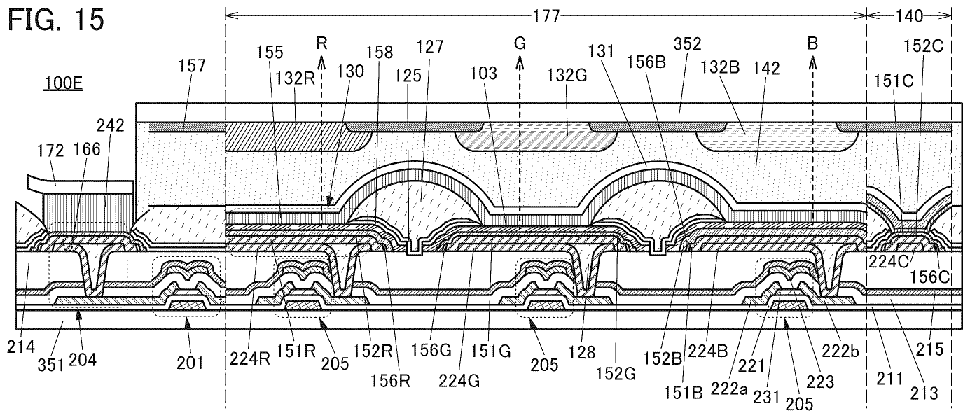

The display device 100E illustrated in FIG. 15 is a variation example of the display device 100C illustrated in FIG. 13 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-block layer 157.

In the display device 100E, the light-emitting device 130 can emit white light, for example. The coloring layer 132R, the coloring layer 132G, and the coloring layer 132B can transmit red light, green light, and blue light, respectively, for example. Note that in the display device 100E, the coloring layers 132R, 132G, and 132B may be provided between the protective layer 131 and the adhesive layer 142.

Although FIGS. 13, 14, and 15 and the like illustrate an example where the top surface of the layer 128 includes a flat portion, the shape of the layer 128 is not particularly limited.

This embodiment can be combined as appropriate with the other embodiments or the examples. In this specification, in the case where a plurality of structure examples are shown in one embodiment, the structure examples can be combined as appropriate.

### [Display Device 100E2]

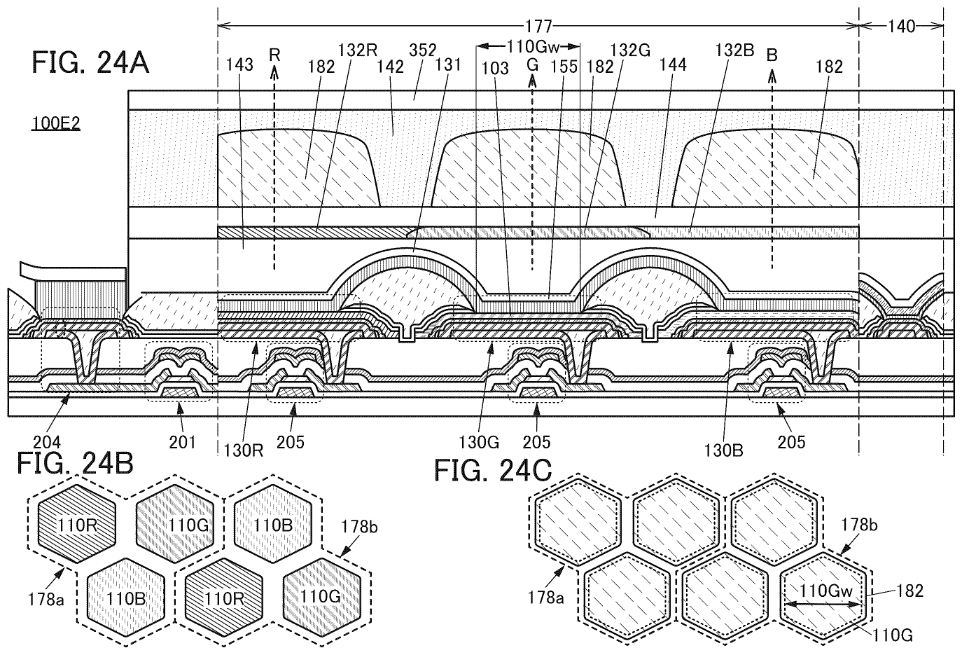

A display device 100E2 illustrated in FIG. 24 is a variation example of the display device 100E illustrated in FIG. 15 and includes microlenses 182 over the coloring layers 132R, 132G, and 132B. Note that reference numerals of components that are the same as those in FIG. 15 are omitted in some cases in the drawings, and the description for FIG. 15 is preferably referred to for the details of such components.

FIG. 24B is a top-view layout of the pixel 178 (the pixels 178a and 178b) including the subpixel 110 (the subpixels 110R, 110G, and 110B), and FIG. 24C is a top view of the microlens 182 in a region where the subpixels 110R and 110G included in the pixel 178 are formed. A region of the subpixel 110G where the common electrode 155 and the EL layer 103 are in contact with each other can be represented as a width 110Gw in a light-emitting region.

In the display device 100E2 illustrated in FIG. 24A, a planarization film 143 over the protective layer 131 is provided, and the coloring layers 132R, 132G, and 132B are provided over a planarization film 144. The planarization film 144 is provided to cover the coloring layers 132R, 132G, and 132B. The microlenses 182 are provided over the planarization film 144.

Note that as illustrated in FIG. 24C, the microlens 182 is preferably provided for each of the subpixels in a region where the subpixel is formed.

Although the top surface shape of the microlens 182 is illustrated as a hexagon in FIG. 24C, other shapes may be employed as needed. Examples of a top surface shape of the depressed portion include polygons such as a triangle, a tetragon (including a rectangle and a square), and a pentagon; polygons with rounded corners; an ellipse; and a circle.

The microlens 182 can be formed using a material similar to that for the organic resin layer 180.

The above-described light-emitting apparatus of one embodiment of the present invention including the microlens 182 includes the organic EL device including the electron-injection layer as described in Embodiment 1, whereby an organic semiconductor device with high reliability, low driving voltage, and low power consumption, which is suitable for a mobile display, can be provided.

### Embodiment 5

In this embodiment, electronic devices of one embodiment of the present invention will be described.

Electronic devices of this embodiment include the display device of one embodiment of the present invention in their display portions. The display device of one embodiment of the present invention has high display performance and can be easily increased in resolution and definition. Thus, the display device of one embodiment of the present invention can be used for display portions of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer and the like, digital signage, and a large game machine such as a pachinko machine.

In particular, the display device of one embodiment of the present invention can have high resolution, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, odor, or infrared rays).

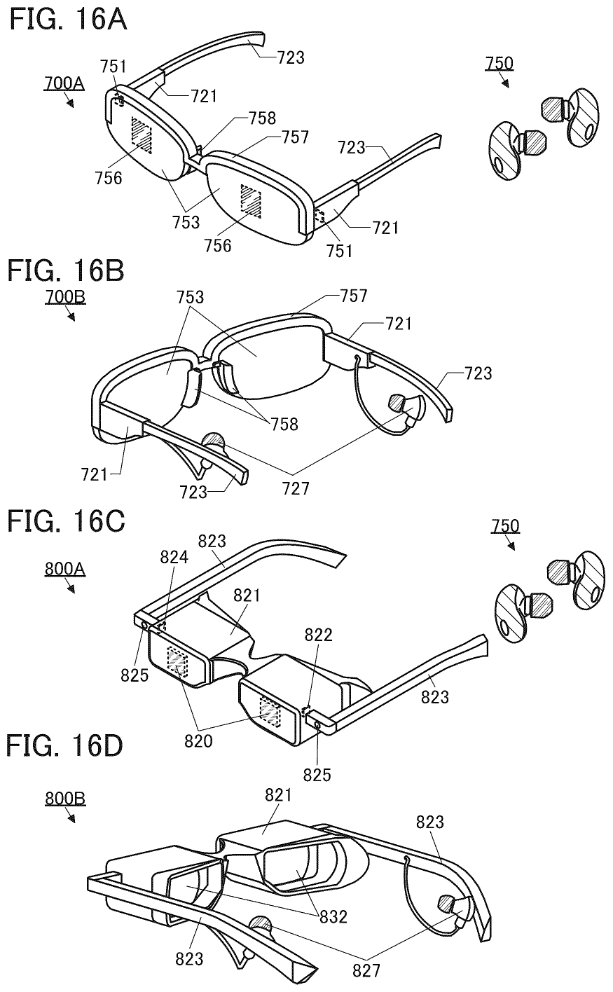

Examples of head-mounted wearable devices are described with reference to FIGS. 16A to 16D.

An electronic device 700A illustrated in FIG. 16A and an electronic device 700B illustrated in FIG. 16B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices can be highly reliable.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic devices 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic device 800A illustrated in FIG. 16C and an electronic device 800B illustrated in FIG. 16D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic devices can be highly reliable.

The display portions 820 are positioned inside the housing 821 so as to be seen through the lenses 832. When the pair of display portions 820 display different images, three-dimensional display using parallax can be performed.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes.

The electronic device 800A or the electronic device 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic device 800A may include a vibration mechanism that functions as bone-conduction earphones.

The electronic devices 800A and 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750.

The electronic device may include an earphone portion. The electronic device 700B in FIG. 16B includes earphone portions 727. Part of a wiring that connects the earphone portion 727 and the control portion may be positioned inside the housing 721 or the mounting portion 723.

Similarly, the electronic device 800B in FIG. 16D includes earphone portions 827. For example, the earphone portion 827 can be connected to the control portion 824 by wire.

As described above, both the glasses-type device (e.g., the electronic devices 700A and 700B) and the goggles-type device (e.g., the electronic devices 800A and 800B) are preferable as the electronic device of one embodiment of the present invention.

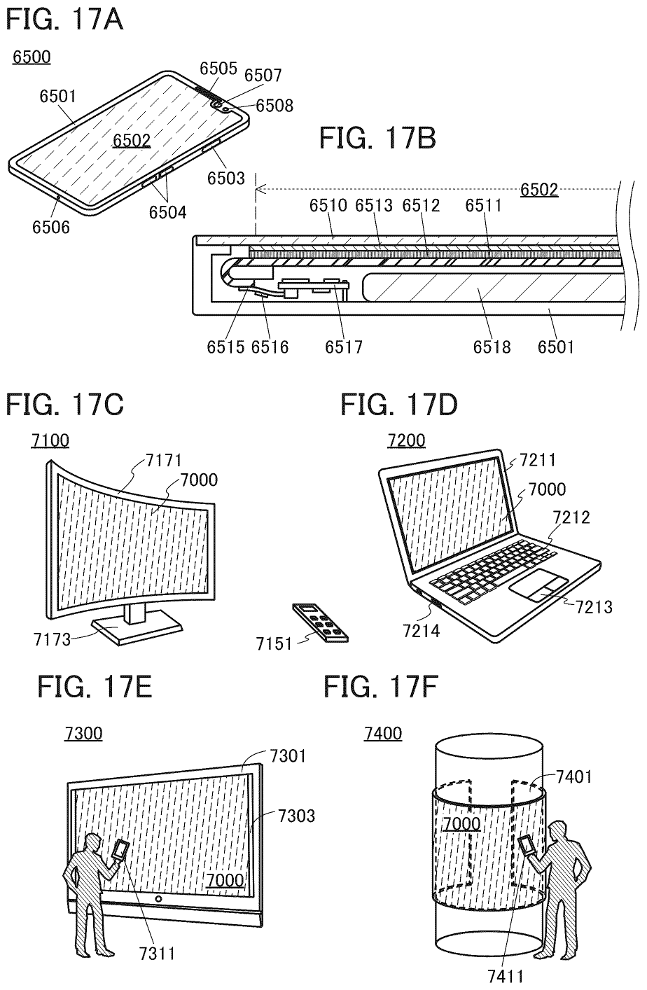

An electronic device 6500 illustrated in FIG. 17A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, the electronic device can be highly reliable.

FIG. 17B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used in the display panel 6511. Thus, the electronic device can be extremely lightweight. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby the electronic device can have a narrow bezel.

FIG. 17C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, a highly reliable electronic device is obtained.

Operation of the television device 7100 illustrated in FIG. 17C can be performed with an operation switch provided in the housing 7171 and a separate remote controller 7151.

FIG. 17D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, a highly reliable electronic device is obtained.

FIGS. 17E and 17F illustrate examples of digital signage.

Digital signage 7300 illustrated in FIG. 17E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 17F illustrates digital signage 7400 attached to a cylindrical pillar 7401. The digital signage 7400 includes the display portion 7000 provided along a curved surface of the pillar 7401.

In FIGS. 17E and 17F, the display device of one embodiment of the present invention can be used in the display portion 7000. Thus, a highly reliable electronic device is obtained.

A larger area of the display portion 7000 can increase the amount of information that can be provided at a time. The display portion 7000 having a larger area attracts more attention, so that the effectiveness of the advertisement can be increased, for example.

As illustrated in FIGS. 17E and 17F, it is preferable that the digital signage 7300 or the digital signage 7400 can work with an information terminal 7311 or an information terminal 7411, such as a smartphone that a user has, through wireless communication.

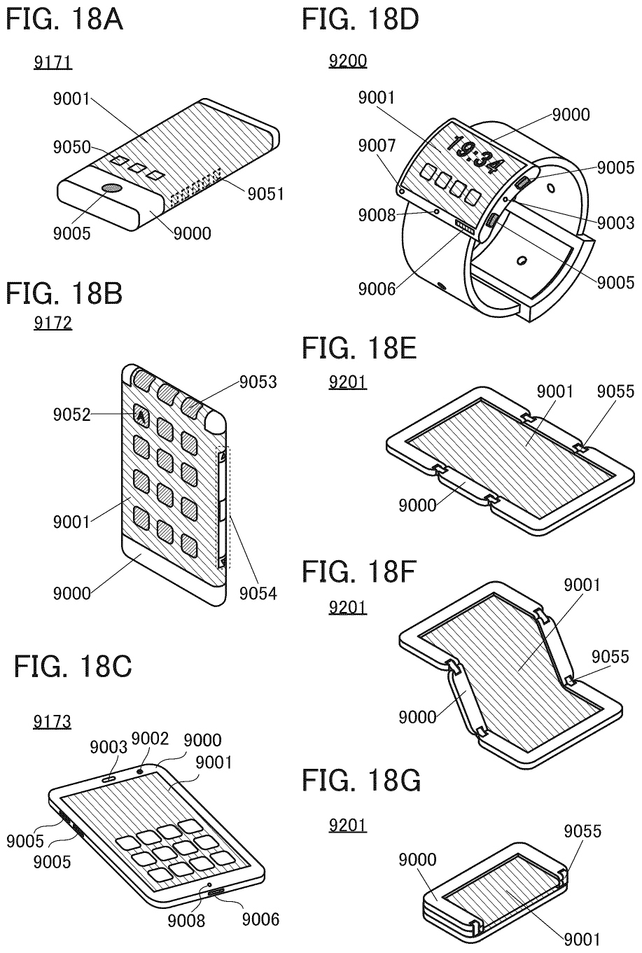

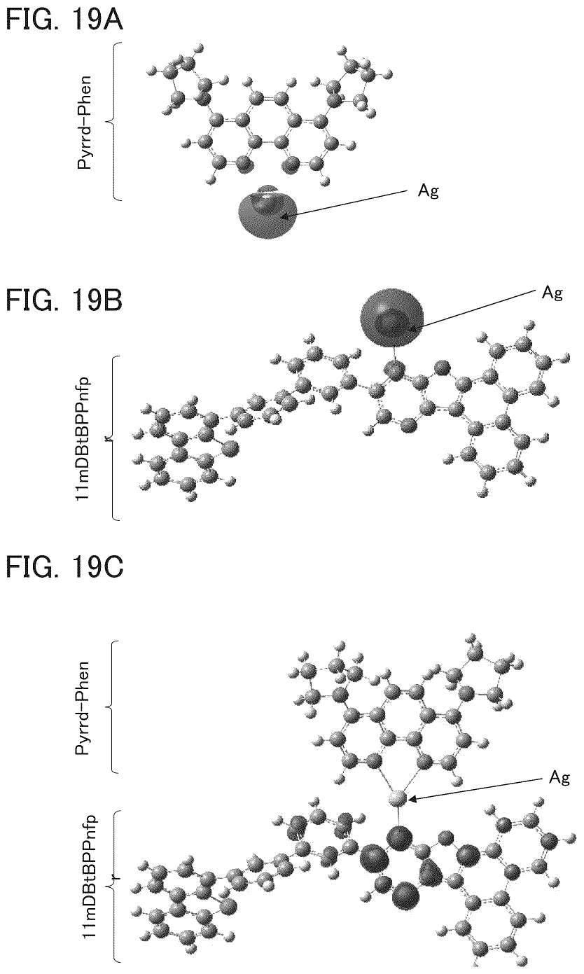

Electronic devices illustrated in FIGS. 18A to 18G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared rays), a microphone 9008, and the like.

The electronic devices illustrated in FIGS. 18A to 18G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The electronic devices in FIGS. 18A to 18G are described in detail below.

FIG. 18A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 18A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 18B is a perspective view of a portable information terminal 9172. The portable information terminal 9172 has a function of displaying information on three or more surfaces of the display portion 9001. Here, information 9052, information 9053, and information 9054 are displayed on the respective surfaces. For example, the user of the portable information terminal 9172 can check the information 9053 displayed such that it can be seen from above the portable information terminal 9172, with the portable information terminal 9172 put in a breast pocket of his/her clothes.

FIG. 18C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 18D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 18E to 18G are perspective views of a foldable portable information terminal 9201. FIG. 18E is a perspective view illustrating the portable information terminal 9201 that is opened. FIG. 18G is a perspective view illustrating the portable information terminal 9201 that is folded. FIG. 18F is a perspective view illustrating the portable information terminal 9201 that is shifted from one of the states in FIGS. 18E and 18G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

Described in this example are specific methods for fabricating light-emitting devices 1-1 and 1-2 of embodiments of the present invention and a comparative light-emitting device 1, and characteristics of the light-emitting devices. Structural formulae of main compounds used in this example are shown below.

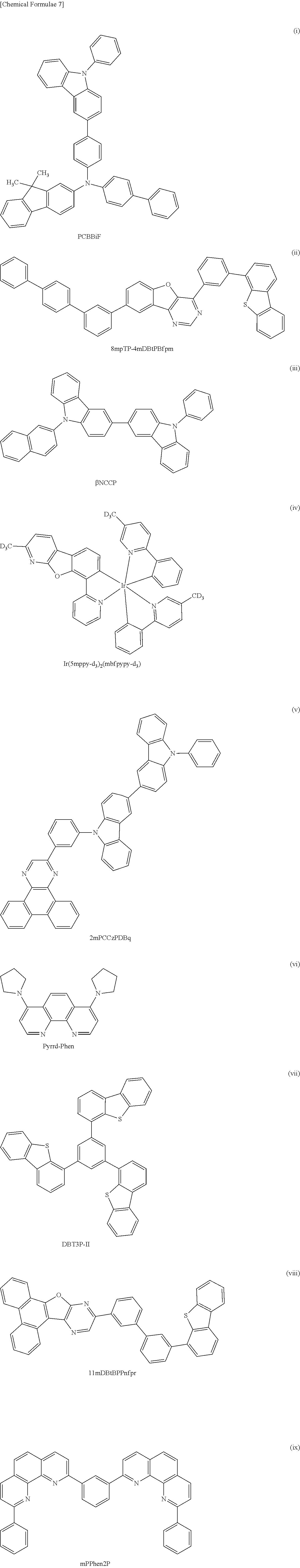

### (Fabrication Method of Light-Emitting Device 1-1)

First, 100-nm-thick alloy of silver, palladium, and copper (Ag—Pd—Cu or APC) and 50-nm-thick indium tin oxide containing silicon oxide (ITSO) were stacked over a glass substrate sequentially from the substrate side by a sputtering method as a reflective electrode and a transparent electrode, respectively, whereby the first electrode 101 with a size of 2 mm×2 mm was formed. Note that the transparent electrode functions as an anode, and the transparent electrode and the reflective electrode are collectively regarded as the first electrode 101.

Next, in pretreatment for forming the light-emitting device over a substrate, the surface of the substrate was washed with water, and baking was performed at 200° C. for one hour.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Then, the substrate was fixed to a holder provided in the vacuum evaporation apparatus such that the surface on which the first electrode 101 was formed faced downward. Over the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and an electron-accepting material having four or more fluorine atoms and a molecular weight of 672 (OCHD-003) were deposited by co-evaporation to a thickness of 10 nm such that the weight ratio of PCBBiF to OCHD-003 was 1:0.03, whereby the hole-injection layer 111 was formed.

Over the hole-injection layer 111, PCBBiF was deposited by evaporation to a thickness of 100 nm, whereby a hole-transport layer was formed.

Then, over the first hole-transport layer, 8-(p-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii) above, 9-(2-naphthyl)-9′-phenyl-9H,9′H-3,3′-bicarbazole (abbreviation: βNCCP) represented by Structural Formula (iii) above, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) represented by Structural Formula (iv) above were deposited by co-evaporation to a thickness of 40 nm such that the weight ratio of 8mpTP-4mDBtPBfpm, βNCCP, and Ir(5mppy-d₃)₂(mbfpypy-d₃) was 0.5:0.5:0.1, whereby a light-emitting layer was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above was deposited by evaporation to a thickness of 20 nm and 8mpTP-4mDBtPBfpm was further deposited by evaporation to a thickness of 15 nm, whereby an electron-transport layer was formed.

After the formation of the electron-transport layer, 8mpTP-4mDBtPBfpm, 4,7-di-1-pyrrolidinyl-1,10-phenanthroline (abbreviation: Pyrrd-Phen) which is represented by Structural Formula (vi) above, and indium (In) were deposited by co-evaporation to a thickness of 5 nm such that the volume ratio of 8mpTP-4mDBtPBfpm, Pyrrd-Phen, and In was 0.5:0.5:0.02, whereby an electron-injection layer was formed.

After that, silver (Ag) and magnesium (Mg) were deposited by co-evaporation to a thickness of 15 nm such that the volume ratio of Ag to Mg was 1:0.1, whereby the second electrode 102 was formed. Over the second electrode 102, 4,4′,4″-(benzene-1,3,5-triyl)tri(dibenzothiophene) (abbreviation: DBT3P-II) represented by Structural Formula (vii) above was deposited to a thickness of 70 nm as a cap layer to improve light extraction efficiency.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 1-1 was fabricated.

### (Method for Fabricating Light-Emitting Device 1-2)

The light-emitting device 1-2 was fabricated in a manner similar to that of the light-emitting device 1-1 except that 8mpTP-4mDBtPBfpm in the electron-injection layer of the light-emitting device 1-1 was replaced with 11-[3′-(dibenzothiophen-4-yl)biphenyl-3-yl]phenanthro[9′,10′:4,5]furo[2,3-b]pyrazine (abbreviation: 11mDBtBPPnfpr) represented by Structural Formula (viii) above and 11mDBtBPPnfpr, Pyrrd-Phen, and indium (In) were deposited by co-evaporation to a thickness of 5 nm such that the volume ratio of 11mDBtBPPnfpr, Pyrrd-Phen, and In was 0.5:0.5:0.02 to form an electron-injection layer.

### (Method for Fabricating Comparative Light-Emitting Device 1)

The comparative light-emitting device 1 was fabricated in a manner similar to that of the light-emitting device 1-1 except that 8mpTP-4mDBtPBfpm, Pyrrd-Phen, and In that are in the electron-injection layer of the light-emitting device 1-1, were replaced with 2,2′-(1,3-phenylene)bis(9-phenyl-1,10-phenanthroline) (abbreviation: mPPhen2P) represented by Structural Formula (ix) above and lithium oxide (Li₂O) and mPPhen2P and Li₂O were deposited by co-evaporation to a thickness of 5 nm such that the volume ratio of mPPhen2P to Li₂O was 1:0.02 to form an electron-injection layer.

Device structures of the light-emitting devices 1-1 and 1-2 and the comparative light-emitting device 1 are shown below.

TABLE 5

| | Thickness | | | Comparative |
|---|---|---|---|---|
| | (nm) | Light-emitting device 1-1 | Light-emitting device 1-2 | light-emitting device 1 |
| Cap layer | 70 | DBT3P-II | | |
| Second electrode | 15 | Ag:Mg (1:0.1) | | |
| Electron-injection layer | 5 | *1 | | |
| Electron-transport layer | 15 | 8mpTP-4mDBtPBfpm | | |
| | 20 | 2mPCCzPDBq | | |
| Light-emitting layer | 40 | 8mpTP-4mDBtPBfpm:βNCCP:Ir(5mppy-d₃)₂(mbfpypy-d₃) | | |
| | | (0.5:0.5:0.1) | | |
| Hole-transport layer | 100 | PCBBiF | | |
| Hole-injection layer | 10 | PCBBiF:OCHD-003 | | |
| | | (1:0.03) | | |
| First electrode | 50 | ITSO | | |
| | 100 | | APC | |

TABLE 6

| | *1 |
|---|---|
| Light-emitting device 1-1 | 8mpTP-4mDBtPBfpm:Pyrrd-Phen:In |
| | (0.5:0.5:0.02) |
| Light-emitting device 1-2 | 11mDBtBPPnfpr:Pyrrd-Phen:In |
| | (0.5:0.5:0.02) |
| Comparative light-emitting | mPPhen2P:Li₂O |
| device 1 | (1:0.02) |

Note that the LUMO levels of 8mpTP-4mDBtPBfpm and 11mDBtBPPnfpr, which are contained in the second organic compounds, were −3.01 eV and −3.02 eV, respectively. The LUMO level of mPPhen2P was −2.71 eV. Note that the LUMO level of Pyrrd-Phen, which is contained in the first organic compound, was −2.55 eV. In other words, the light-emitting devices 1-1 and 1-2 are light-emitting devices in which the LUMO level of the second organic compound is lower than that of the first organic compound by 0.20 eV or more, and the comparative light-emitting device 1 is a light-emitting device in which the LUMO level of the second organic compound is lower than that of the first organic compound and a difference in LUMO level between the first and second organic compounds is less than 0.20 eV.

Note that the LUMO level was obtained through cyclic voltammetry (CV) measurement.

In the cyclic voltammetry (CV) measurement, the values (E) of LUMO levels were calculated on the basis of an oxidation peak potential (Eₚₐ) and a reduction peak potential (E_{pc}), which were obtained by changing the potential of a working electrode with respect to a reference electrode. In the measurement, the LUMO level was obtained by potential scanning in negative direction. The scanning speed in the measurement was 0.1 V/s.

Specifically, a standard oxidation-reduction potential (Eₒ) (=Eₚₐ+E_{pc})/2) was calculated from an oxidation peak potential (Eₚₐ) and a reduction peak potential (E_{pc}), which were obtained by the cyclic voltammogram of a material. Then, the standard oxidation-reduction potential (Eₒ) was subtracted from the potential energy (Eₓ) of the reference electrode with respect to a vacuum level, whereby each of the values (E) (=Eₓ−Eₒ) of LUMO levels were obtained.

Note that the reversible oxidation-reduction wave was obtained in the above case; in the case where an irreversible oxidation-reduction wave is obtained, a value obtained by adding a predetermined value (0.1 eV) to a reduction peak potential (E_{pc}) is assumed to be an oxidation peak potential (Eₚₐ), and a standard oxidation-reduction potential (Eₒ) is calculated to one decimal place.

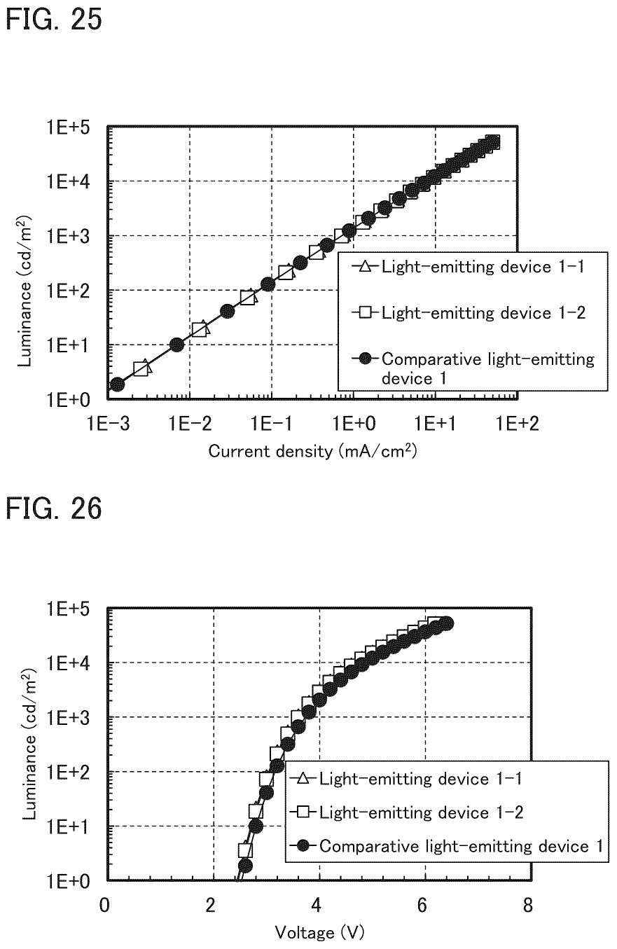

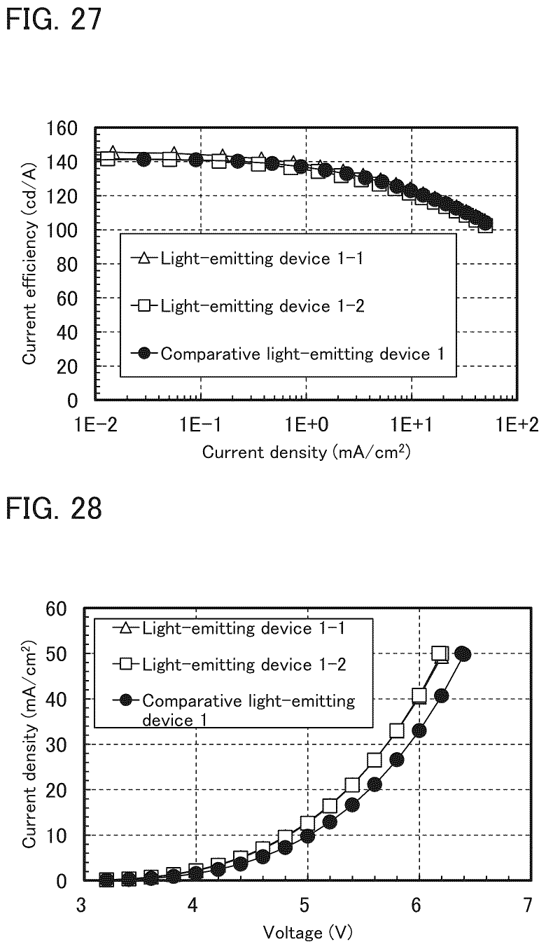

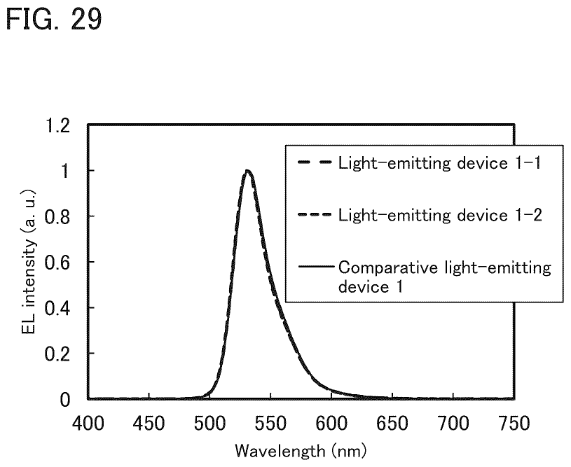

FIG. 25 shows luminance-current density characteristics of the light-emitting devices 1-1 and 1-2 and the comparative light-emitting device 1. FIG. 26 shows luminance-voltage characteristics thereof. FIG. 27 shows current efficiency-current density characteristics thereof. FIG. 28 shows current density-voltage characteristics thereof. FIG. 29 shows electroluminescence spectra thereof.

As can be seen from FIG. 25 to FIG. 29, the light-emitting devices 1-1 and 1-2 in which the LUMO level of the second organic compound is lower than that of the first organic compound by 0.20 ev or more were found to have favorable characteristics with lower driving voltage than the comparative light-emitting device 1 and highly efficient green light emission.

### Example 2

Described in this example are specific methods for fabricating light-emitting devices 2-1 and 2-2 of embodiments of the present invention and comparative light-emitting devices 2-1 and 2-2, and characteristics of the light-emitting devices. Structural formulae of main compounds used in this example are shown below.

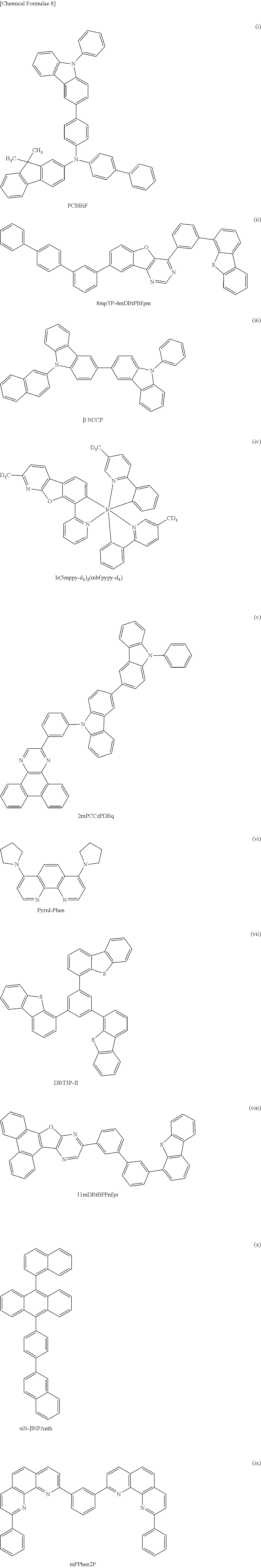

### (Fabrication Method of Light-Emitting Device 2-1)

First, 100-nm-thick alloy of silver, palladium, and copper (Ag—Pd—Cu, also referred to as APC) and 50-nm-thick indium tin oxide containing silicon oxide (JTSO) were stacked over a glass substrate sequentially from the substrate side by a sputtering method as a reflective electrode and a transparent electrode, respectively, whereby the first electrode 101 with a size of 2 mm×2 mm was formed. Note that the transparent electrode functions as an anode, and the transparent electrode and the reflective electrode are collectively regarded as the first electrode 101.

Next, in pretreatment for forming the light-emitting device over a substrate, the surface of the substrate was washed with water, and baking was performed at 200° C. for one hour.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Then, the substrate was fixed to a holder provided in the vacuum evaporation apparatus such that the surface on which the first electrode 101 was formed faced downward. Over the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and an electron-accepting material having four or more fluorine atoms and a molecular weight of 672 (OCHD-003) were deposited by co-evaporation to a thickness of 10 nm such that the weight ratio of PCBBiF to OCHD-003 was 1:0.03, whereby the hole-injection layer 111 was formed.

Over the hole-injection layer 111, PCBBiF was deposited by evaporation to a thickness of 100 nm, whereby a hole-transport layer was formed.

Then, over the first hole-transport layer, 8-(p-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii) above, 9-(2-naphthyl)-9′-phenyl-9H,9′H-3,3′-bicarbazole (abbreviation: βNCCP) represented by Structural Formula (iii) above, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) represented by Structural Formula (iv) above were deposited by co-evaporation to a thickness of 40 nm such that the weight ratio of 8mpTP-4mDBtPBfpm, βNCCP, and Ir(5mppy-d₃)₂(mbfpypy-d₃) was 0.5:0.5:0.1, whereby a light-emitting layer was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above was deposited by evaporation to a thickness of 20 nm, and then, 8mpTP-4mDBtPBfpm was deposited by evaporation to a thickness of 15 nm, whereby an electron-transport layer was formed.

After the formation of the electron-transport layer, 8mpTP-4mDBtPBfpm, 4,7-di-1-pyrrolidinyl-1,10-phenanthroline (abbreviation: Pyrrd-Phen) which is represented by Structural Formula (vi) above, and indium oxide (In₂O₃) were deposited by co-evaporation to a thickness of 5 nm such that the volume ratio of 8mpTP-4mDBtPBfpm, Pyrrd-Phen, and In₂O₃ was 0.5:0.5:0.02, whereby an electron-injection layer was formed.

After that, the substrate provided with the components up to the electron-injection layer was taken out from the vacuum evaporation apparatus and exposed to the atmosphere. After that, trimethylaluminum (abbreviation: TMA) was used as a precursor and water vapor was used as an oxidizer to deposit aluminum oxide to a thickness of 30 nm by an ALD method, so that an aluminum oxide film was formed as a first protective layer.

Over the first protective layer, molybdenum was deposited to a thickness of 50 nm by a sputtering method to form a second protective layer.

A photoresist was applied over the second protective layer, light-exposure and development were conducted, and processing was performed to form a slit having a width of 3 μm in a position 3.5 μm away from an end portion of the first electrode so that the EL layer was independently provided for each of the first electrodes.

Specifically, the second protective layer was processed using an etching gas containing carbon tetrafluoride (CF₄), oxygen (O₂), and helium (He) and an etching gas containing oxygen (O₂) with use of the photoresist in the development as a mask, and then a removal of the photoresist and the processing of the first protective layer were performed using a basic chemical solution containing tetramethyl ammonium hydroxide (abbreviation: TMAH) and water as a solvent and an etching gas containing fluoroform (CHF₃) and helium (He). After that, the EL layer (the electron-injection layer, the electron-transport layer, the light-emitting layer, the hole-transport layer, and the hole-injection layer) were processed using an etching gas containing oxygen (O₂).

After the EL layer was processed, the second protective layer was removed using an etching gas containing carbon tetrafluoride (CF₄), oxygen (O₂), and helium (He), and then the first protective layer was removed using an acidic chemical solution of a mixed acid containing hydrofluoric acid and water as a solvent, so that the top surface of the electron-injection layer was exposed. Then, the substrate was transferred into a vacuum evaporation apparatus where the pressure had been reduced to approximately 1×10⁻⁴ Pa, and heat treatment was performed at 100° C. for 1 hour in a heating chamber of the vacuum evaporation apparatus.

Then, silver (Ag) and magnesium (Mg) were deposited by co-evaporation to a thickness of 15 nm such that the volume ratio of Ag to Mg was 1:0.1, whereby the second electrode 102 was formed. Over the second electrode 102, 4,4′,4″-(benzene-1,3,5-triyl)tri(dibenzothiophene) (abbreviation: DBT3P-II) represented by Structural Formula (vii) above was deposited to a thickness of 70 nm as a cap layer to improve light extraction efficiency.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 2-1 was fabricated.

### (Method for Fabricating Light-Emitting Device 2-2)

The light-emitting device 2-2 was fabricated in a manner similar to that of the light-emitting device 2-1 except that 8mpTP-4mDBtPBfpm in the electron-injection layer of the light-emitting device 2-1 was replaced with 11-[3′-(dibenzothiophen-4-yl)biphenyl-3-yl]phenanthro[9′,10′:4,5]furo[2,3-b]pyrazine (abbreviation: 11mDBtBPPnfpr) represented by Structural Formula (viii) above and 11mDBtBPPnfpr, Pyrrd-Phen, and indium oxide (In₂O₃) were deposited by co-evaporation to a thickness of 5 nm such that the volume ratio of 11mDBtBPPnfpr, Pyrrd-Phen, and In₂O₃ was 0.5:0.5:0.02 to form an electron-injection layer.

### (Method for Fabricating Comparative Light-Emitting Device 2-1)

The comparative light-emitting device 2-1 was fabricated in a manner similar to that of the light-emitting device 2-1 except that 8mpTP-4mDBtPBfpm, Pyrrd-Phen, and indium oxide (In₂O₃) that are in the electron-injection layer of the light-emitting device 2-1, were replaced with 2,2′-(1,3-phenylene)bis(9-phenyl-1,10-phenanthroline) (abbreviation: mPPhen2P) represented by Structural Formula (ix) above and lithium oxide (Li₂O) and mPPhen2P and lithium oxide (Li₂O) were deposited by co-evaporation to a thickness of 5 nm such that the volume ratio of mPPhen2P to Li₂O was 1:0.02.

### (Method for Fabricating Comparative Light-Emitting Device 2-2)

The comparative light-emitting device 2-2 was fabricated in a manner similar to that of the light-emitting device 2-1 except that 8mpTP-4mDBtPBfpm, Pyrrd-Phen, and indium oxide (In₂O₃) that are in the electron-injection layer of the light-emitting device 2-1, were replaced with 9-(1-naphthyl)-10-[4-(2-naphthyl)phenyl]anthracene (abbreviation: αN-βNPAnth) represented by Structural Formula (x) above, Pyrrd-Phen, and indium (In) and αN-βNPAnth, Pyrrd-Phen, and indium (In) were deposited by co-evaporation to a thickness of 5 nm such that the volume ratio of αN-βNPAnth, Pyrrd-Phen, and In was 0.5:0.5:0.02 to form an electron-injection layer

Device structures of the light-emitting devices 2-1 and 2-2 and the comparative light-emitting devices 2-1 and 2-2 are shown below.

TABLE 7

| | | | | |
|---|---|---|---|---|
| | | | Comparative | Comparative |
| Thickness | Light-emitting | Light-emitting | light-emitting | light-emitting |
| (nm) | device 2-1 | device 2-2 | device 2-1 | device 2-2 |

| | | |
|---|---|---|
| Cap layer | 70 | DBT3P-II |
| Second electrode | 15 | Ag:Mg (1:0.1) |

Processing by photolithography technique

| | | |
|---|---|---|
| Electron-injection layer | 5 | *2 |
| Electron-transport layer | 15 | 8mpTP-4mDBtPBfpm |
| | 20 | 2mPCCzPDBq |
| Light-emitting layer | 40 | 8mpTP-4mDBtPBfpm:βNCCP:Ir(5mppy-d₃)₂(mbfpypy-d₃) |
| | | (0.5:0.5:0.1) |
| Hole-transport layer | 100 | PCBBiF |
| Hole-injection layer | 10 | PCBBiF:OCHD-003 |
| | | (1:0.03) |
| First electrode | 50 | ITSO |
| | 100 | APC |

TABLE 8

| | *2 |
|---|---|
| Light-emitting device 2-1 | 8mpTP-4mDBtPBfpm:Pyrrd-Phen:In₂O₃ |
| | (0.5:0.5:0.02) |
| Light-emitting device 2-2 | 11mDBtBPPnfpr:Pyrrd-Phen:In₂O₃ |
| | (0.5:0.5:0.02) |
| Comparative light-emitting | mPPhen2P:Li₂O |
| device 2-1 | (1:0.02) |
| Comparative light-emitting | αN-βNPAnth:Pyrrd-Phen:In |
| device 2-2 | (0.5:0.5:0.02) |

Note that the LUMO levels of 8mpTP-4mDBtPBfpm, 11mDBtBPPnfpr, and αN-βNPAnth, which are contained in the second organic compounds, were −3.01 eV, −3.02 eV, and −2.74 eV, respectively. The LUMO level of mPPhen2P was −2.71 eV. Note that the LUMO level of Pyrrd-Phen, which is contained in the first organic compound, was −2.55 eV. Note that the value of the LUMO level was calculated by the method described in Example 1.

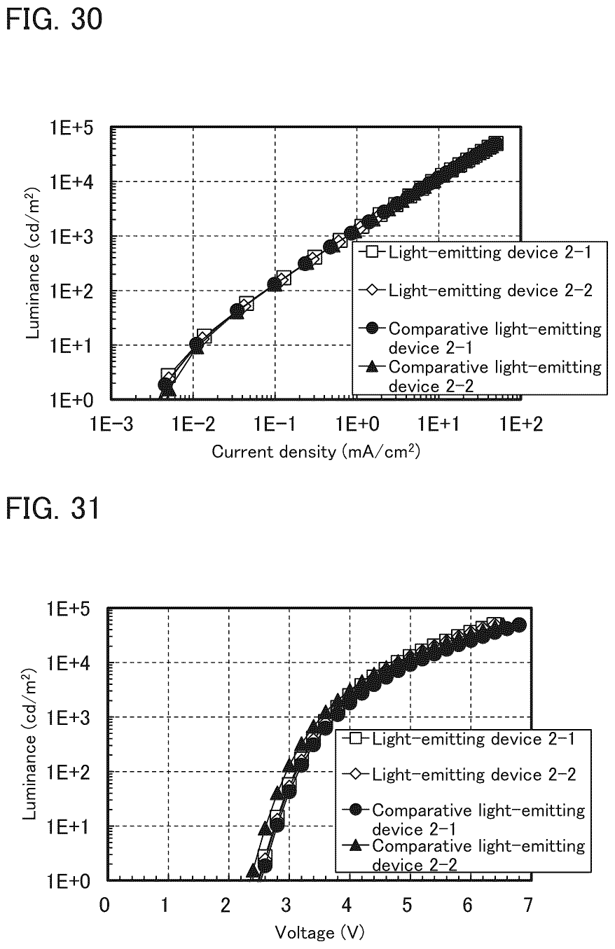

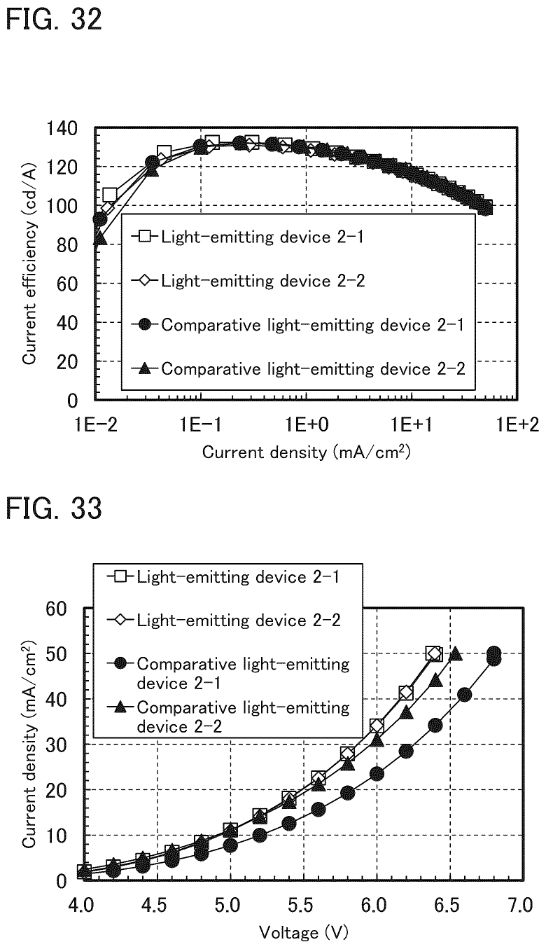

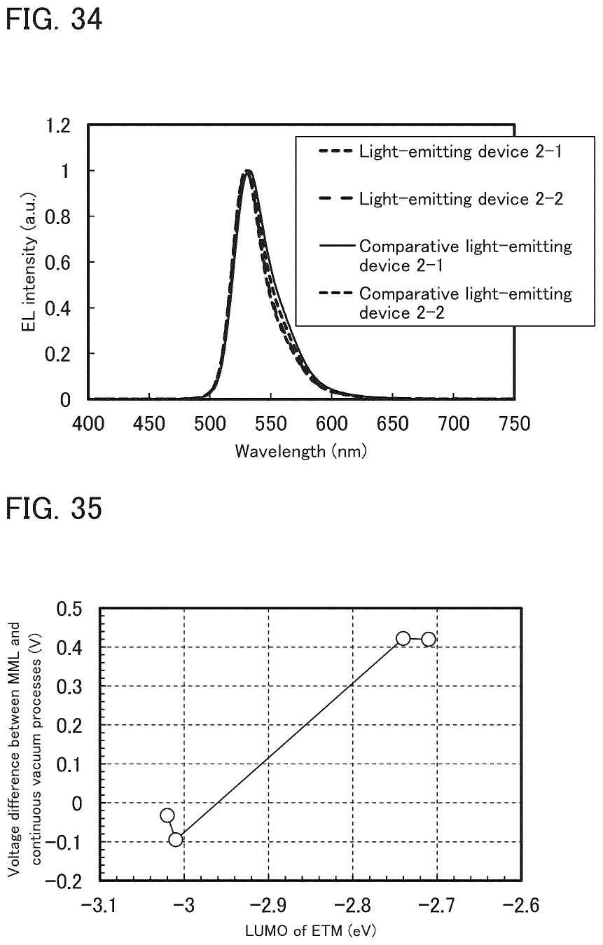

FIG. 30 shows the luminance-current density characteristics of the light-emitting devices 2-1 and 2-2 and the comparative light-emitting devices 2-1 and 2-2, FIG. 31 shows the luminance-voltage characteristics thereof, FIG. 32 shows the current efficiency-current density characteristics thereof, FIG. 33 shows the current density-voltage characteristics thereof, and FIG. 34 shows the electroluminescence spectra thereof. Luminance and emission spectra were measured at normal temperature with a spectroradiometer (SR-UL1R manufactured by TOPCON TECHNOHOUSE CORPORATION).

As can be seen from FIG. 30 to FIG. 34, the light-emitting devices 2-1 and 2-2 in which the LUMO level of the second organic compound is lower than that of the first organic compound by 0.20 ev or more were found to have favorable characteristics with lower driving voltage than the comparative light-emitting devices 2-1 and 2-2 and highly efficient green light emission.

Light-emitting devices having the same respective stacked-layer structures as the light-emitting devices 2-1 and 2-2 and the comparative light-emitting devices 2-1 and 2-2 and not subjected to EL layer processing by a photolithography technique were fabricated, and differences in voltage at a current density of 50 mA/cm² were obtained. FIG. 35 shows the results of plotting the obtained voltage differences with respect to the LUMO levels of the second organic compounds. It was found from FIG. 35 that the light-emitting device in which the LUMO level of the second organic compound is lower than 2.74 eV has favorable characteristics such that an increase in driving voltage is inhibited, even when being processed by a photolithography technique. The LUMO level of the first organic compound was −2.55 eV; thus, it was found that the light-emitting device in which the LUMO level of the second organic compound was lower than that of the first organic compound by 0.20 eV or more has favorable characteristics such that an increase in driving voltage is inhibited, even when being processed by a photolithography technique.

This application is based on Japanese Patent Application Serial No. 2023-188880 filed with Japan Patent Office on Nov. 2, 2023, the entire contents of which are hereby incorporated by reference.

What is claimed is:

1. A light-emitting device comprising:
a first electrode;
a second electrode; and
an EL layer,
wherein the EL layer is positioned between the first electrode and the second electrode,
wherein the EL layer comprises a light-emitting layer and an electron-injection layer,
wherein the electron-injection layer comprises a metal or an oxide of the metal, a first organic compound, and a second organic compound,
wherein the first organic compound is an organic compound comprising a first π-electron deficient heteroaromatic ring with an electron-donating group,
wherein the second organic compound is an organic compound comprising a second π-electron deficient heteroaromatic ring, and
wherein a LUMO level of the second organic compound is lower than a LUMO level of the first organic compound by 0.20 eV or more.

2. The light-emitting device according to claim 1,
wherein the electron-injection layer is a mixed layer comprising the metal or the oxide of the metal, the first organic compound, and the second organic compound.

3. The light-emitting device according to claim 1,
wherein the electron-injection layer comprises a stacked-layer structure of a first layer comprising the metal and a second layer comprising the first organic compound and the second organic compound, and
wherein the first layer is closer to a cathode side than the second layer is.

4. The light-emitting device according to claim 1,
wherein a relation LUMO1−0.80≤LUMO2≤LUMO1−0.20 is satisfied where the LUMO level of the first organic compound is LUMO1 (eV) and the LUMO level of the second organic compound is LUMO2 (eV).

5. The light-emitting device according to claim 1,
wherein the first π-electron deficient heteroaromatic ring is a heteroaromatic ring comprising two or more pyridine rings.

6. The light-emitting device according to claim 1,
wherein the first organic compound is an organic compound having an acid dissociation constant pKₐ larger than or equal to 8.

7. The light-emitting device according to claim 1,
wherein the first π-electron deficient heteroaromatic ring and the second π-electron deficient heteroaromatic ring are different from each other.

8. The light-emitting device according to claim 1,
wherein the second organic compound comprises at least one of an imidazole ring, a pyrazole ring, an oxazole ring, a thiazole ring, a triazole ring, a pyrazine ring, a pyrimidine ring, a pyridazine ring, and a triazine ring.

9. The light-emitting device according to claim 1,
wherein the second organic compound has an acid dissociation constant pKₐ less than 4.

10. The light-emitting device according to claim 1,
wherein the light-emitting layer comprises a third organic compound,
wherein the third organic compound comprises a third π-electron deficient heteroaromatic ring, and
wherein the third π-electron deficient heteroaromatic ring is the same as the second it-electron deficient heteroaromatic ring.

11. The light-emitting device according to claim 1,
wherein the electron-donating group is any one or more of an alkyl group, an alkoxy group, an aryloxy group, an alkylamino group, an arylamino group, and a heterocyclic amino group.

12. A light-emitting device that is one light-emitting device of a plurality of light-emitting devices included in a light-emitting device group, the light-emitting device group comprising:
a first electrode group formed over one insulating surface;
a second electrode group facing the first electrode group; and
an EL layer group positioned between the first electrode group and the second electrode group,
wherein the light-emitting device comprises a first electrode, a second electrode, and an EL layer,
wherein the first electrode is one included in the first electrode group,
wherein the first electrode is independent for each of the plurality of light-emitting devices,
wherein the EL layer is one included in the EL layer group,
wherein the EL layer is independent for each of the plurality of light-emitting devices,
wherein the second electrode is a continuous conductive layer shared by the plurality of light-emitting devices,
wherein the second electrode and the EL layer overlap with the first electrode,
wherein the EL layer comprises a light-emitting layer and an electron-injection layer,
wherein the electron-injection layer comprises a metal or an oxide of the metal, a first organic compound, and a second organic compound,
wherein the first organic compound is an organic compound comprising a first π-electron deficient heteroaromatic ring with an electron-donating group,
wherein the second organic compound is an organic compound comprising a second π-electron deficient heteroaromatic ring,
wherein a LUMO level of the second organic compound is lower than a LUMO level of the first organic compound by 0.20 eV or more, and
wherein a distance between the EL layer included in the light-emitting device and the EL layer included in another light-emitting device adjacent to the light-emitting device is greater than or equal to 0.5 μm and less than or equal to 5 μm.

13. The light-emitting device according to claim 12,
wherein the electron-injection layer is a mixed layer comprising the metal or the oxide of the metal, the first organic compound, and the second organic compound.

14. The light-emitting device according to claim 12,
wherein the electron-injection layer comprises a stacked-layer structure of a first layer comprising the metal and a second layer comprising the first organic compound and the second organic compound, and
wherein the first layer is closer to a cathode side than the second layer is.

15. The light-emitting device according to claim 12,
wherein a relation LUMO1−0.80≤LUMO2≤LUMO1−0.20 is satisfied where the LUMO level of the first organic compound is LUMO1 (eV) and the LUMO level of the second organic compound is LUMO2 (eV).

16. The light-emitting device according to claim 12,
wherein the first π-electron deficient heteroaromatic ring is a heteroaromatic ring comprising two or more pyridine rings.

17. The light-emitting device according to claim 12,
wherein the first organic compound is an organic compound having an acid dissociation constant pKₐ larger than or equal to 8.

18. The light-emitting device according to claim 12,
wherein the first π-electron deficient heteroaromatic ring and the second π-electron deficient heteroaromatic ring are different from each other.

19. The light-emitting device according to claim 12,
wherein the second organic compound comprises at least one of an imidazole ring, a pyrazole ring, an oxazole ring, a thiazole ring, a triazole ring, a pyrazine ring, a pyrimidine ring, a pyridazine ring, and a triazine ring.

20. The light-emitting device according to claim 12,
wherein the second organic compound has an acid dissociation constant pKₐ less than 4.

21. The light-emitting device according to claim 12,
wherein the light-emitting layer comprises a third organic compound,
wherein the third organic compound comprises a third π-electron deficient heteroaromatic ring, and
wherein the third π-electron deficient heteroaromatic ring is the same as the second it-electron deficient heteroaromatic ring.

22. The light-emitting device according to claim 12,
wherein the electron-donating group is any one or more of an alkyl group, an alkoxy group, an aryloxy group, an alkylamino group, an arylamino group, and a heterocyclic amino group.
